(19) United States
(12) Patent Application Publication
(10) Pub. No.: US 2026/0314163 A1
(43) Pub. Date: Oct. 8, 2026

(54) ORGANIC ELECTROLUMINESCENT MATERIAL, ELEMENT AND DISPLAY DEVICE

(71) Applicant: BEIJING SUMMER SPROUT TECHNOLOGY CO., LTD., Beijing (CN)

(72) Inventors: Zheng Wang, Beijing (CN); Hongbo Li, Beijing (CN); Wei Cai, Beijing (CN); Zhen Wang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 19/633,205

(22) Filed: Mar. 30, 2026

(30) Foreign Application Priority Data
Mar. 30, 2025 (CN) 202510386039.X
Mar. 13, 2026 (CN) 202610310357.2

(51) Int. Cl. H10K 50/12; H10K 85/60; H10K 101/00; H10K 101/20

(52) U.S. Cl. CPC H10K 50/12; H10K 85/622; H10K 85/626; H10K 85/654; H10K 85/656; H10K 85/6572; H10K 85/6574; H10K 85/6576; H10K 85/658; H10K 2101/20; H10K 2101/90

(57) ABSTRACT

Provided are an organic electroluminescent material, a device thereof, and a display device. The organic electroluminescent material is a compound having a structure represented by Formula 1. An organic electroluminescent device using the compound as a fluorescent material can achieve particular green light emission and has a relatively narrow full width at half maximum (FWHM), a relatively low driving voltage, and relatively high device efficiency (CE, PE, and EQE), thus exhibiting excellent overall performance. Further provided are an organic electroluminescent device comprising the organic electroluminescent material, a display device thereof, and a compound composition comprising the organic electroluminescent material.

### CROSS-REFERENCE TO RELATED APPLICATION(S)

This application claims priority to Chinese Patent Application No. 202510386039.X filed on Mar. 30, 2025, and Chinese Patent Application No. 202610310357.2 filed on Mar. 13, 2026, the disclosure of which is incorporated herein by reference in its entirety.

### TECHNICAL FIELD

The present disclosure relates to compounds for organic electronic devices such as organic light-emitting devices. Particularly, the present disclosure relates to a compound having a structure of Formula 1, an organic electroluminescent device comprising the compound, a display device, and a compound composition comprising the compound.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This invention has laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

WO2020080528A1 discloses a compound having a structure represented by the following general formula:

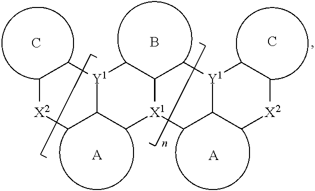

wherein X² each independently represents O, NR, CRR, S, or Se. WO2020080528A1 further discloses specific compounds where X² is selected from O or N, such as

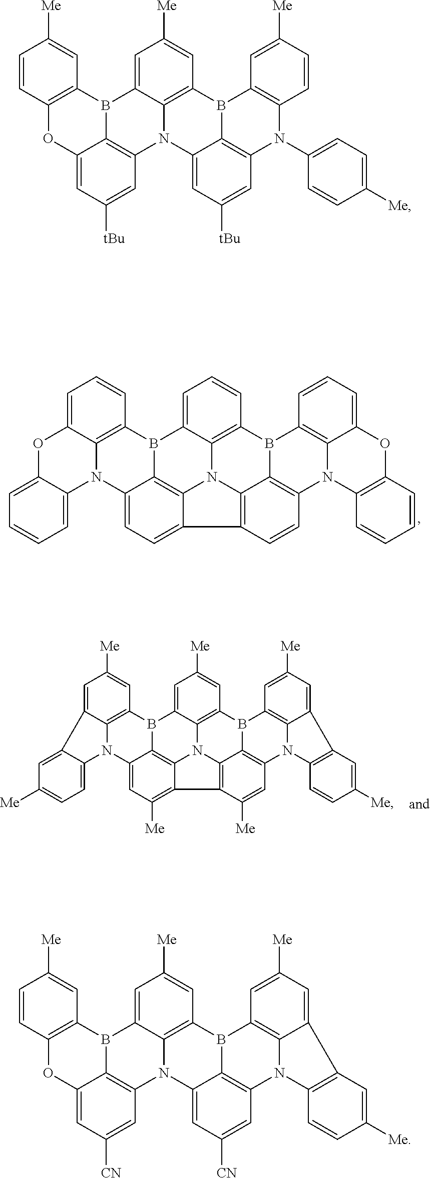 [SMILES: Cc1ccc(N2c3ccc(C)cc3B3c4cc(C)cc5c4N(c4cc(C(C)(C)C)cc6c4B5c4cc(C)ccc4O6)c4cc(C(C)(C)C)cc2c43)cc1 ; c1ccc2c(c1)Oc1cccc3c1N2c1ccc2c4ccc5c6c4n4c2c1B3c1cccc(c1-4)B6c1cccc2c1N5c1ccccc1O2 ; Cc1cc2c3c(c1)B1c4cc(C)cc5c6cc(C)ccc6n(c45)-c4cc(C)c5c6c(C)cc7c(c6n-3c5c41)B2c1cc(C)cc2c3cc(C)ccc3n-7c12 ; Cc1ccc2c(c1)B1c3cc(C)cc4c3N(c3cc(C#N)cc(c31)O2)c1cc(C#N)cc2c1B4c1cc(C)cc3c4cc(C)ccc4n-2c13]

However, WO2020080528A1 has neither disclosed nor taught a compound where X² is another atom and an application of the compound in an electroluminescent device, and has not disclosed different technical effects which can be brought about by the compound where X² is another atom.

At present, the performance of fluorescent devices still needs to be further improved, such as the adjustment of emission wavelengths, full widths at half maximum, voltages, and device efficiency. Therefore, developing a new fluorescent material with excellent performance is an urgent technical problem to be solved in the art.

### SUMMARY

The present disclosure aims to provide a new compound to solve at least part of the preceding problems. The compound has a structure represented by Formula 1. An organic electroluminescent device using the compound as a fluorescent material can achieve particular green light emission and has a relatively narrow full width at half maximum (FWHM), a relatively low driving voltage, and relatively high device efficiency (CE, PE, and EQE), thus exhibiting excellent overall performance.

According to an embodiment of the present disclosure, disclosed is a compound having a structure represented by Formula 1:

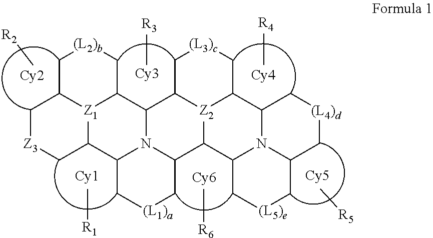

wherein,
the ring Cy1, the ring Cy2, the ring Cy3, the ring Cy4, the ring Cy5, and the ring Cy6 are, at each occurrence identically or differently, selected from an unsaturated carbocyclic ring having 5 to 30 carbon atoms, an unsaturated heterocyclic ring having 3 to 30 carbon atoms, or a combination thereof;
Z₁ and Z₂ are, at each occurrence identically or differently, selected from B, N, P, P═O, P═S, As, As═O, or As═S;
Z₃ is, at each occurrence identically or differently, selected from S, SiRR, GeRR, C═O, C═S, or C═CRR; when multiple R are present, the multiple R are identical or different;
L₁, L₂, L₃, L₄, and L₅ are, at each occurrence identically or differently, selected from a single bond, O, S, Se, BR′, NR′, PR′, P═OR′, P═SR′, AsR′, As═OR′, As═SR′, C═O, CR′R′, SiR′R′, or GeR′R′; when multiple R′ are present, the multiple R′ are identical or different;
a, b, c, d, and e are each independently selected from 0 or 1;
R₁, R₂, R₃, R₄, R₅, and R₆ represent, at each occurrence identically or differently, mono-substitution, multiple substitutions, or non-substitution;
R, R′, R₁, R₂, R₃, R₄, R₅, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, R′, R″, R₁, R₂, R₃, R₄, R₅, and R₆ can be optionally joined to form a ring.

According to another embodiment of the present disclosure, further disclosed is a compound composition comprising the compound of any one of the preceding embodiments.

According to another embodiment of the present disclosure, further disclosed is an organic electroluminescent device comprising a cathode, an anode, and an organic layer disposed between the anode and the cathode, wherein the organic layer comprises the compound of any one of the preceding embodiments.

According to another embodiment of the present disclosure, further disclosed is a display device comprising the preceding organic electroluminescent device.

### BRIEF DESCRIPTION OF DRAWINGS

FIG. 1 is a schematic diagram of an organic light-emitting device that may comprise a compound and a compound composition disclosed herein.

FIG. 2 is a schematic diagram of another organic light-emitting device that may comprise a compound and a compound composition disclosed herein.

### DETAILED DESCRIPTION

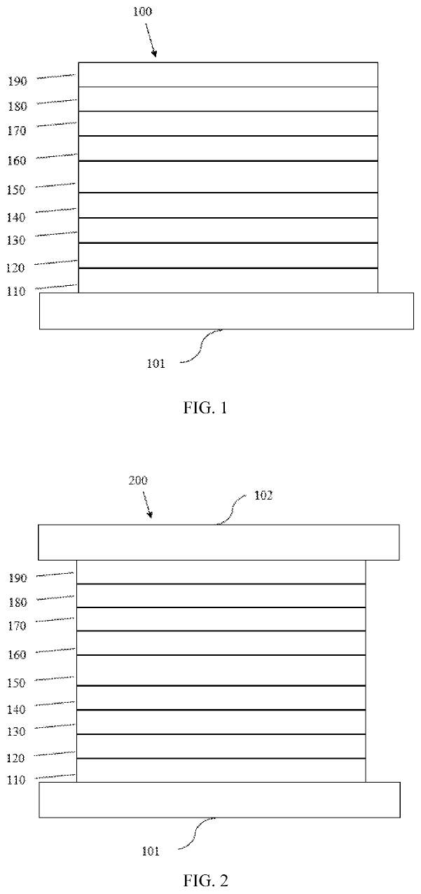

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, an n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or aromatic group or aromatic ring—as used herein includes noncondensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl or heteroaromatic group or heteroaromatic ring—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-aminobenzyl, o-aminobenzyl, m-hydroxybenzyl, o-hydroxybenzyl, p-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with at least one aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions, etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

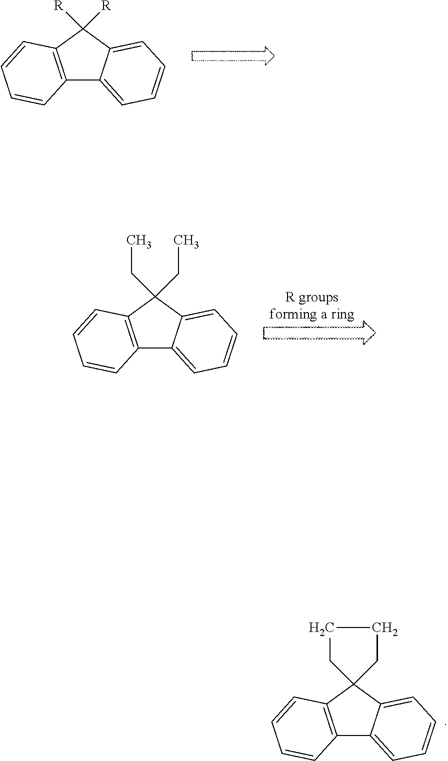

The expression that adjacent substituents can be optionally joined to form a ring is also intended to mean that two substituents bonded to carbon atoms which are directly bonded to each other are joined to each other via a chemical bond to form a ring, which can be exemplified by the following formula:

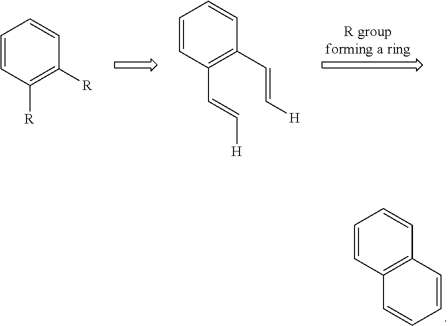

The expression that adjacent substituents can be optionally joined to form a ring is also intended to mean that two substituents bonded to further distant carbon atoms are joined to each other via a chemical bond to form a ring, which can be exemplified by the following formula:

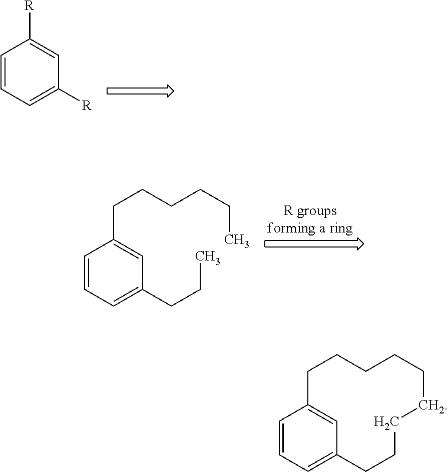

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

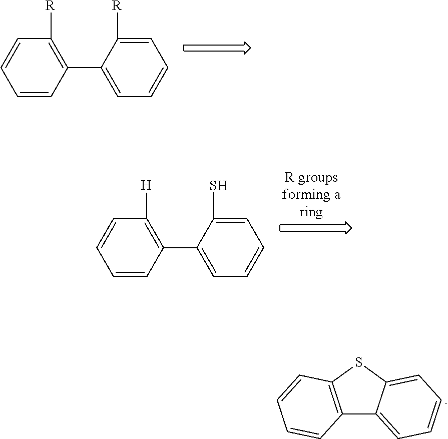

According to an embodiment of the present disclosure, disclosed is a compound having a structure represented by Formula 1:

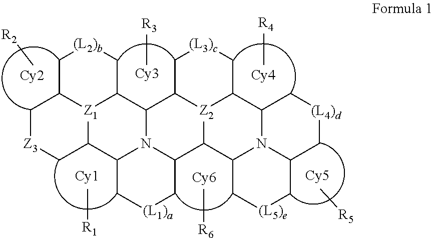

wherein,
the ring Cy1, the ring Cy2, the ring Cy3, the ring Cy4, the ring Cy5, and the ring Cy6 are, at each occurrence identically or differently, selected from an unsaturated carbocyclic ring having 5 to 30 carbon atoms, an unsaturated heterocyclic ring having 3 to 30 carbon atoms, or a combination thereof;
Z₁ and Z₂ are, at each occurrence identically or differently, selected from B, N, P, P═O, P═S, As, As═O, or As═S;
Z₃ is, at each occurrence identically or differently, selected from S, SiRR, GeRR, C═O, C═S, or C═CRR; when multiple R are present, the multiple R are identical or different;

L₁, L₂, L₃, L₄, and L₅ are, at each occurrence identically or differently, selected from a single bond, O, S, Se, BR′, NR′, PR′, P═OR′, P═SR′, AsR′, As═OR′, As═SR′, C═O, CR′R′, SiR′R′, or GeR′R′; when multiple R′ are present, the multiple R′ are identical or different;
a, b, c, d, and e are each independently selected from 0 or 1;
R₁, R₂, R₃, R₄, R₅, and R₆ represent, at each occurrence identically or differently, mono-substitution, multiple substitutions, or non-substitution;
R, R′, R₁, R₂, R₃, R₄, R₅, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, R′, R″, R₁, R₂, R₃, R₄, R₅, and R₆ can be optionally joined to form a ring.

Herein, the expression that “adjacent substituents R, R′, R″, R₁, R₂, R₃, R₄, R₅, and R₆ can be optionally joined to form a ring” is intended to mean that any one or more of groups of adjacent substituents, including, but not limited to, two substituents R, two substituents R′, two substituents R″, two substituents R₁, two substituents R₂, two substituents R₃, two substituents R₄, two substituents R₅, two substituents R₆, substituents R and R₁, substituents R and R₂, substituents R′ and R₁, substituents R′ and R₂, substituents R′ and R₃, substituents R′ and R₄, substituents R′ and R₅, substituents R′ and R₆, substituents R₁ and R₆, substituents R₆ and R₅, substituents R₄ and R₃, substituents R₂ and R₃, substituents R″ and R₁, substituents R″ and R₂, substituents R″ and R₃, substituents R″ and R₄, substituents R″ and R₅, substituents R″ and R₆, substituents R″ and R′, and substituents R″ and R, can be joined to form a ring. Obviously, it is also possible that none of these groups of adjacent substituents are joined to form a ring.

Herein, the expression that “a, b, c, d, and e are each independently selected from 0 or 1” is intended to mean that Cy1 and Cy6, Cy2 and Cy3, Cy3 and Cy4, Cy4 and Cy5, and Cy5 and Cy6 corresponding to a, b, c, d, and e are joined or disjoined. For example, when a is 0, Cy1 and Cy6 are disjoined (that is, Cy1 is not joined to Cy6), and the same is true when one or more of a, b, c, d, and e are 0.

Herein, a “carbocyclic ring” comprises a saturated carbocyclic ring and an unsaturated carbocyclic ring, the “unsaturated carbocyclic ring” comprises an aromatic unsaturated carbocyclic ring and a non-aromatic unsaturated carbocyclic ring, a “heterocyclic ring” comprises a saturated heterocyclic ring and an unsaturated heterocyclic ring, and the “unsaturated heterocyclic ring” comprises an aromatic unsaturated heterocyclic ring and a non-aromatic unsaturated heterocyclic ring.

In this embodiment, “R, R′, R₁, R₂, R₃, R₄, R₅, and R₆ are, at each occurrence identically or differently,” means that the listed substituents may be identical or different at each occurrence, where the listed substituents include substituents with different reference numerals, for example, R and R₁ may be identical or different at each occurrence; or the listed substituents include substituents with the same reference numerals, for example, when multiple R₁ are present, each R₁ may be identical or different. The same is true for the other listed substituents that are identical or different.

According to an embodiment of the present disclosure, the compound has a relative molecular weight of 450 to 1500.

According to an embodiment of the present disclosure, the compound has a relative molecular weight of 500 to 1300.

According to an embodiment of the present disclosure, the compound has a relative molecular weight of 800 to 1200.

According to an embodiment of the present disclosure, the compound has a relative molecular weight of 600 to 1000.

According to an embodiment of the present disclosure, the ring Cy1, the ring Cy2, the ring Cy3, the ring Cy4, the ring Cy5, and the ring Cy6 are, at each occurrence identically or differently, selected from a five-membered unsaturated carbocyclic ring, an aromatic ring having 6 to 30 carbon atoms, a heteroaromatic ring having 3 to 30 carbon atoms, or a combination thereof.

According to an embodiment of the present disclosure, the ring Cy1, the ring Cy2, the ring Cy3, the ring Cy4, the ring Cy5, and the ring Cy6 are, at each occurrence identically or differently, selected from a five-membered unsaturated carbocyclic ring, an aromatic ring having 6 to 18 carbon atoms, a heteroaromatic ring having 3 to 18 carbon atoms, or a combination thereof.

According to an embodiment of the present disclosure, the ring Cy1, the ring Cy2, the ring Cy3, the ring Cy4, the ring Cy5, and the ring Cy6 are, at each occurrence identically or differently, selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring, or a combination thereof.

According to an embodiment of the present disclosure, the ring Cy1, the ring Cy2, the ring Cy3, the ring Cy4, the ring Cy5, and the ring Cy6 are, at each occurrence identically or differently, selected from a benzene ring.

According to an embodiment of the present disclosure, L₁, L₂, L₃, L₄, and L₅ are, at each occurrence identically or differently, selected from a single bond, O, S, Se, BR′, NR′, P═OR′, CR′R′, or SiR′R′; and the R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, L₁, L₂, L₃, L₄, and L₅ are, at each occurrence identically or differently, selected from a single bond, O, S, NR′, or CR′R′; and the R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, L₁, L₂, L₃, L₄, and L₅ are each a single bond.

According to an embodiment of the present disclosure, a+b+c+d+e is greater than or equal to 1.

According to an embodiment of the present disclosure, a+b+c+d+e=0, 1, or 2.

According to an embodiment of the present disclosure, a+d+e=1 or 2.

According to an embodiment of the present disclosure, d+e=1 or 2.

According to an embodiment of the present disclosure, a, b, c, and e are all 0, and d=1.

According to an embodiment of the present disclosure, a, b, c, and e are all 0, d=1, and L₄ is selected from a single bond.

According to an embodiment of the present disclosure, the compound has a structure represented by Formula 2-1 to Formula 2-20:

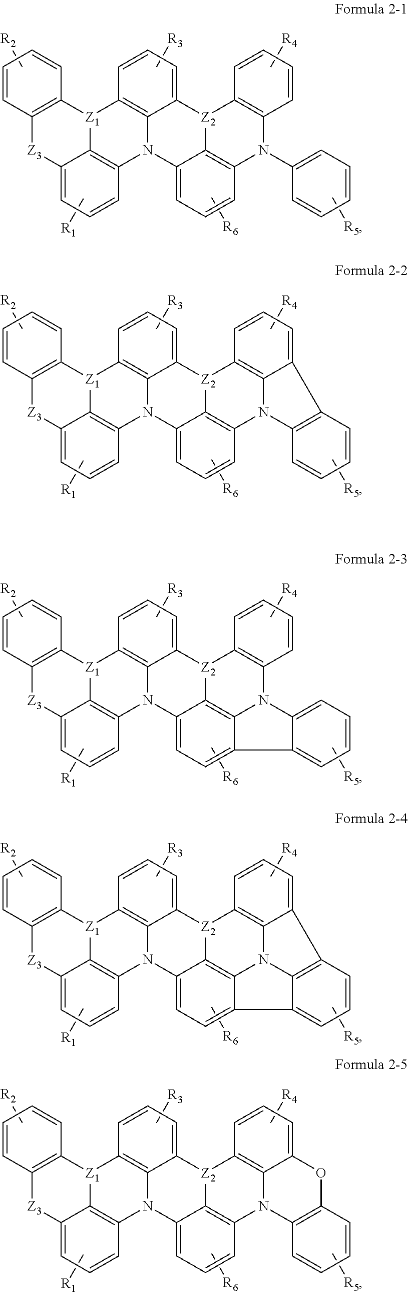

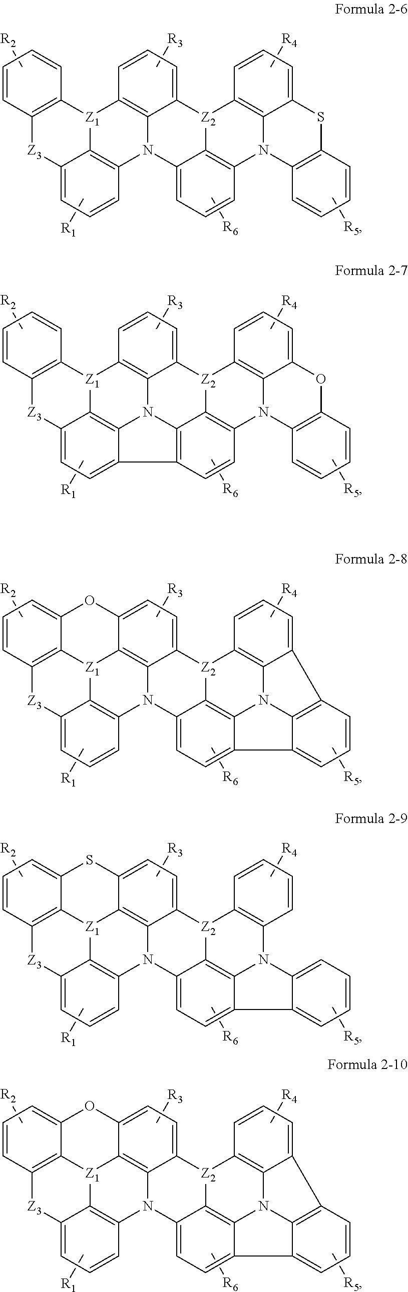

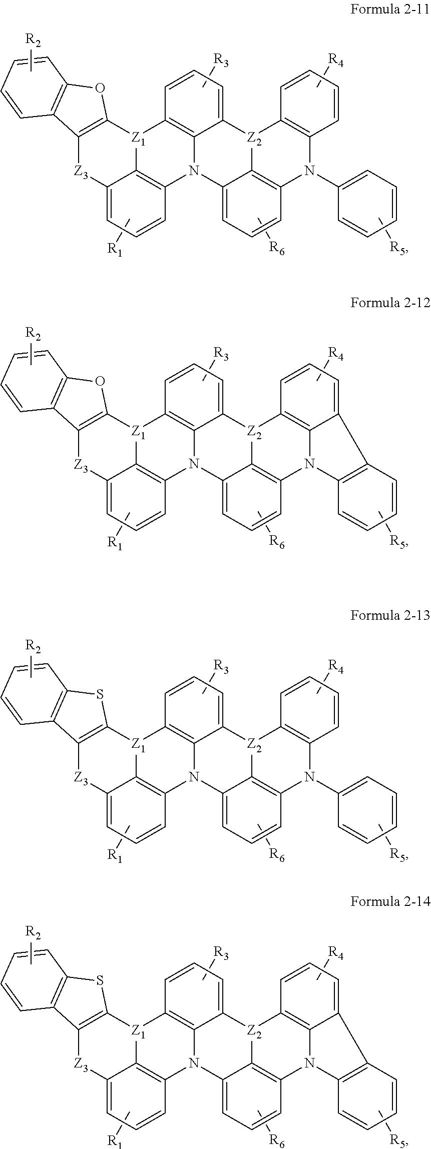

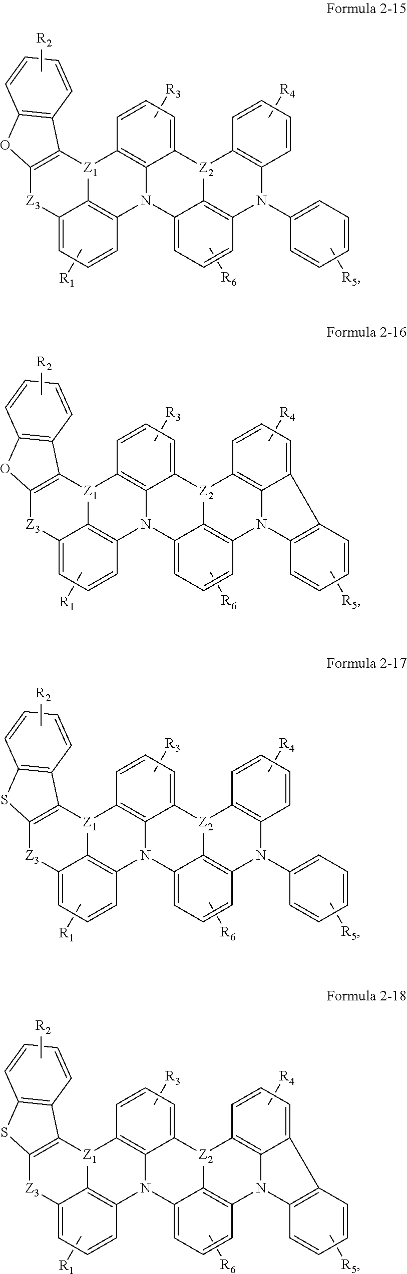

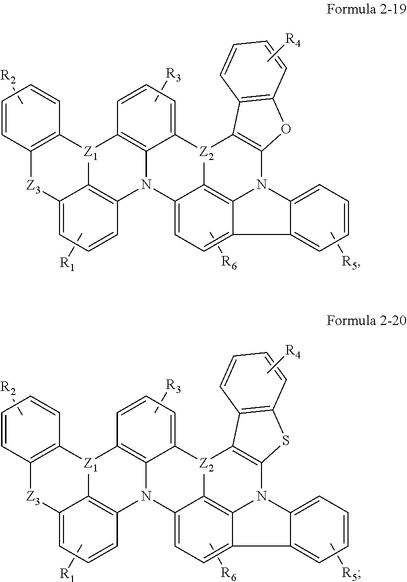

wherein,
Z₁ and Z₂ are, at each occurrence identically or differently, selected from B, N, P, P═O, P═S, As, As═O, or As═S;
Z₃ is, at each occurrence identically or differently, selected from S, SiRR, GeRR, C═O, C═S, or C═CRR; when multiple R are present, the multiple R are identical or different;
R₁, R₂, R₃, R₄, R₅, and R₆ represent, at each occurrence identically or differently, mono-substitution, multiple substitutions, or non-substitution;
R, R₁, R₂, R₃, R₄, R₅, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, R″, R₁, R₂, R₃, R₄, R₅, and R₆ can be optionally joined to form a ring.

Herein, the expression that “adjacent substituents R, R″, R₁, R₂, R₃, R₄, R₅, and R₆ can be optionally joined to form a ring” is intended to mean that any one or more of groups of adjacent substituents, including, but not limited to, two substituents R, two substituents R″, two substituents R₁, two substituents R₂, two substituents R₃, two substituents R₄, two substituents R₅, two substituents R₆, substituents R and R₁, substituents R and R₂, substituents R₁ and R₆, substituents R₆ and R₅, substituents R₄ and R₃, substituents R₂ and R₃, substituents R″ and R₁, substituents R″ and R₂, substituents R″ and R₃, substituents R″ and R₄, substituents R″ and R₅, substituents R″ and R₆, and substituents R″ and R, can be joined to form a ring. Obviously, it is also possible that none of these groups of adjacent substituents are joined to form a ring.

According to an embodiment of the present disclosure, the compound is selected from a structure represented by Formula 2-2.

According to an embodiment of the present disclosure, the fluorescent material has a structure represented by Formula 2-1-1 to Formula 2-1-11:

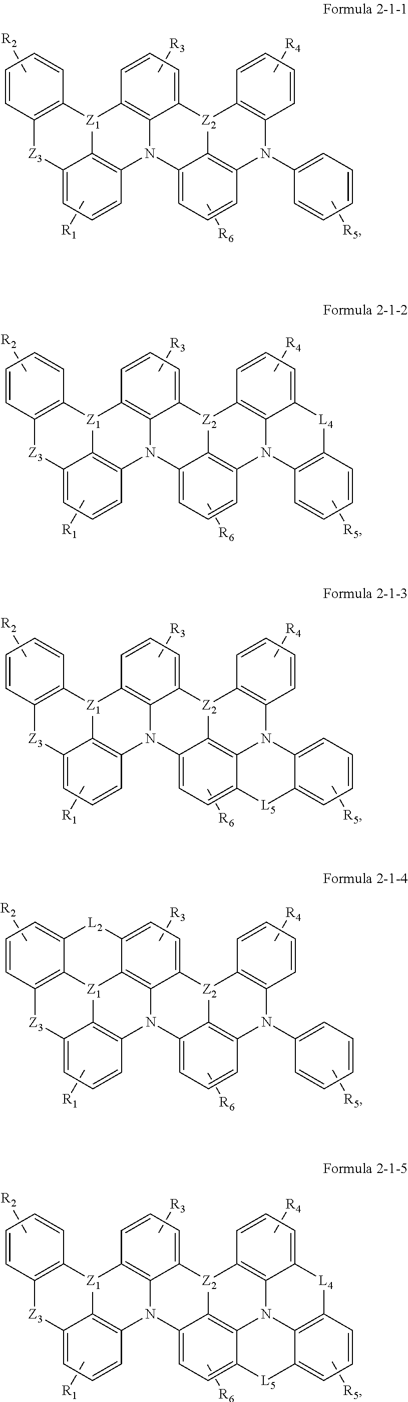

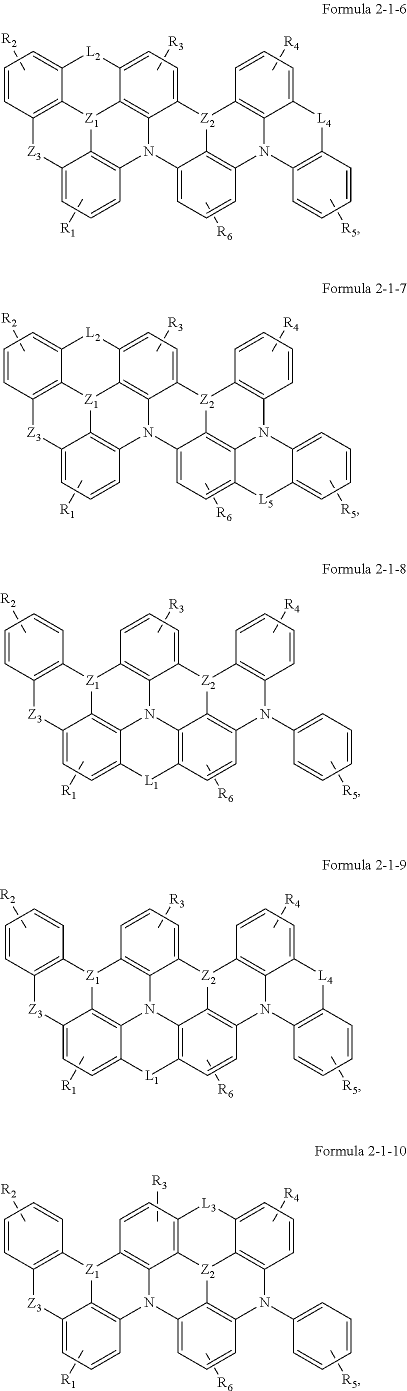

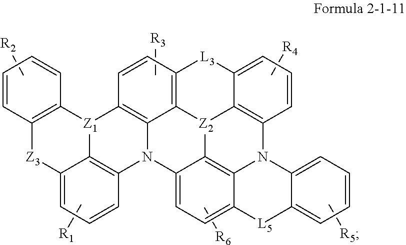

wherein,
Z₁ and Z₂ are, at each occurrence identically or differently, selected from B, N, P, P═O, P═S, As, As═O, or As═S;
Z₃ is, at each occurrence identically or differently, selected from S, SiRR, GeRR, C—O, C═S, or C═CRR; when multiple R are present, the multiple R are identical or different;
L₁, L₂, L₃, L₄, and L₅ are, at each occurrence identically or differently, selected from a single bond, O, S, Se, BR′, NR′, PR′, P═OR′, P═SR′, AsR′, As═OR′, As═SR′, C═O, CR′R′, SIR′R′, or GeR′R′; when multiple R′ are present, the multiple R′ are identical or different;
R₁, R₂, R₃, R₄, R₅, and R₆ represent, at each occurrence identically or differently, mono-substitution, multiple substitutions, or non-substitution;
R₁, R₂, R₃, R₄, R₅, R₆, R, and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₁, R₂, R₃, R₄, R₅, R₆, R, R′, and R″ can be optionally joined to form a ring.

According to an embodiment of the present disclosure, the compound is selected from a structure represented by Formula 2-1-2.

According to an embodiment of the present disclosure, Z₁ and Z₂ are, at each occurrence identically or differently, selected from B, P, P═O, or P═S.

According to an embodiment of the present disclosure, Z₁ and Z₂ are, at each occurrence identically or differently, selected from B or P═O.

According to an embodiment of the present disclosure, at least one of Z₁ or Z₂ is selected from B.

According to an embodiment of the present disclosure, Z₁ and Z₂ are, at each occurrence, selected from B.

According to an embodiment of the present disclosure, Z₃ is, at each occurrence identically or differently, selected from S, SiRR, C═O, or C═S; and the R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, Z₃ is, at each occurrence identically or differently, selected from S, SiRR, or C—O; and the R is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, Z₃ is, at each occurrence identically or differently, selected from S.

According to an embodiment of the present disclosure, R₁, R₂, R₃, R₄, R₅, and R₆ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted amino having 0 to 20 carbon atoms, a cyano group, an isocyano group, a hydroxyl group, a sulfanyl group, and combinations thereof; and adjacent substituents R₁, R₂, R₃, R₄, R₅, and R₆ can be optionally joined to form a ring.

According to an embodiment of the present disclosure, R₁, R₂, R₃, R₄, R₅, and R₆ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, a cyano group, a hydroxyl group, a sulfanyl group, and combinations thereof; and adjacent substituents R₁, R₂, R₃, R₄, R₅, and R₆ can be optionally joined to form a ring.

According to an embodiment of the present disclosure, at least one (for example, one, two, three, or four) of R₁, R₂, R₃, R₄, R₅, or R₆ is selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, and combinations thereof.

According to an embodiment of the present disclosure, at least one R₁, at least one R₂, at least one R₃, at least one R₄, at least one R₅, and/or at least one R₆ are each selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, a hydroxyl group, a sulfanyl group, and combinations thereof.

According to an embodiment of the present disclosure, at least one R₁, at least one R₂, at least one R₃, at least one R₄, at least one R₅, and/or at least one R₆ are, at each occurrence identically or differently, selected from the group consisting of: deuterium, substituted or unsubstituted alkyl having 1 to 10 carbon atoms, substituted or unsubstituted cycloalkyl having 3 to 10 ring carbon atoms, substituted or unsubstituted alkenyl having 2 to 20 carbon atoms, substituted or unsubstituted aryl having 6 to 14 carbon atoms, substituted or unsubstituted heteroaryl having 3 to 14 carbon atoms, a hydroxyl group, a sulfanyl group, and combinations thereof; and adjacent substituents R₁, R₂, R₃, R₄, R₅, and R₆ can be optionally joined to form a ring.

According to an embodiment of the present disclosure, the compound is selected from the group consisting of Compound 3-1-k, Compound 3-2-k, Compound 3-3-k, Compound 3-4-k, Compound 3-5-k, Compound 3-6-k, Compound 3-7-k, Compound 3-8-k, and Compound 4-1-k₁, wherein k is selected from an integer from 1 to 423, and k₁ is selected from an integer from 1 to 129; wherein the specific structures of Compound 3-1-k, Compound 3-2-k, Compound 3-3-k, Compound 3-4-k, Compound 3-5-k, Compound 3-6-k, Compound 3-7-k, Compound 3-8-k, and Compound 4-1-k₁ are referred to claim 9.

According to an embodiment of the present disclosure, hydrogens in Compound 3-1-k, Compound 3-2-k, Compound 3-3-k, Compound 3-4-k, Compound 3-5-k, Compound 3-6-k, Compound 3-7-k, Compound 3-8-k, and Compound 4-1-k₁ (k is selected from an integer from 1 to 423, and k₁ is selected from an integer from 1 to 129) can be partially or fully substituted with deuterium.

According to another embodiment of the present disclosure, further disclosed is an organic electroluminescent device comprising an anode, a cathode, and an organic layer disposed between the anode and the cathode, wherein the organic layer comprises the compound of any one of the preceding embodiments.

According to an embodiment of the present disclosure, the organic layer is an emissive layer, and the compound is a fluorescent material.

According to an embodiment of the present disclosure, the compound is a delayed fluorescent material.

According to an embodiment of the present disclosure, the compound is a thermally activated delayed fluorescent (TADF) material.

According to an embodiment of the present disclosure, the organic layer further comprises at least one metal complex.

According to an embodiment of the present disclosure, the at least one metal complex is used as a phosphorescent sensitizer.

According to an embodiment of the present disclosure, the organic layer further comprises at least one metal complex having a general formula of M(Lₐ)ₘ(L_{b})ₙ(L_{c})_{q};
the metal M is selected from a metal with a relative atomic mass greater than 40;
Lₐ, L_{b}, and L_{c} are a first ligand, a second ligand, and a third ligand coordinated to the metal M, respectively; Lₐ, L_{b}, and L_{c} may be identical or different;
Lₐ, L_{b}, and L_{c} can be optionally joined to form a multidentate ligand;
m is 1, 2, or 3, n is 0, 1, or 2, q is 0, 1, or 2, and m+n+q is equal to the oxidation state of the metal M; when m is greater than or equal to 2, multiple Lₐ may be identical or different; when n is 2, two L_{b} may be identical or different; when q is 2, two L_{c} may be identical or different;
the ligand Lₐ has a structure represented by Formula 3:

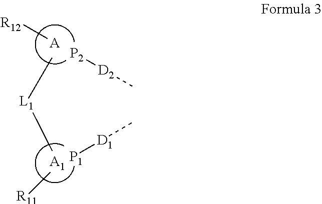

the ring A₁ and the ring A₂ are, at each occurrence identically or differently, selected from a substituted or unsubstituted aromatic ring having 5 to 30 ring atoms, a substituted or unsubstituted heteroaromatic ring having 5 to 30 ring atoms, or a combination thereof;
P₁ and P₂ are, at each occurrence identically or differently, selected from C or N;
D₁ and D₂ are, at each occurrence identically or differently, selected from a single bond, O, or S;
L₁ is selected from the group consisting of: a single bond, BR′, CR′IR′₁, NR′₁, O, SiR′₁R′₁, PR′₁, S, GeR′₁R′₁, Se, substituted or unsubstituted vinylene, ethynylene, substituted or unsubstituted arylene having 6 to 30 carbon atoms, substituted or unsubstituted heteroarylene having 5 to 30 carbon atoms, and combinations thereof; when two R′ are present at the same time, the two R′ are identical or different;
R₁₁ and R₁₂ represent, at each occurrence identically or differently, mono-substitution, multiple substitutions, or non-substitution;
R₁₁, R₁₂, and R′₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁₁, R₁₂, and R′₁ can be optionally joined to form a ring; and
the ligands L_{b} and L_{c} are, at each occurrence identically or differently, selected from a monoanionic bidentate ligand.

In this embodiment, the expression that “adjacent substituents R₁₁, R₁₂, and R′₁ can be optionally joined to form a ring” is intended to mean that any one or more of groups of adjacent substituents, such as two substituents R₁₁, two substituents R₁₂, two substituents R′₁, and substituents R₁₁ and R₁₂, may be joined to form a ring. Obviously, it is also possible that none of these substituents are joined to form a ring.

According to an embodiment of the present disclosure, the emissive layer comprises a host material.

According to an embodiment of the present disclosure, the host material is a host compound.

According to an embodiment of the present disclosure, the emissive layer comprises at least one first host compound.

According to an embodiment of the present disclosure, the emissive layer further comprises at least two host compounds.

According to an embodiment of the present disclosure, at least one of the host compounds comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to another embodiment of the present disclosure, the first host compound has a structure represented by Formula X-1 or Formula X-2:

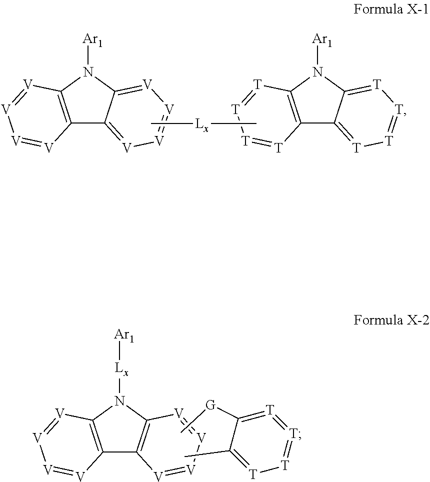

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
G is, at each occurrence identically or differently, selected from C(R_{g})₂, NR_{g}, O, or S;
V is, at each occurrence identically or differently, selected from C, CRᵥ, or N;
in Formula X-1, T is, at each occurrence identically or differently, selected from C, CR_{T}, or N;
in Formula X-2, T is, at each occurrence identically or differently, selected from CR_{T} or N;
R_{g}, Rᵥ, and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms, or a combination thereof; and
adjacent substituents R_{g}, Rᵥ, and R_{T} can be optionally joined to form a ring.

In this embodiment, the expression that “adjacent substituents R_{g}, Rᵥ, and R_{T} can be optionally joined to form a ring” is intended to mean that any one or more of groups of adjacent substituents, such as two substituents Rᵥ, two substituents R_{T}, two substituents R_{g}, substituents Rᵥ and R_{T}, substituents Rᵥ and R_{g}, and substituents R_{g} and R_{T}, may be joined to form a ring. Obviously, it is also possible that none of these substituents are joined to form a ring.

According to an embodiment of the present disclosure, the first host compound has a structure represented by one of Formula X-a to Formula X-p:

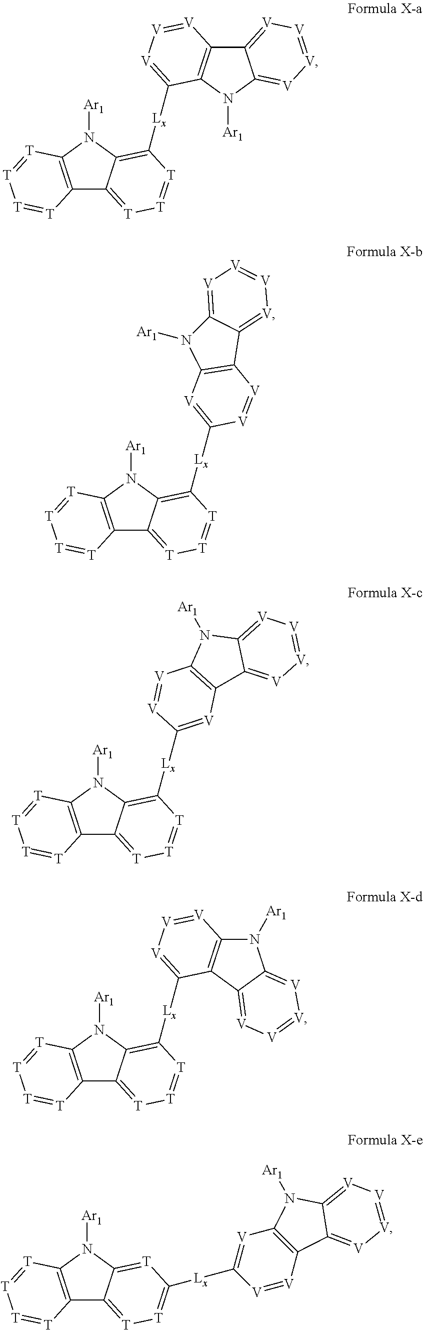

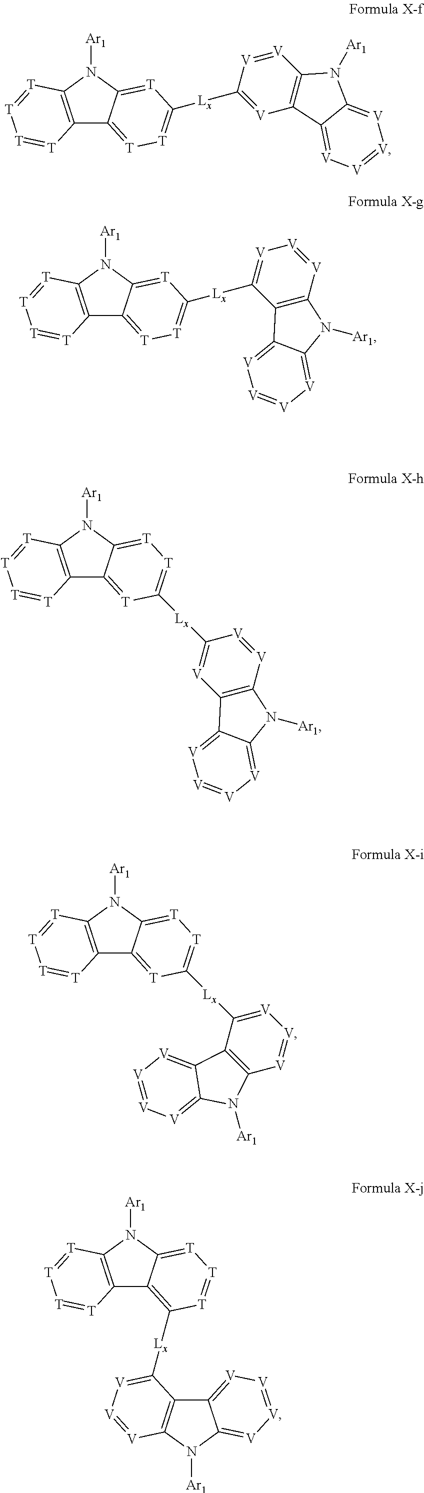

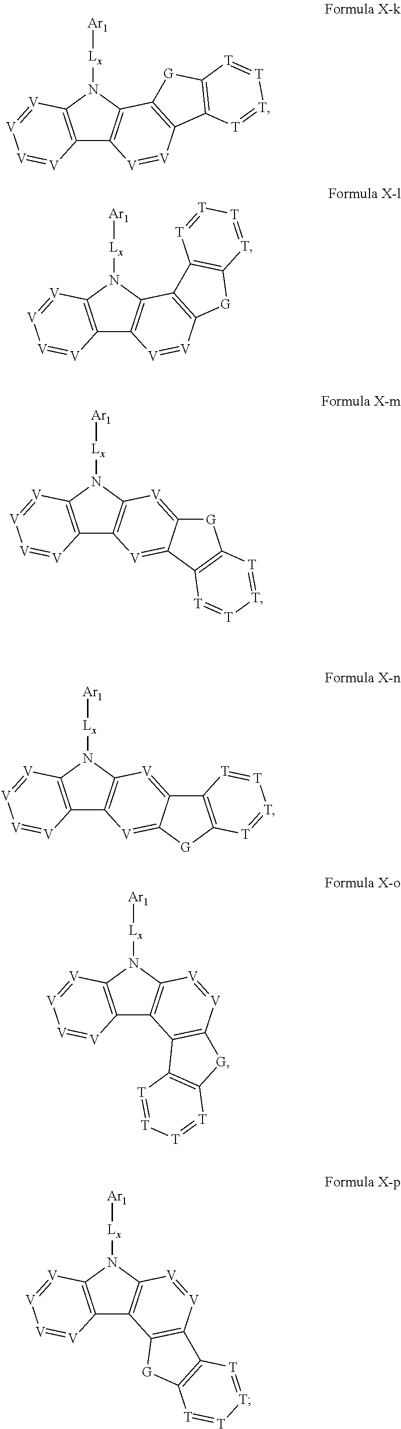

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
G is, at each occurrence identically or differently, selected from C(R_{g})₂, NR_{g}, O, or S;
V is, at each occurrence identically or differently, selected from CRᵥ or N;
T is, at each occurrence identically or differently, selected from CR_{T} or N;
R_{g}, Rᵥ, and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms, or a combination thereof; and
adjacent substituents R_{g}, Rᵥ, and R_{T} can be optionally joined to form a ring.

According to an embodiment of the present disclosure, the first host compound is selected from the group consisting of the following compounds:

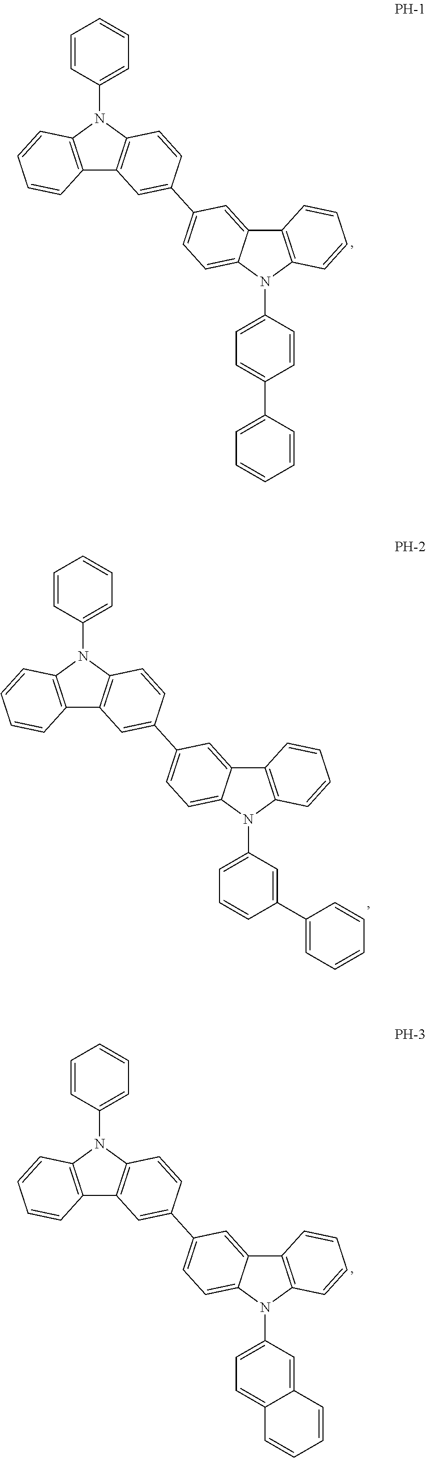 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccc5ccccc5c4)ccc32)cc1]

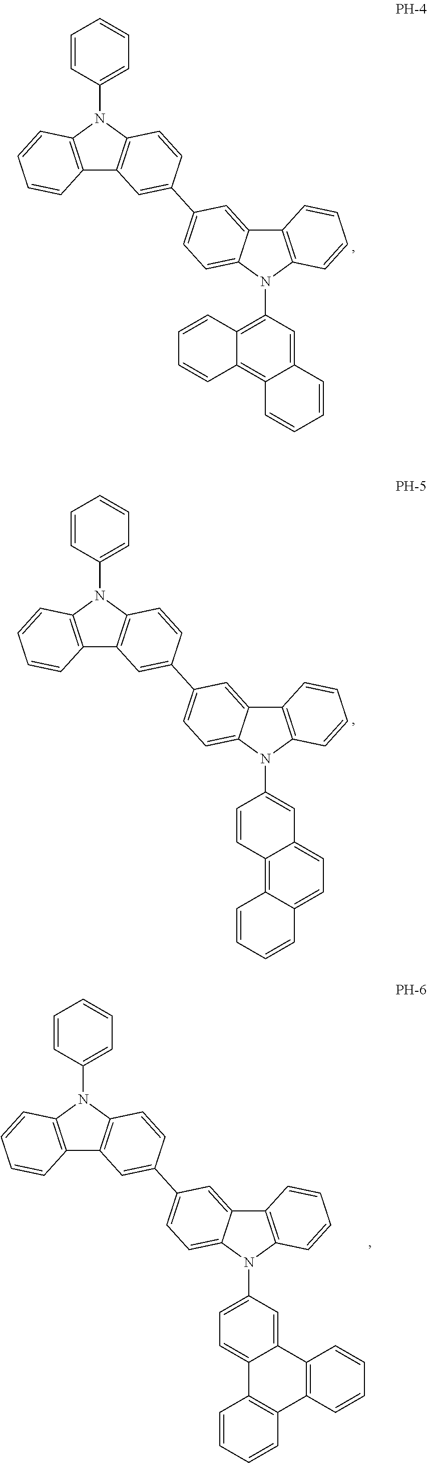 [SMILES: c1ccc(-n2c3ccccc3c3cc(-c4ccc5c(c4)c4ccccc4n5-c4cc5ccccc5c5ccccc45)ccc32)cc1 ; c1ccc(-n2c3ccccc3c3cc(-c4ccc5c(c4)c4ccccc4n5-c4ccc5c(ccc6ccccc65)c4)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

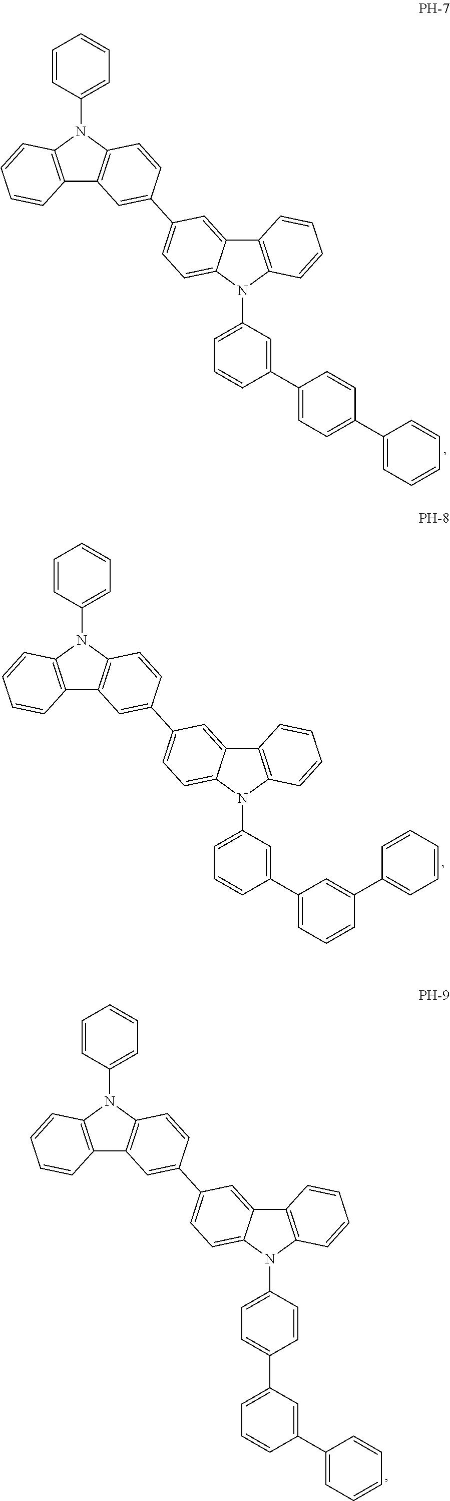 [SMILES: c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cccc(-c3ccc(-n4c5ccccc5c5cc(-c6ccc7c(c6)c6ccccc6n7-c6ccccc6)ccc54)cc3)c2)cc1]

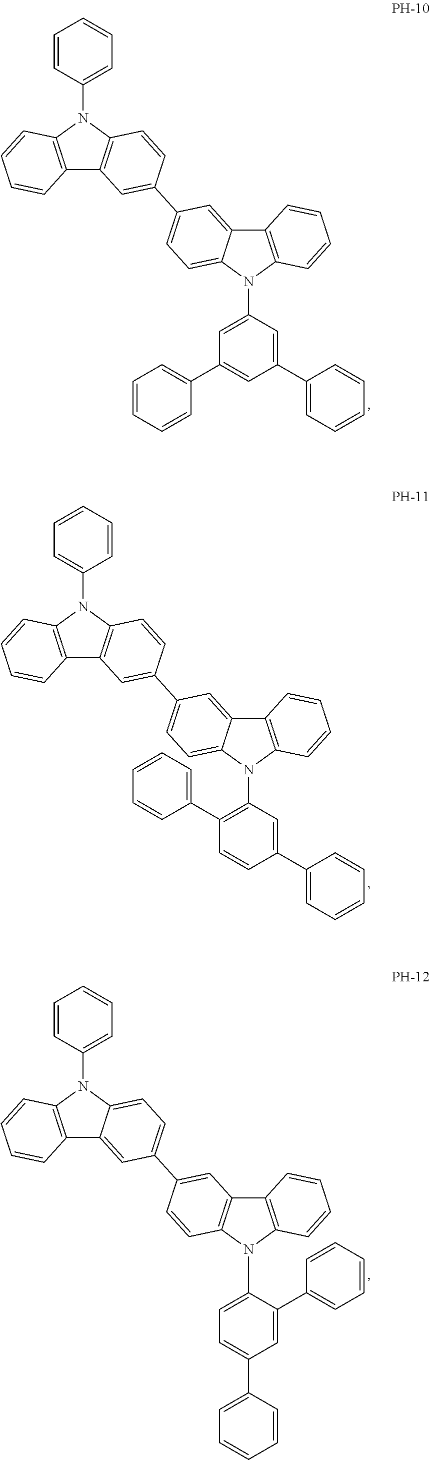 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-c3ccccc3)c(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccccc5)ccc43)c(-c3ccccc3)c2)cc1]

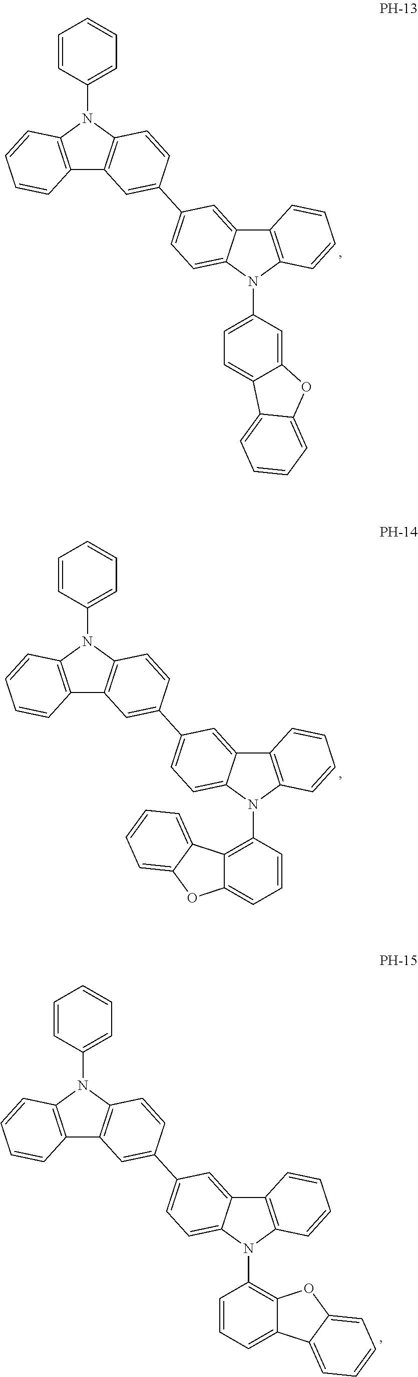 [SMILES: c1ccc(-n2c3ccccc3c3cc(-c4ccc5c(c4)c4ccccc4n5-c4ccc5c(c4)oc4ccccc45)ccc32)cc1 ; c1ccc(-n2c3ccccc3c3cc(-c4ccc5c(c4)c4ccccc4n5-c4cccc5oc6ccccc6c45)ccc32)cc1 ; c1ccc(-n2c3ccccc3c3cc(-c4ccc5c(c4)c4ccccc4n5-c4cccc5c4oc4ccccc45)ccc32)cc1]

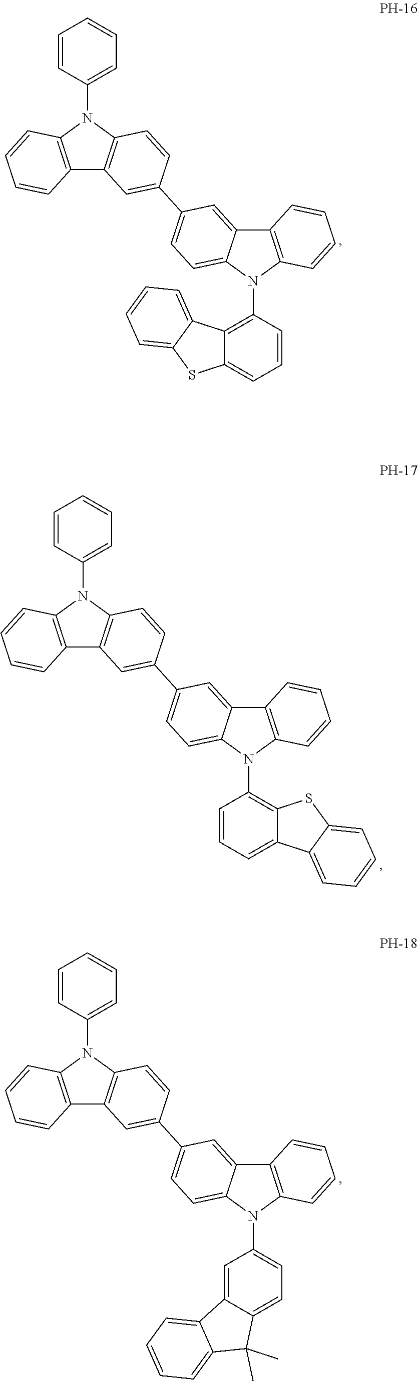 [SMILES: c1ccc(-n2c3ccccc3c3cc(-c4ccc5c(c4)c4ccccc4n5-c4cccc5sc6ccccc6c45)ccc32)cc1 ; c1ccc(-n2c3ccccc3c3cc(-c4ccc5c(c4)c4ccccc4n5-c4cccc5c4sc4ccccc45)ccc32)cc1 ; CC1(C)c2ccccc2-c2cc(-n3c4ccccc4c4cc(-c5ccc6c(c5)c5ccccc5n6-c5ccccc5)ccc43)ccc21]

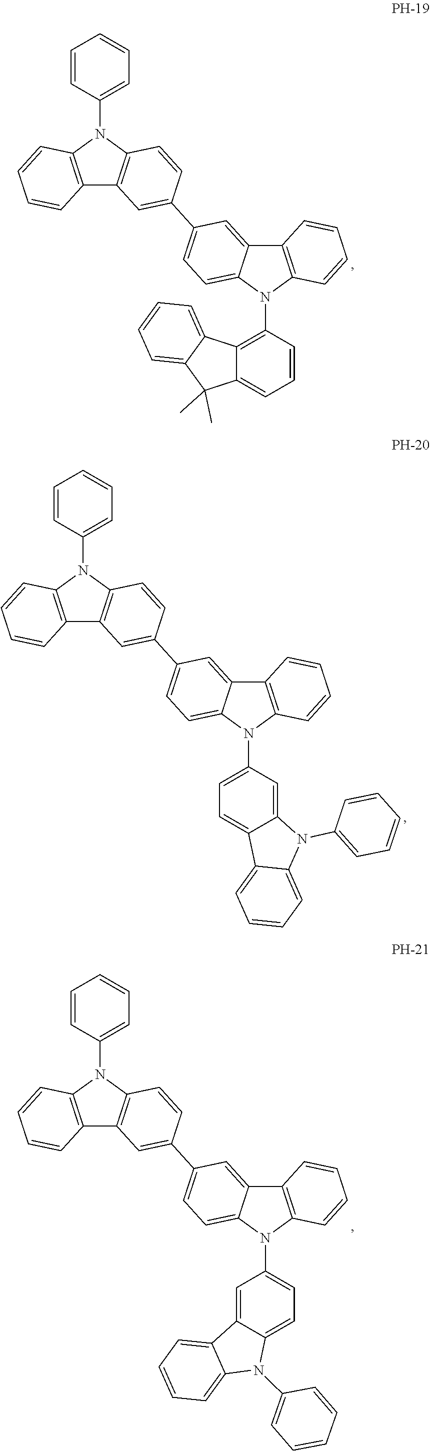 [SMILES: CC1(C)c2ccccc2-c2c(-n3c4ccccc4c4cc(-c5ccc6c(c5)c5ccccc5n6-c5ccccc5)ccc43)cccc21 ; c1ccc(-n2c3ccccc3c3cc(-c4ccc5c(c4)c4ccccc4n5-c4ccc5c6ccccc6n(-c6ccccc6)c5c4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1]

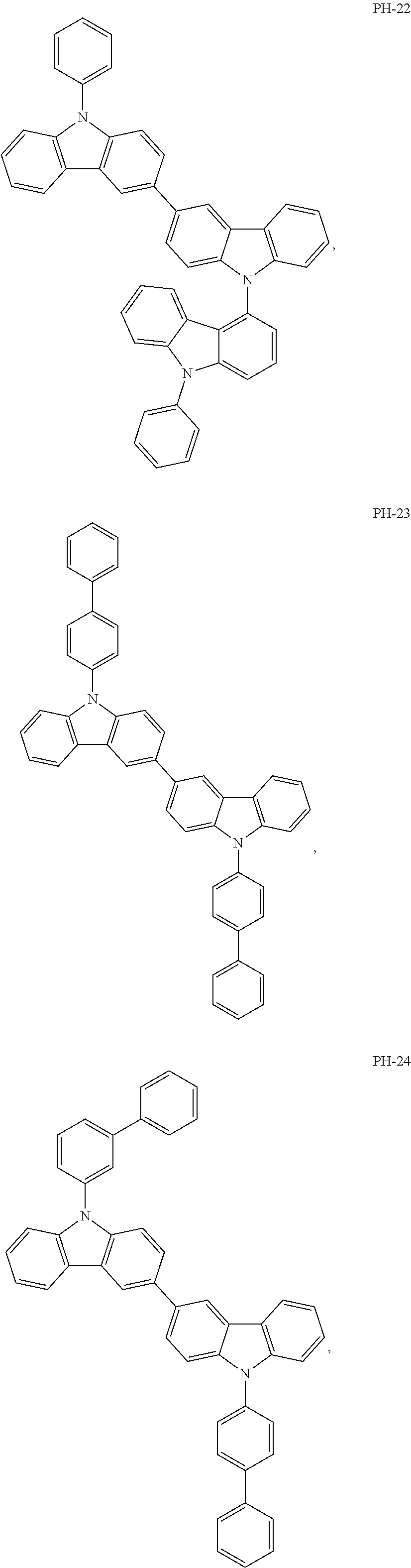 [SMILES: c1ccc(-n2c3ccccc3c3cc(-c4ccc5c(c4)c4ccccc4n5-c4cccc5c4c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

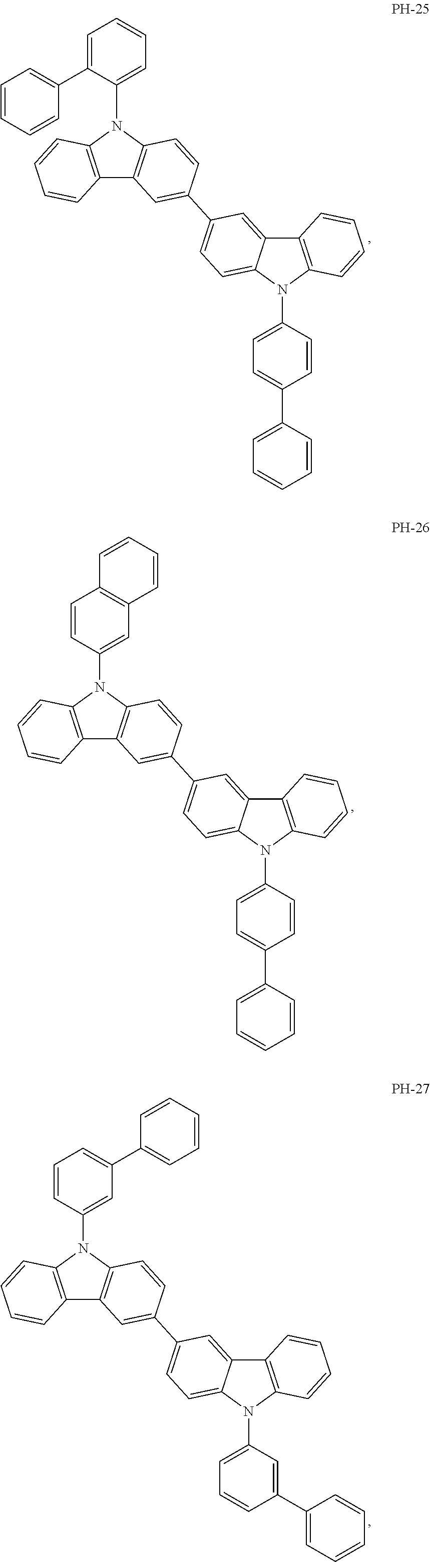 [SMILES: c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1]

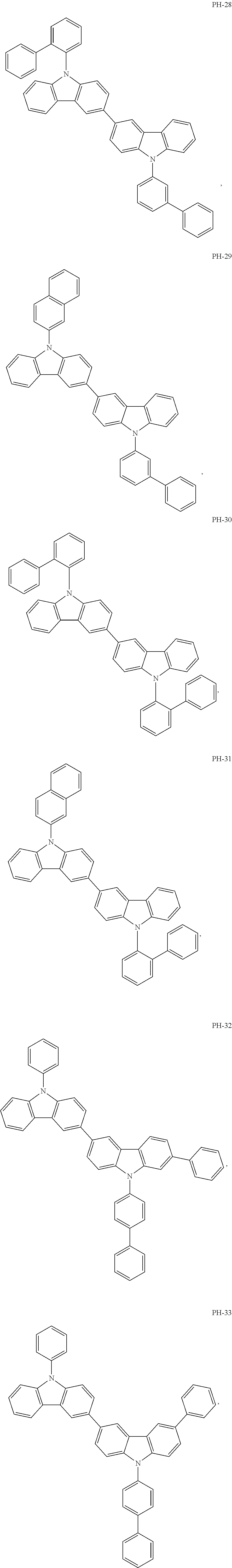

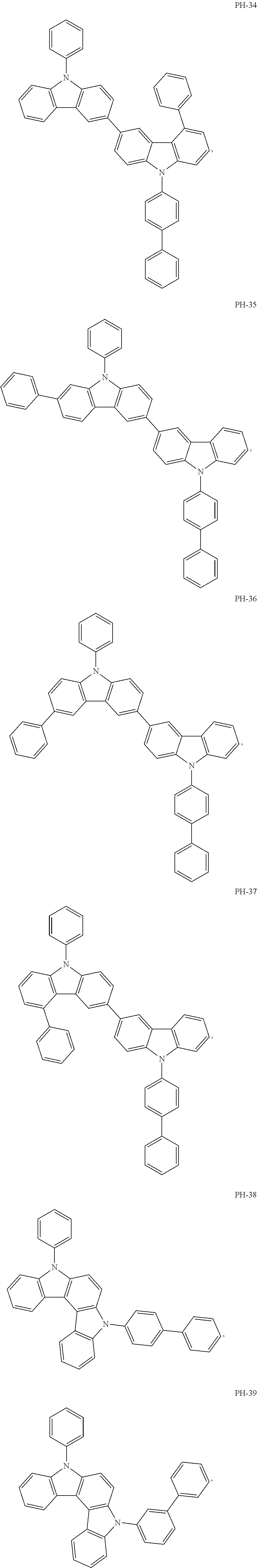 [SMILES: c1ccc(-c2ccc(-n3c4ccc(-c5ccc6c(c5)c5ccccc5n6-c5ccccc5)cc4c4c(-c5ccccc5)cccc43)cc2)cc1 ; c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2ccc(-n3c4ccccc4c4cc(-c5ccc6c(c5)c5cc(-c7ccccc7)ccc5n6-c5ccccc5)ccc43)cc2)cc1 ; c1ccc(-c2ccc(-n3c4ccccc4c4cc(-c5ccc6c(c5)c5c(-c7ccccc7)cccc5n6-c5ccccc5)ccc43)cc2)cc1 ; c1ccc(-c2ccc(-n3c4ccccc4c4c5c6ccccc6n(-c6ccccc6)c5ccc43)cc2)cc1 ; c1ccc(-c2cccc(-n3c4ccccc4c4c5c6ccccc6n(-c6ccccc6)c5ccc43)c2)cc1]

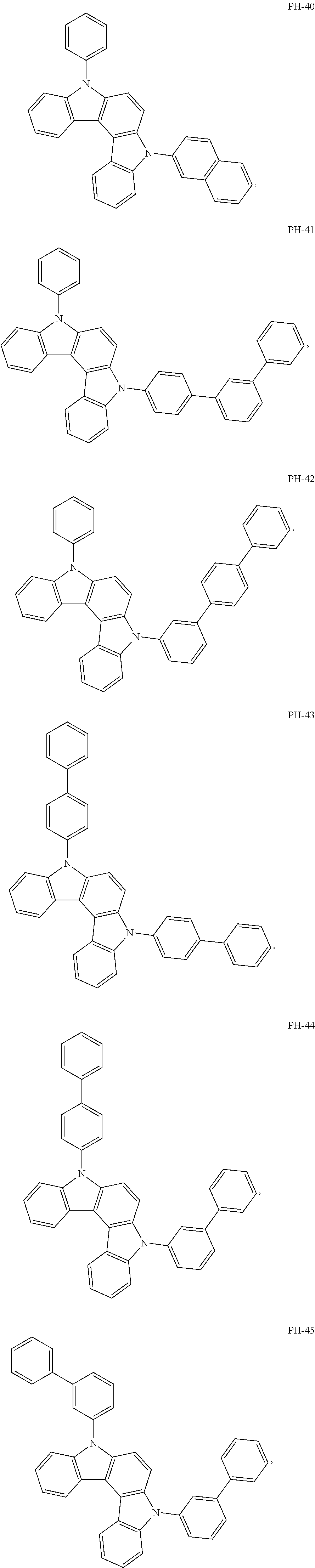 [SMILES: c1ccc(-n2c3ccccc3c3c4c5ccccc5n(-c5ccc6ccccc6c5)c4ccc32)cc1 ; c1ccc(-c2cccc(-c3ccc(-n4c5ccccc5c5c6c7ccccc7n(-c7ccccc7)c6ccc54)cc3)c2)cc1 ; c1ccc(-c2ccc(-c3cccc(-n4c5ccccc5c5c6c7ccccc7n(-c7ccccc7)c6ccc54)c3)cc2)cc1 ; c1ccc(-c2ccc(-n3c4ccccc4c4c5c6ccccc6n(-c6ccc(-c7ccccc7)cc6)c5ccc43)cc2)cc1 ; c1ccc(-c2ccc(-n3c4ccccc4c4c5c6ccccc6n(-c6cccc(-c7ccccc7)c6)c5ccc43)cc2)cc1 ; c1ccc(-c2cccc(-n3c4ccccc4c4c5c6ccccc6n(-c6cccc(-c7ccccc7)c6)c5ccc43)c2)cc1]

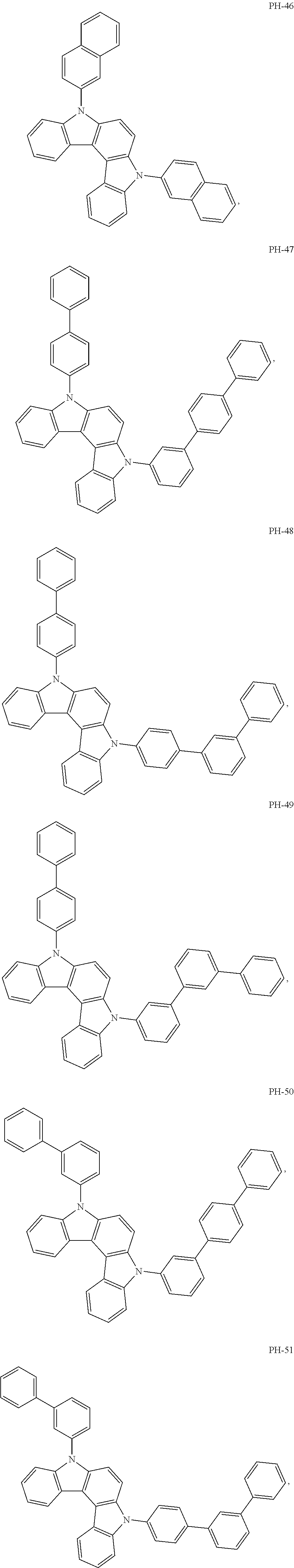

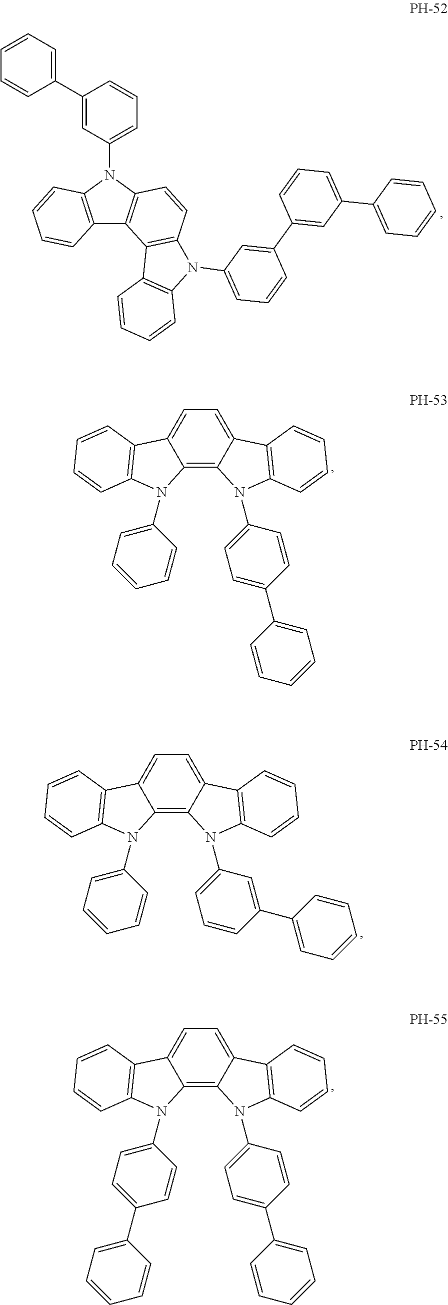 [SMILES: c1ccc(-c2cccc(-c3cccc(-n4c5ccccc5c5c6c7ccccc7n(-c7cccc(-c8ccccc8)c7)c6ccc54)c3)c2)cc1 ; c1ccc(-c2ccc(-n3c4ccccc4c4ccc5c6ccccc6n(-c6ccccc6)c5c43)cc2)cc1 ; c1ccc(-c2cccc(-n3c4ccccc4c4ccc5c6ccccc6n(-c6ccccc6)c5c43)c2)cc1 ; c1ccc(-c2ccc(-n3c4ccccc4c4ccc5c6ccccc6n(-c6ccc(-c7ccccc7)cc6)c5c43)cc2)cc1]

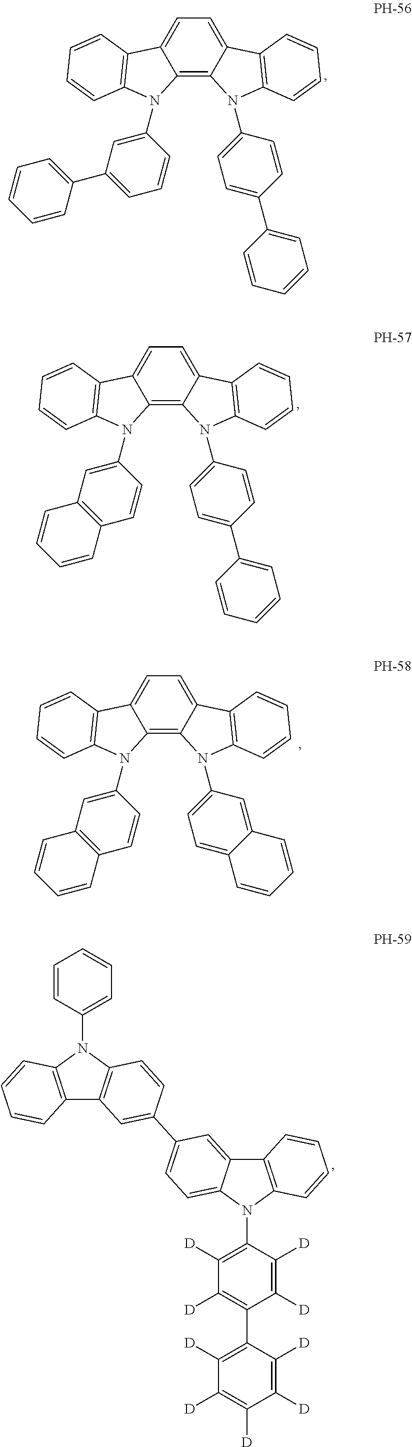 [SMILES: c1ccc(-c2ccc(-n3c4ccccc4c4ccc5c6ccccc6n(-c6cccc(-c7ccccc7)c6)c5c43)cc2)cc1 ; c1ccc(-c2ccc(-n3c4ccccc4c4ccc5c6ccccc6n(-c6ccc7ccccc7c6)c5c43)cc2)cc1 ; c1ccc2cc(-n3c4ccccc4c4ccc5c6ccccc6n(-c6ccc7ccccc7c6)c5c43)ccc2c1 ; [2H]c1c([2H])c([2H])c(-c2c([2H])c([2H])c(-n3c4ccccc4c4cc(-c5ccc6c(c5)c5ccccc5n6-c5ccccc5)ccc43)c([2H])c2[2H])c([2H])c1[2H]]

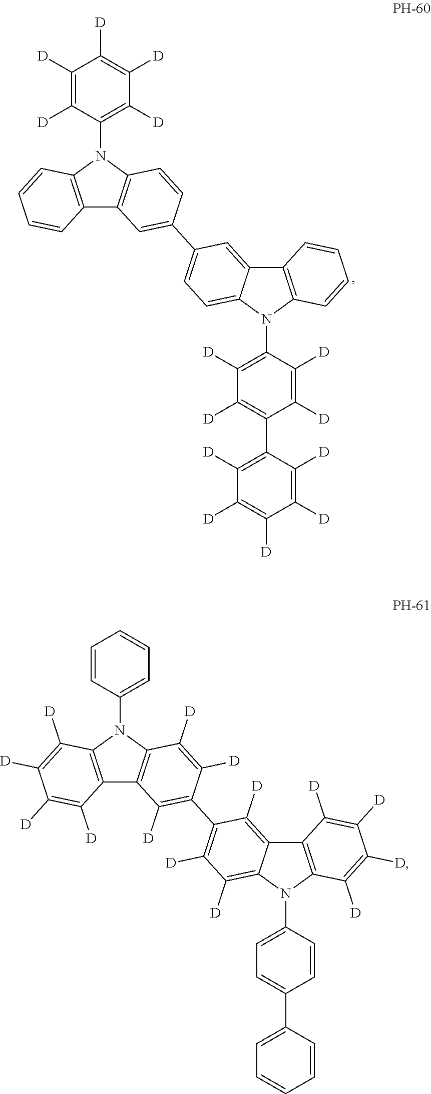

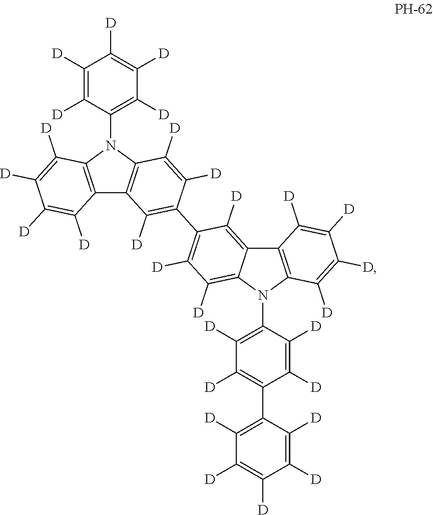

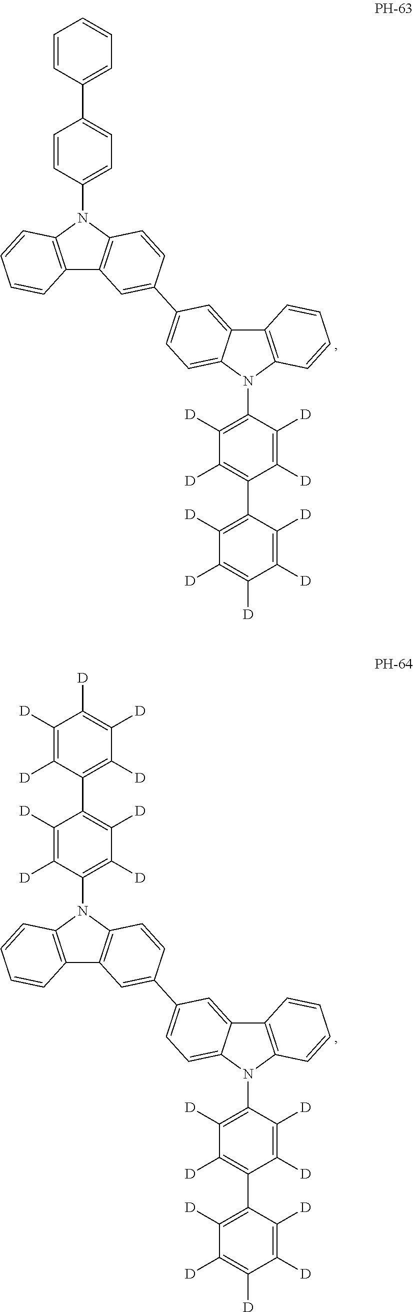 [SMILES: [2H]c1c([2H])c([2H])c(-c2c([2H])c([2H])c(-n3c4ccccc4c4cc(-c5ccc6c(c5)c5ccccc5n6-c5ccc(-c6ccccc6)cc5)ccc43)c([2H])c2[2H])c([2H])c1[2H] ; [2H]c1c([2H])c([2H])c(-c2c([2H])c([2H])c(-n3c4ccccc4c4cc(-c5ccc6c(c5)c5ccccc5n6-c5c([2H])c([2H])c(-c6c([2H])c([2H])c([2H])c([2H])c6[2H])c([2H])c5[2H])ccc43)c([2H])c2[2H])c([2H])c1[2H]]

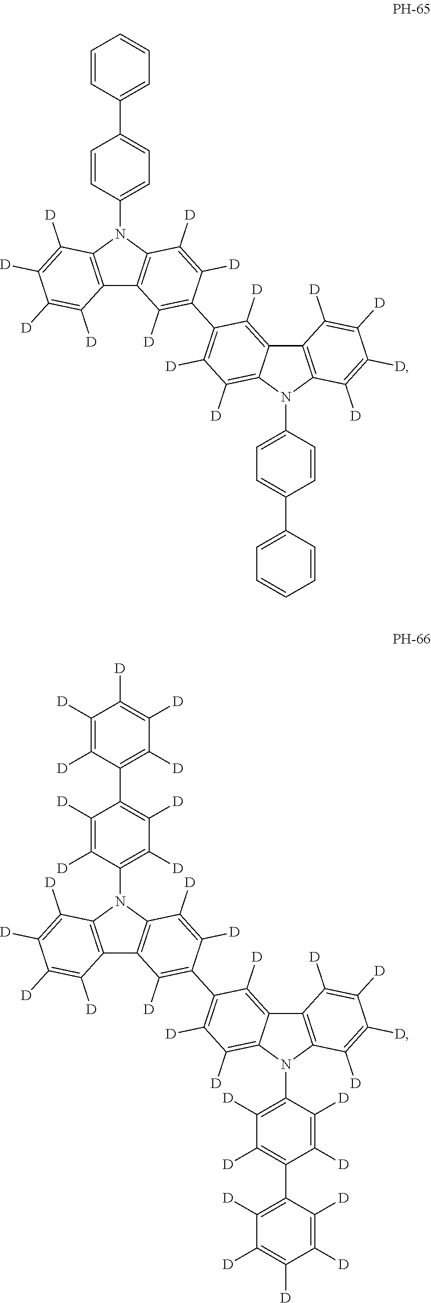

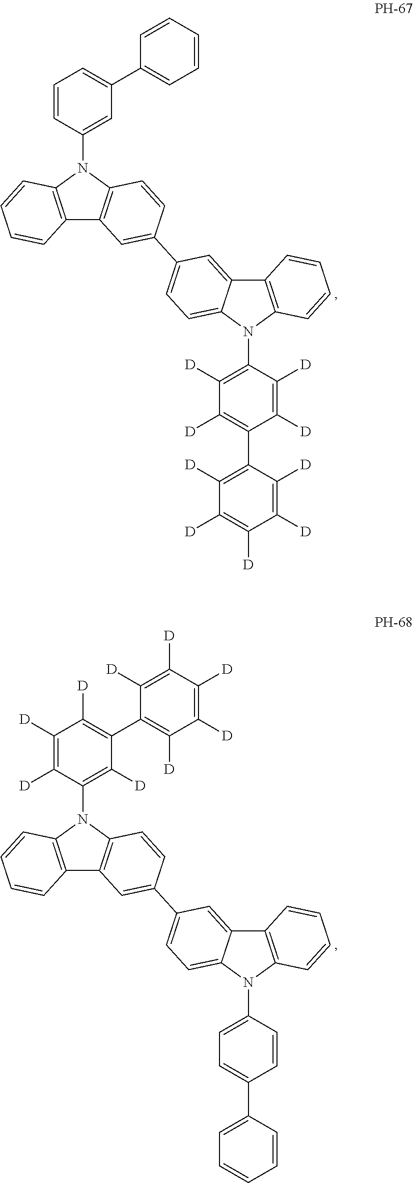 [SMILES: [2H]c1c([2H])c([2H])c(-c2c([2H])c([2H])c(-n3c4ccccc4c4cc(-c5ccc6c(c5)c5ccccc5n6-c5cccc(-c6ccccc6)c5)ccc43)c([2H])c2[2H])c([2H])c1[2H] ; [2H]c1c([2H])c([2H])c(-c2c([2H])c([2H])c([2H])c(-n3c4ccccc4c4cc(-c5ccc6c(c5)c5ccccc5n6-c5ccc(-c6ccccc6)cc5)ccc43)c2[2H])c([2H])c1[2H]]

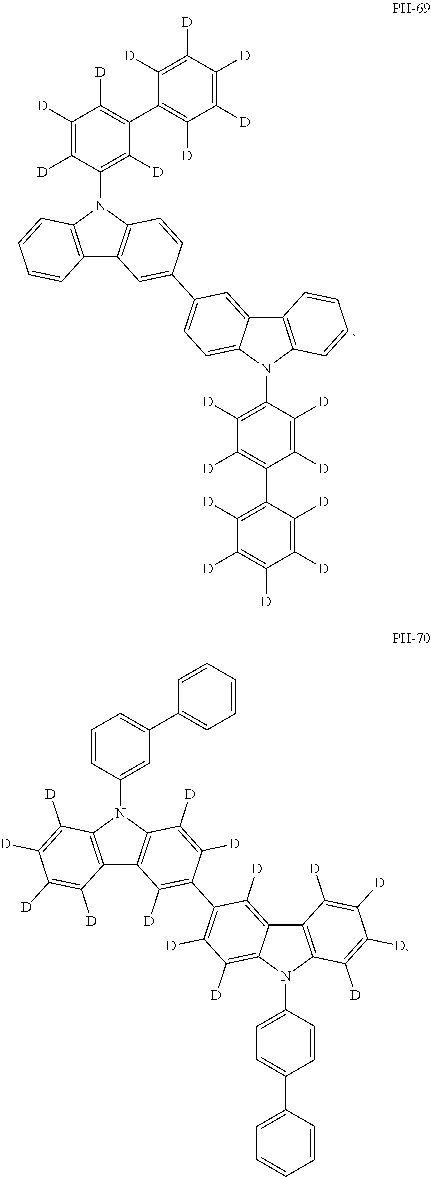

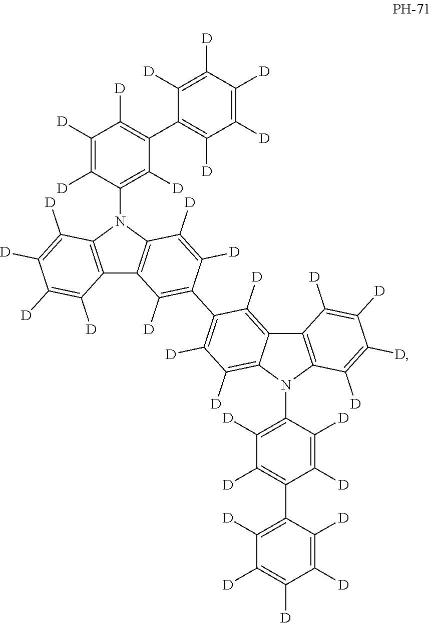

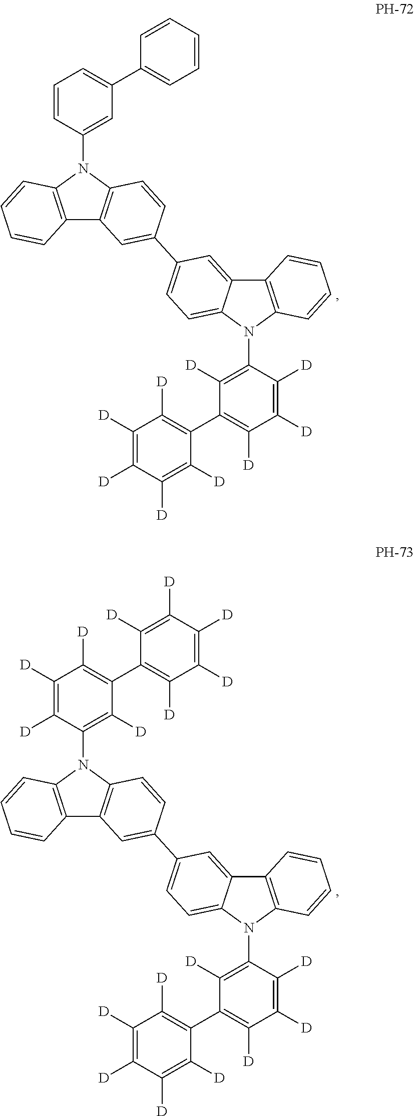 [SMILES: [2H]c1c([2H])c([2H])c(-c2c([2H])c([2H])c([2H])c(-n3c4ccccc4c4cc(-c5ccc6c(c5)c5ccccc5n6-c5cccc(-c6ccccc6)c5)ccc43)c2[2H])c([2H])c1[2H] ; [2H]c1c([2H])c([2H])c(-c2c([2H])c([2H])c([2H])c(-n3c4ccccc4c4cc(-c5ccc6c(c5)c5ccccc5n6-c5c([2H])c([2H])c([2H])c(-c6c([2H])c([2H])c([2H])c([2H])c6[2H])c5[2H])ccc43)c2[2H])c([2H])c1[2H]]

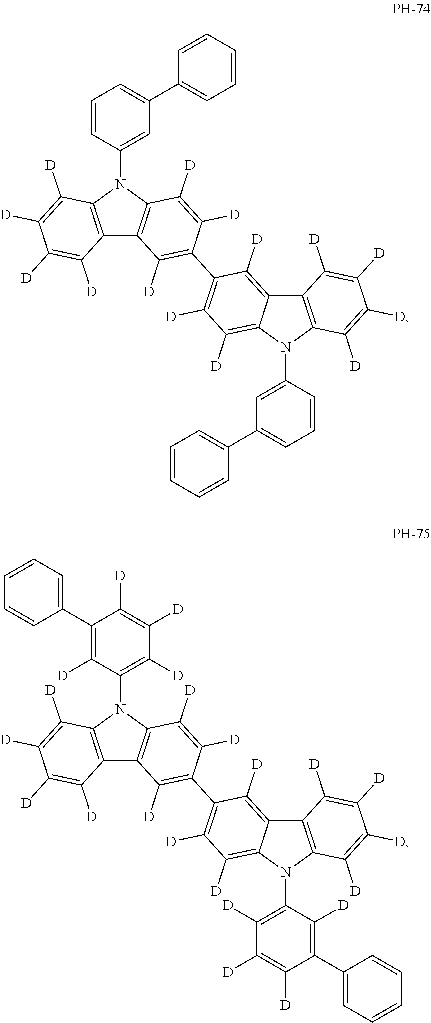

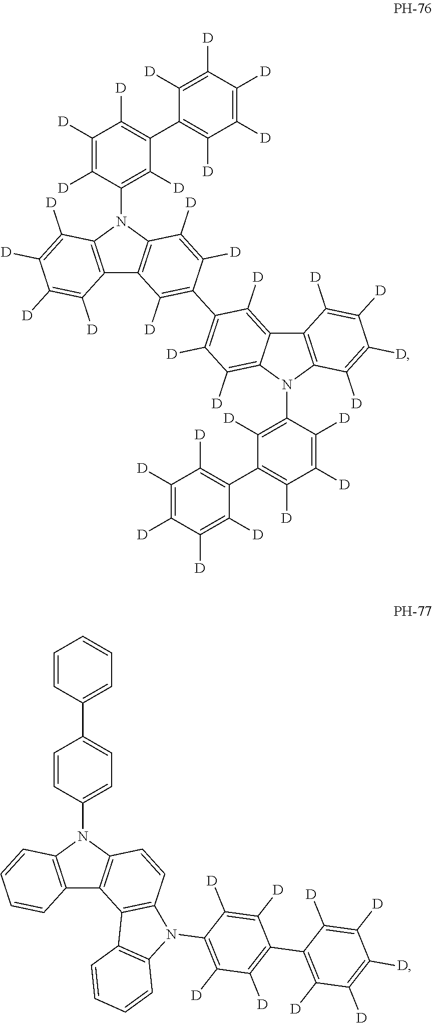

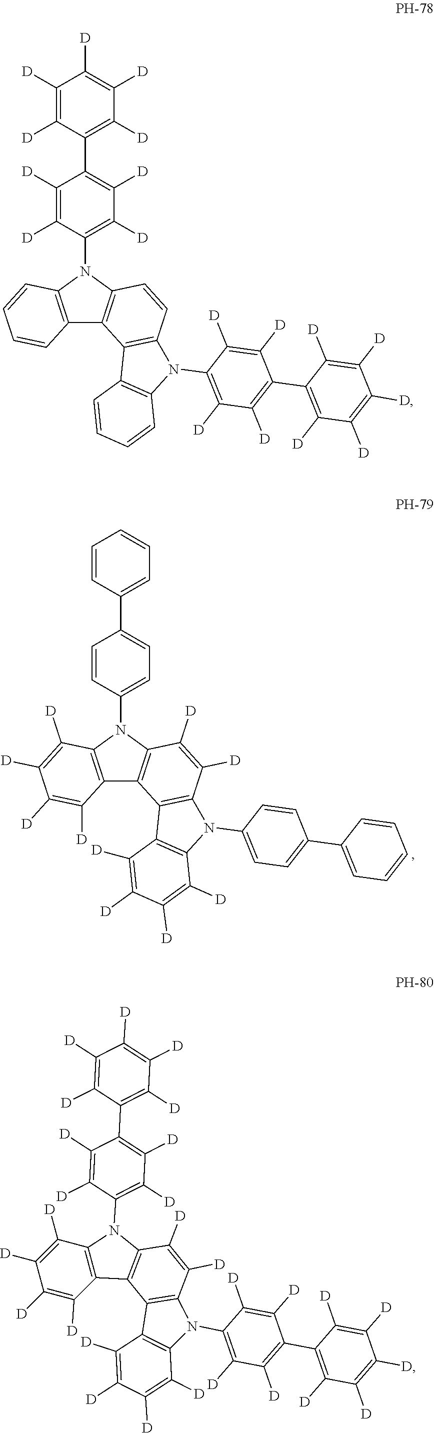

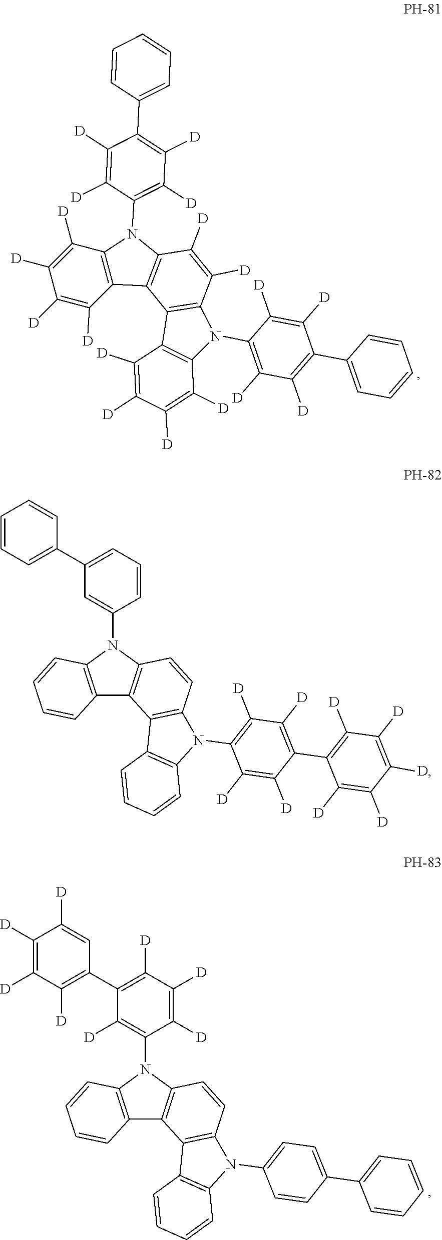

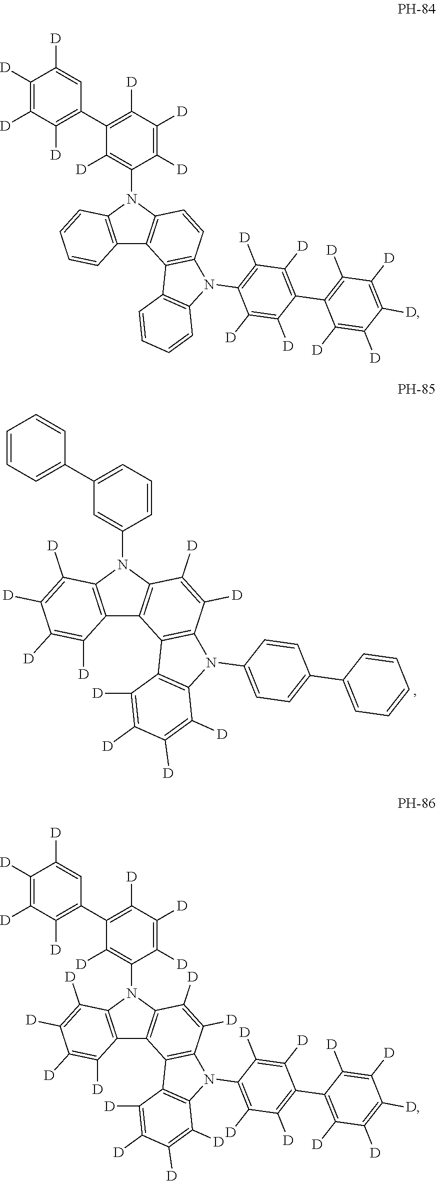

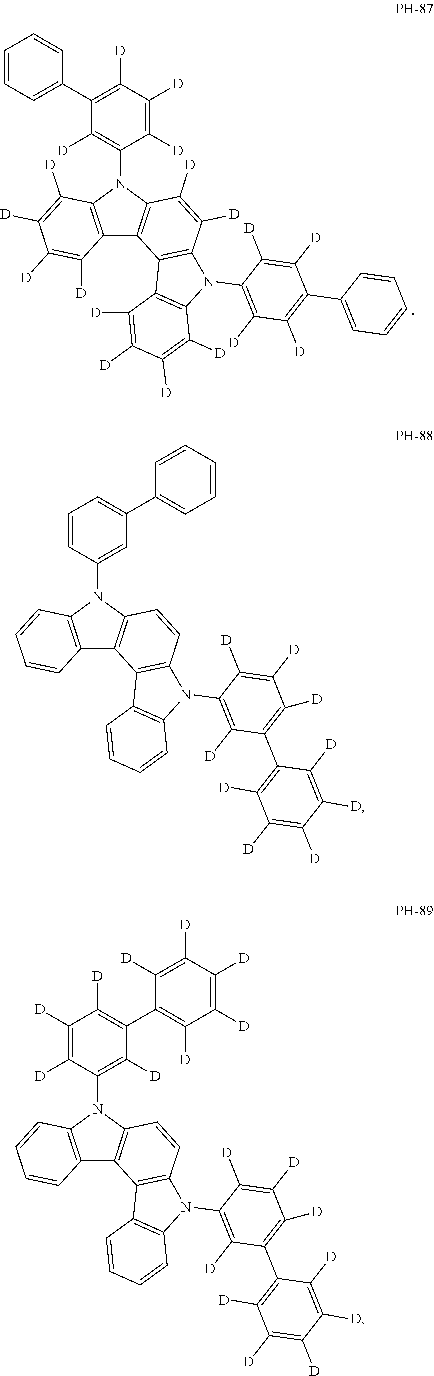

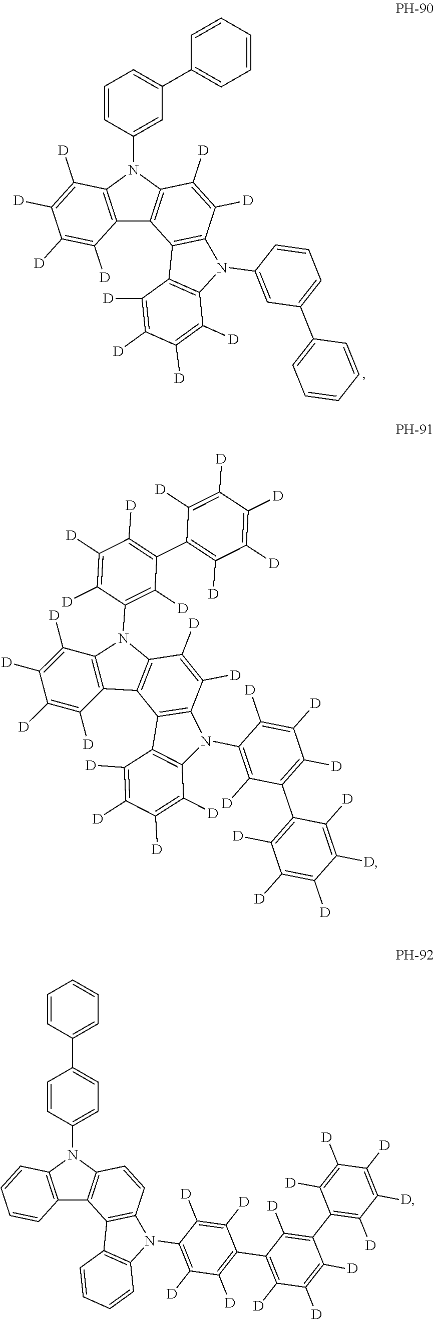

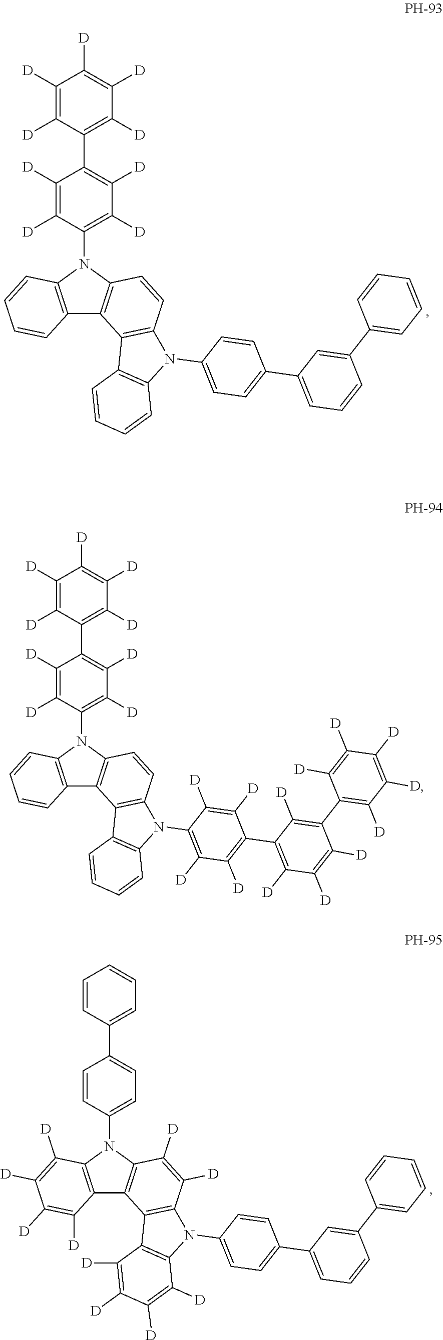

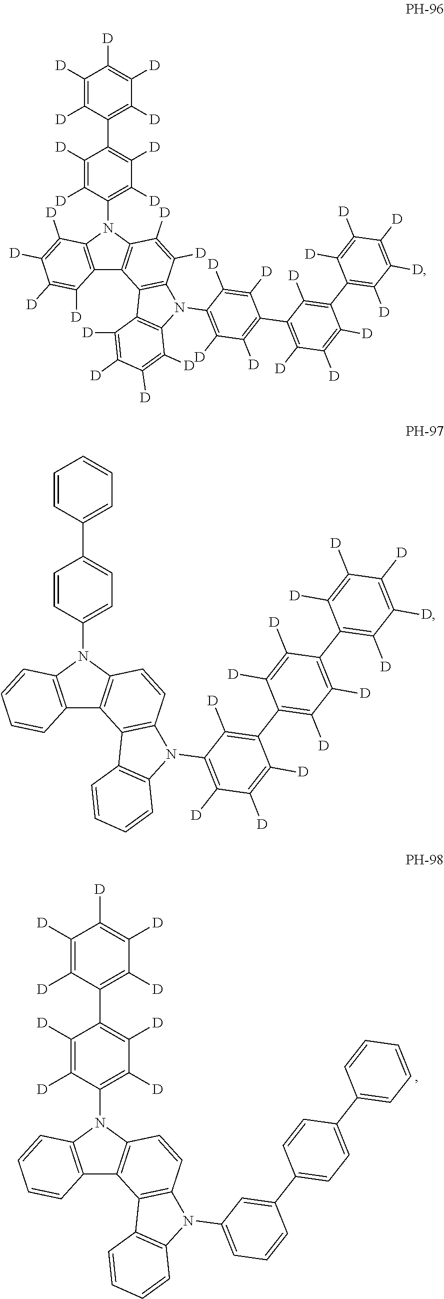

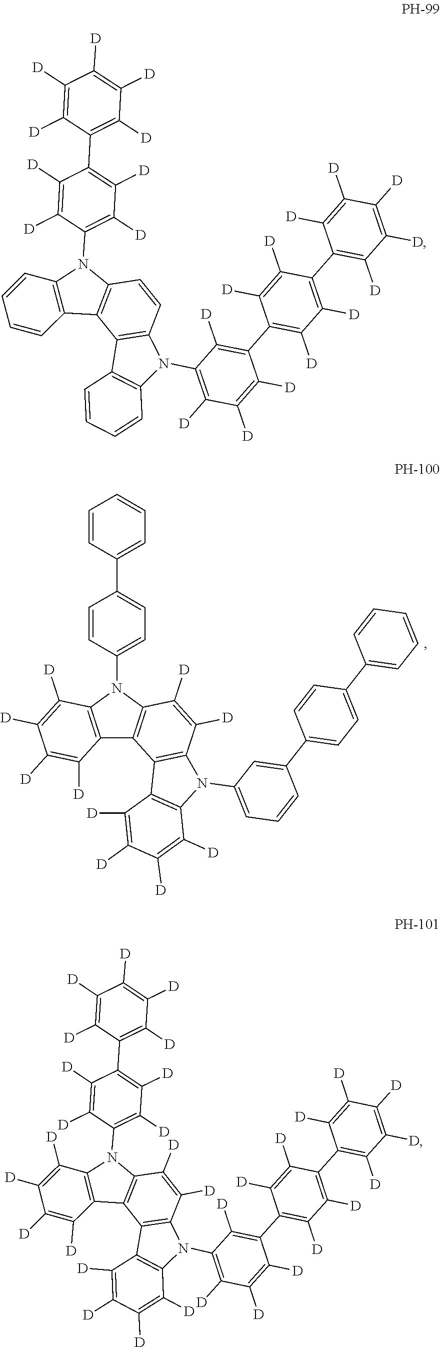

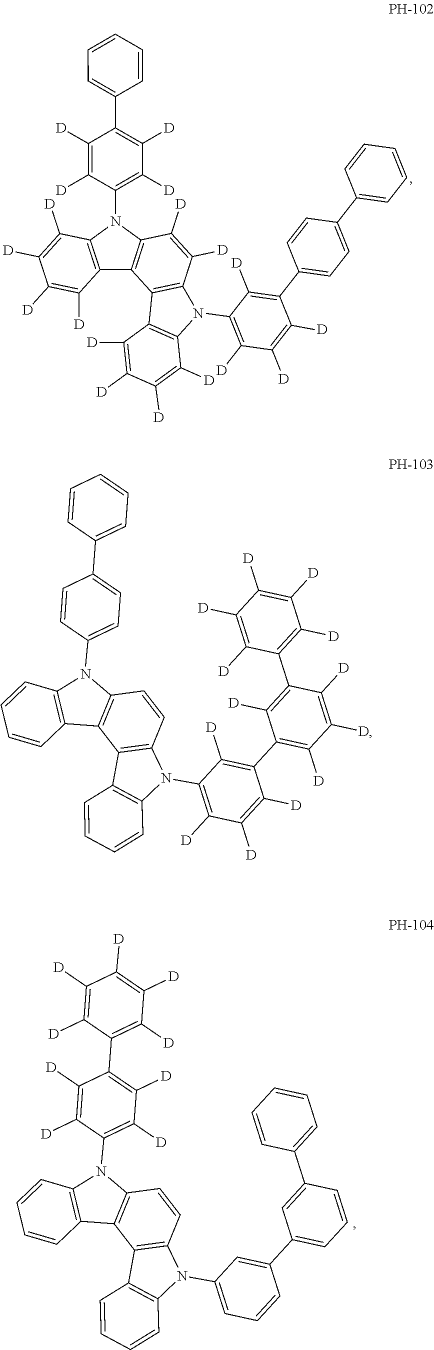

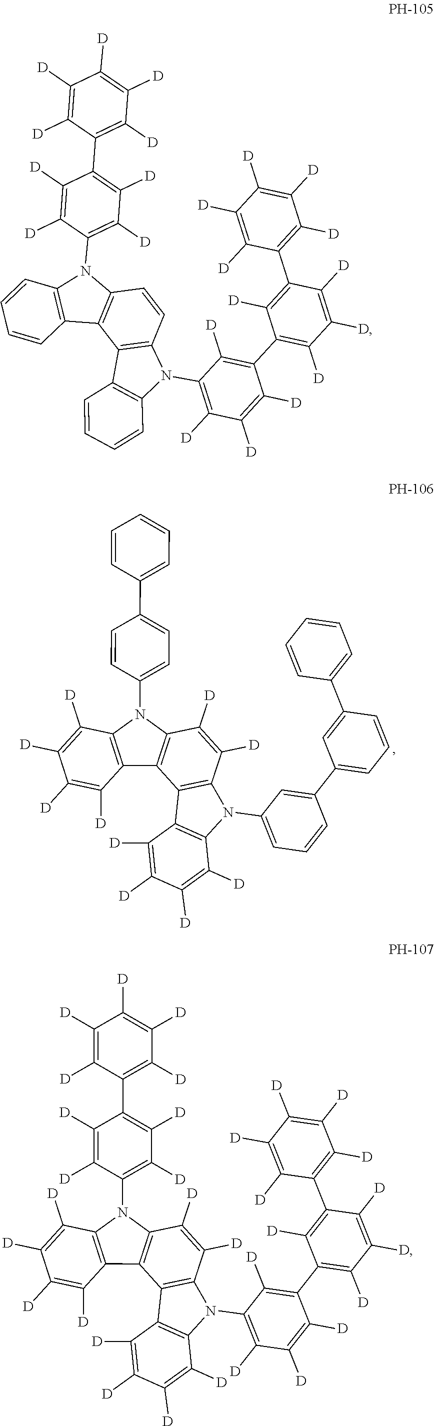

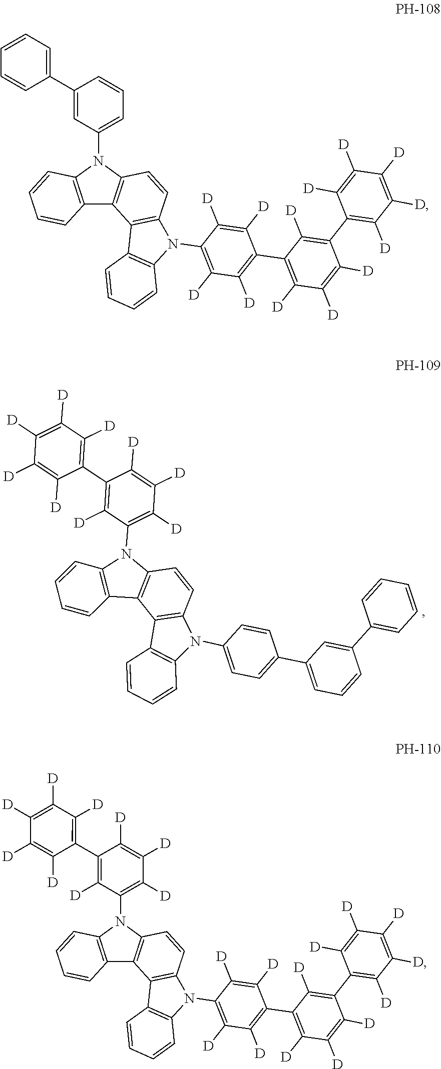

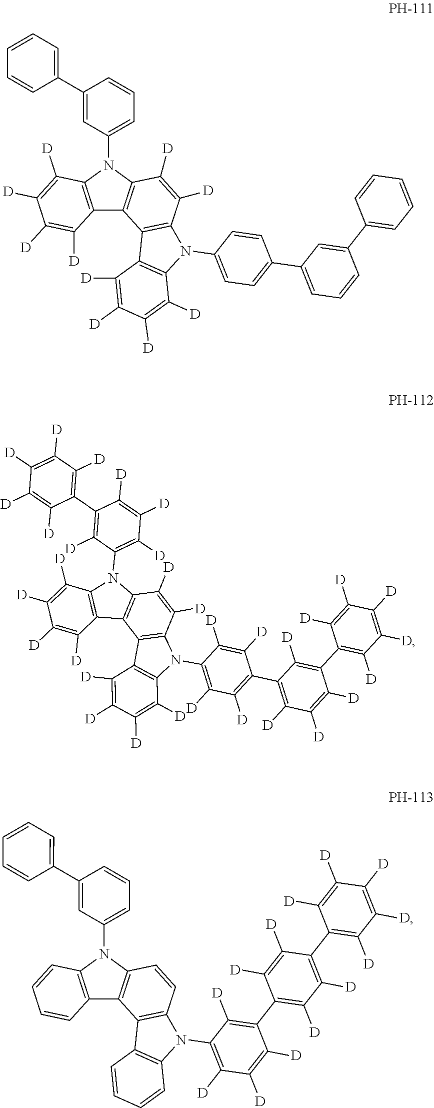

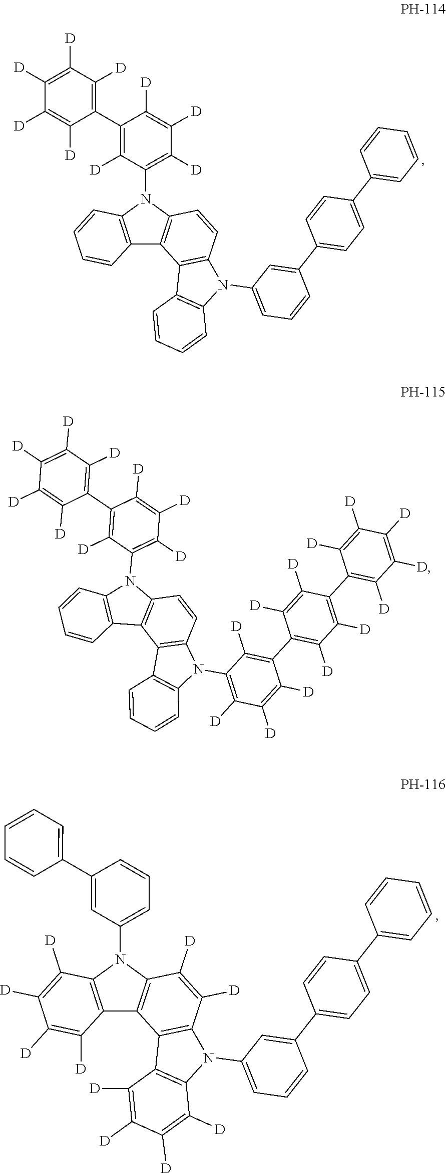

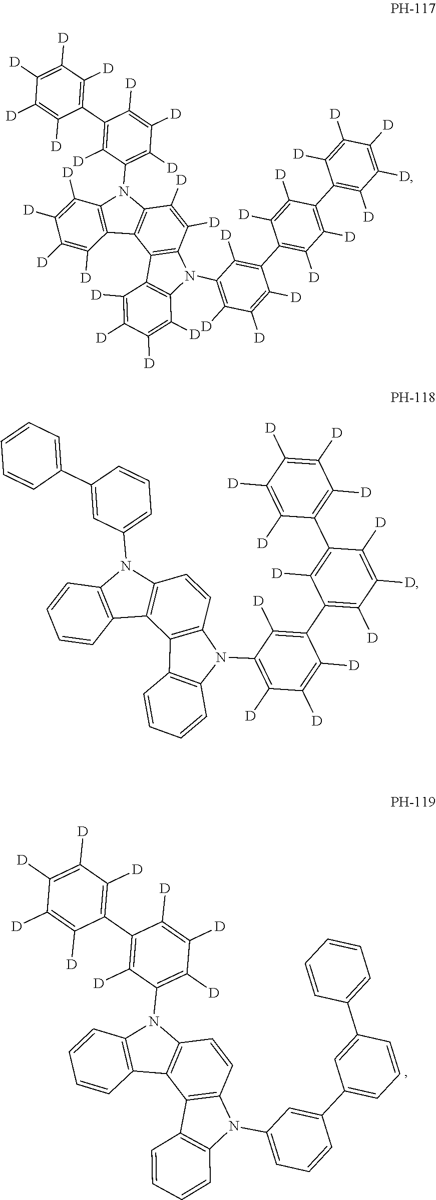

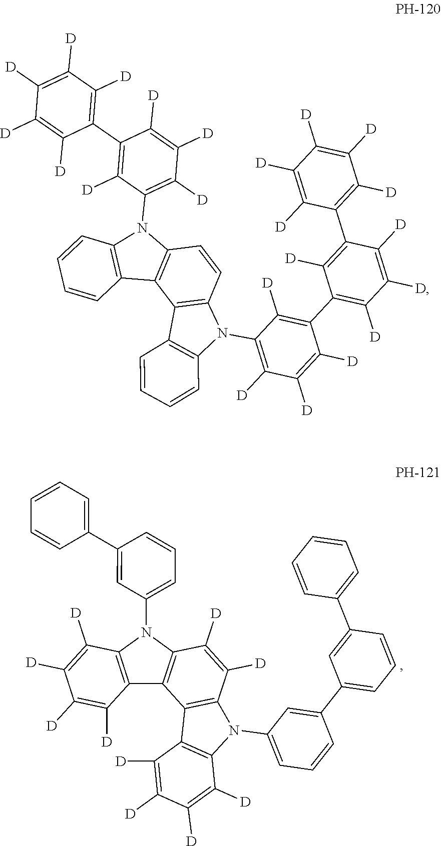

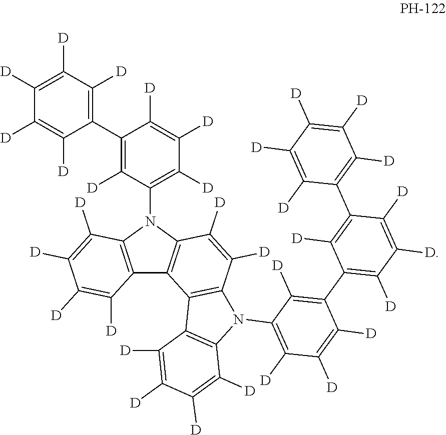

According to an embodiment of the present disclosure, the emissive layer further comprises a second host compound, and the second host compound has a structure represented by Formula Y:

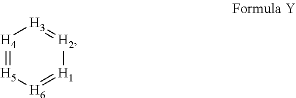

wherein,
H₁ to H₆ are, at each occurrence identically or differently, selected from C, CRₕ, or N, at least two of H₁ to H₆ are N, and at least one of H₁ to H₆ is C and joined to Formula A:

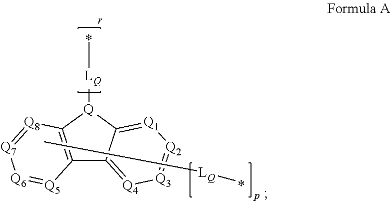

wherein,
Q is, at each occurrence identically or differently, selected from the group consisting of O, S, Se, N, NR_{Q}, CR_{Q}R_{Q}, SiR_{Q}R_{Q}, GeR_{Q}R_{Q}, and R_{Q}C═CR_{Q}; when two R_{Q} are present at the same time, the two R_{Q} may be identical or different;
p is 0 or 1; r is 0 or 1;
when Q is selected from N, p is 0, and r is 1;
when Q is selected from the group consisting of O, S, Se, NR_{Q}, CR_{Q}R_{Q}, SiR_{Q}R_{Q}, GER_{Q}R_{Q}, and R_{Q}C═CR_{Q}, p is 1, and r is 0;
L_{Q} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
Q₁ to Q₈ are, at each occurrence identically or differently, selected from C, CR_{q}, or N;
Rₕ, R_{Q}, and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
“*” represents a position where Formula A is joined to Formula Y; and
adjacent substituents Rₕ, R_{Q}, and R_{q} can be optionally joined to form a ring.

Herein, the expression that “adjacent substituents Rₕ, R_{Q}, and R_{q} can be optionally joined to form a ring” is intended to mean that any one or more of groups of adjacent substituents, such as two substituents Rn, two substituents R_{Q}, two substituents R_{q}, and two substituents R_{Q} and R_{q}, may be joined to form a ring. Obviously, it is also possible that none of these substituents are joined to form a ring.

According to an embodiment of the present disclosure, the second host compound is selected from the group consisting of the following compounds:

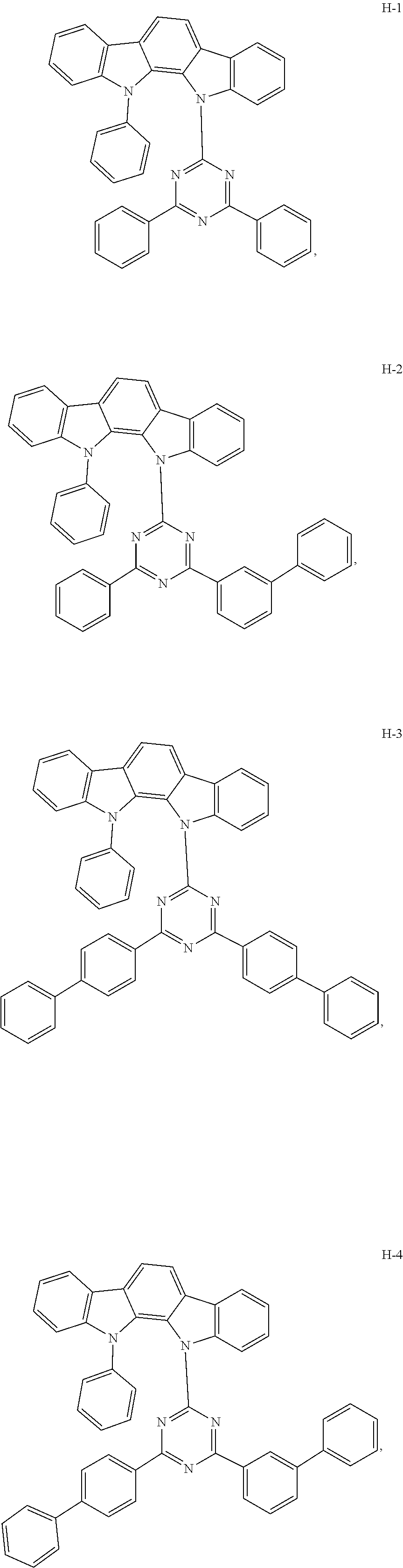 [SMILES: c1ccc(-c2nc(-c3ccccc3)nc(-n3c4ccccc4c4ccc5c6ccccc6n(-c6ccccc6)c5c43)n2)cc1 ; c1ccc(-c2cccc(-c3nc(-c4ccccc4)nc(-n4c5ccccc5c5ccc6c7ccccc7n(-c7ccccc7)c6c54)n3)c2)cc1 ; c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1 ; c1ccc(-c2ccc(-c3nc(-c4cccc(-c5ccccc5)c4)nc(-n4c5ccccc5c5ccc6c7ccccc7n(-c7ccccc7)c6c54)n3)cc2)cc1]

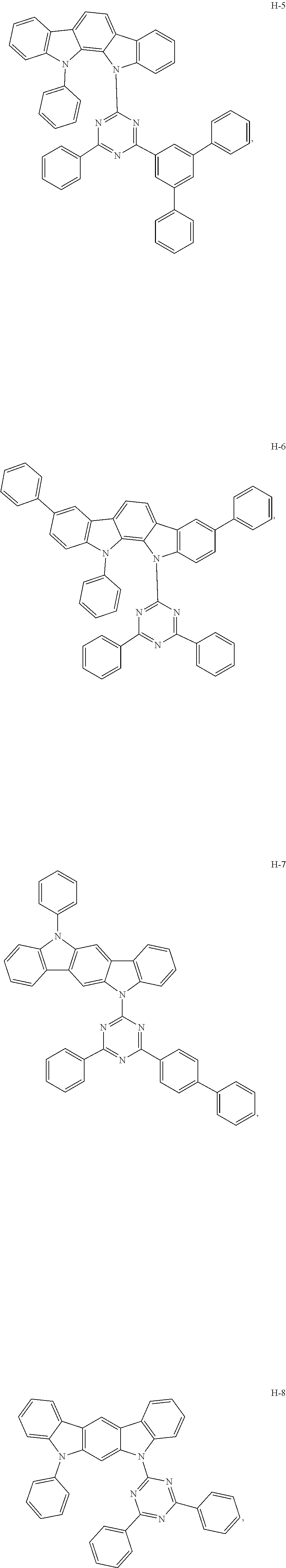 [SMILES: c1ccc(-c2cc(-c3ccccc3)cc(-c3nc(-c4ccccc4)nc(-n4c5ccccc5c5ccc6c7ccccc7n(-c7ccccc7)c6c54)n3)c2)cc1 ; c1ccc(-c2ccc3c(c2)c2ccc4c5cc(-c6ccccc6)ccc5n(-c5nc(-c6ccccc6)nc(-c6ccccc6)n5)c4c2n3-c2ccccc2)cc1 ; c1ccc(-c2ccc(-c3nc(-c4ccccc4)nc(-n4c5ccccc5c5cc6c(cc54)c4ccccc4n6-c4ccccc4)n3)cc2)cc1 ; c1ccc(-c2nc(-c3ccccc3)nc(-n3c4ccccc4c4cc5c6ccccc6n(-c6ccccc6)c5cc43)n2)cc1]

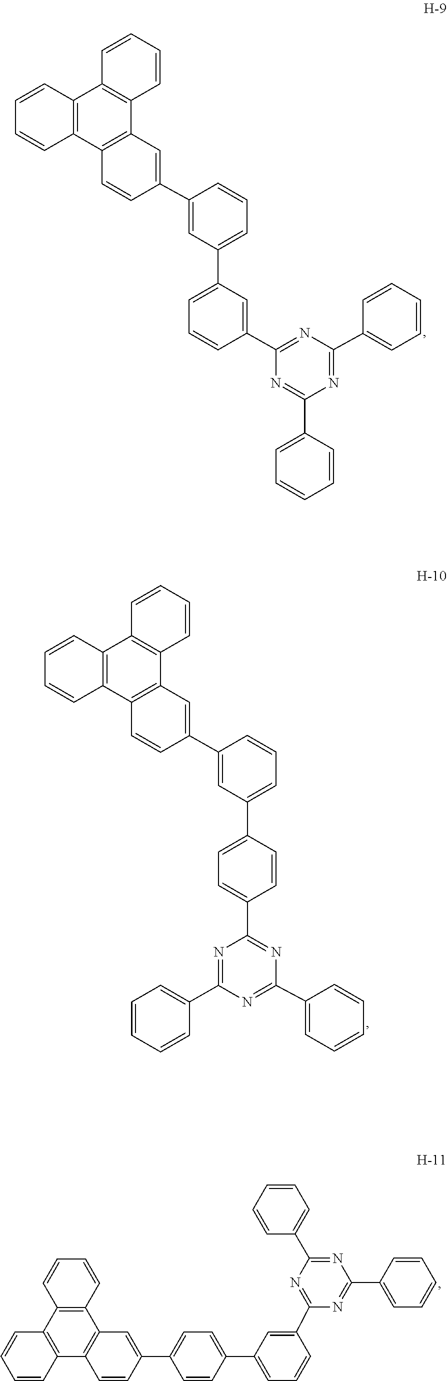 [SMILES: c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3ccccc3)nc(-c3ccc(-c4cccc(-c5ccc6c7ccccc7c7ccccc7c6c5)c4)cc3)n2)cc1 ; c1ccc(-c2nc(-c3ccccc3)nc(-c3cccc(-c4ccc(-c5ccc6c7ccccc7c7ccccc7c6c5)cc4)c3)n2)cc1]

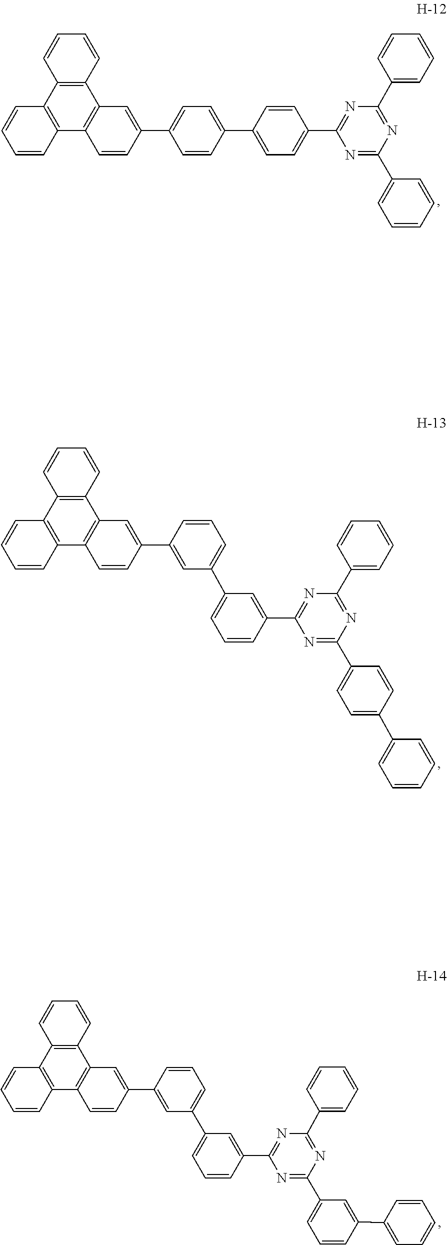 [SMILES: c1ccc(-c2nc(-c3ccccc3)nc(-c3ccc(-c4ccc(-c5ccc6c7ccccc7c7ccccc7c6c5)cc4)cc3)n2)cc1 ; c1ccc(-c2ccc(-c3nc(-c4ccccc4)nc(-c4cccc(-c5cccc(-c6ccc7c8ccccc8c8ccccc8c7c6)c5)c4)n3)cc2)cc1 ; c1ccc(-c2cccc(-c3nc(-c4ccccc4)nc(-c4cccc(-c5cccc(-c6ccc7c8ccccc8c8ccccc8c7c6)c5)c4)n3)c2)cc1]

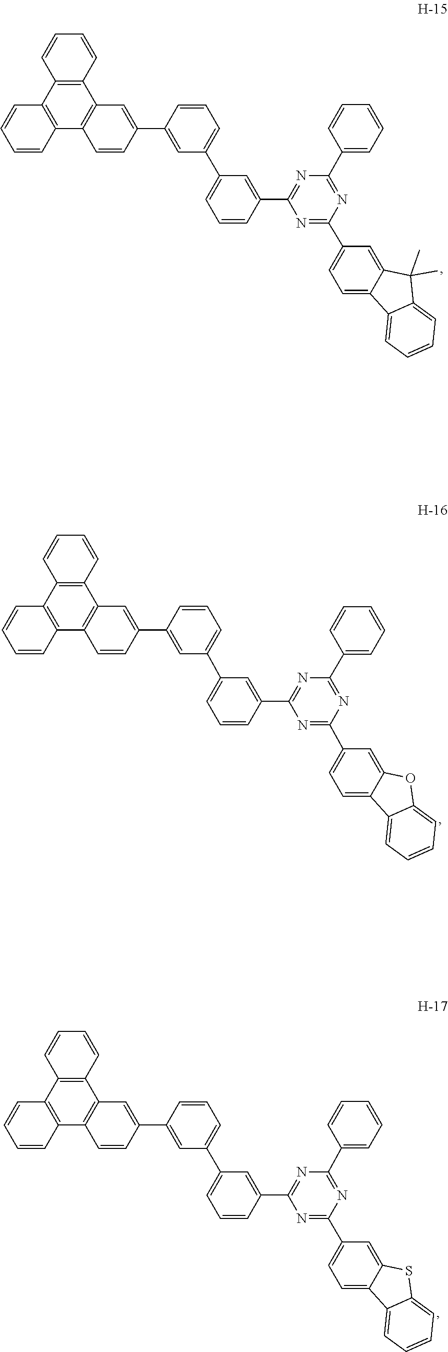 [SMILES: CC1(C)c2ccccc2-c2ccc(-c3nc(-c4ccccc4)nc(-c4cccc(-c5cccc(-c6ccc7c8ccccc8c8ccccc8c7c6)c5)c4)n3)cc21 ; c1ccc(-c2nc(-c3cccc(-c4cccc(-c5ccc6c7ccccc7c7ccccc7c6c5)c4)c3)nc(-c3ccc4c(c3)oc3ccccc34)n2)cc1 ; c1ccc(-c2nc(-c3cccc(-c4cccc(-c5ccc6c7ccccc7c7ccccc7c6c5)c4)c3)nc(-c3ccc4c(c3)sc3ccccc34)n2)cc1]

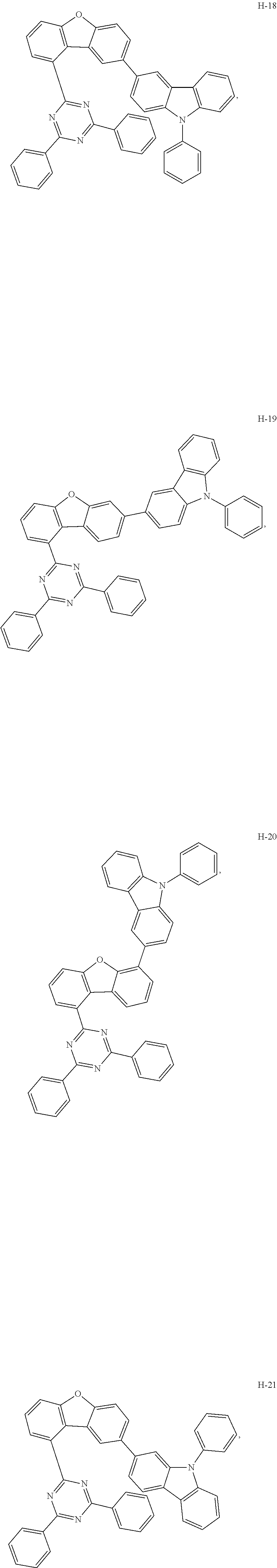 [SMILES: c1ccc(-c2nc(-c3ccccc3)nc(-c3cccc4oc5ccc(-c6ccc7c(c6)c6ccccc6n7-c6ccccc6)cc5c34)n2)cc1 ; c1ccc(-c2nc(-c3ccccc3)nc(-c3cccc4oc5cc(-c6ccc7c(c6)c6ccccc6n7-c6ccccc6)ccc5c34)n2)cc1 ; c1ccc(-c2nc(-c3ccccc3)nc(-c3cccc4oc5c(-c6ccc7c(c6)c6ccccc6n7-c6ccccc6)cccc5c34)n2)cc1 ; c1ccc(-c2nc(-c3ccccc3)nc(-c3cccc4oc5ccc(-c6ccc7c8ccccc8n(-c8ccccc8)c7c6)cc5c34)n2)cc1]

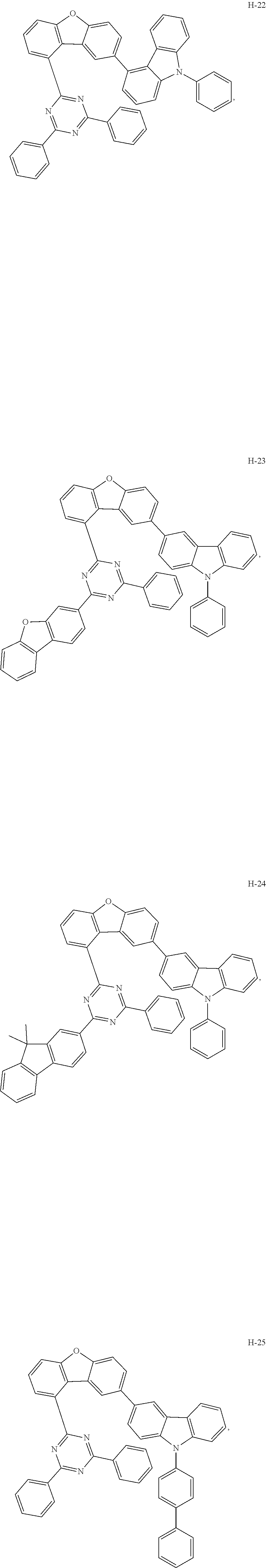 [SMILES: c1ccc(-c2nc(-c3ccccc3)nc(-c3cccc4oc5ccc(-c6cccc7c6c6ccccc6n7-c6ccccc6)cc5c34)n2)cc1 ; c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1 ; CC1(C)c2ccccc2-c2ccc(-c3nc(-c4ccccc4)nc(-c4cccc5oc6ccc(-c7ccc8c(c7)c7ccccc7n8-c7ccccc7)cc6c45)n3)cc21 ; c1ccc(-c2ccc(-n3c4ccccc4c4cc(-c5ccc6oc7cccc(-c8nc(-c9ccccc9)nc(-c9ccccc9)n8)c7c6c5)ccc43)cc2)cc1]

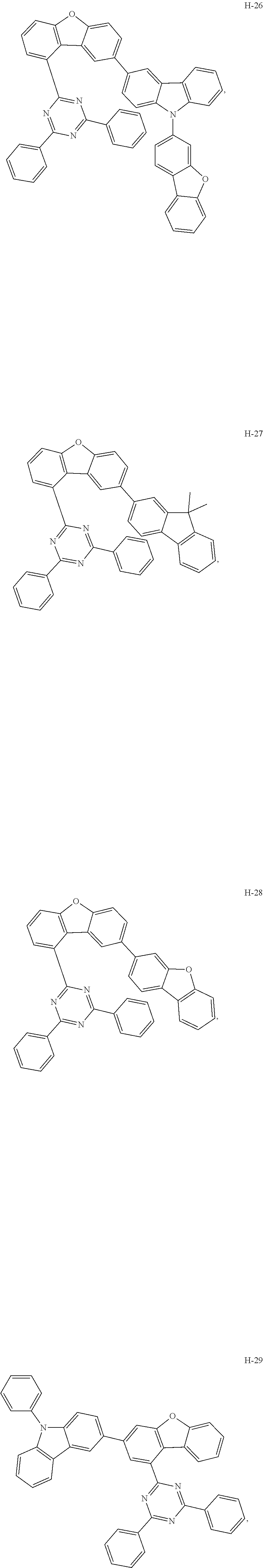 [SMILES: c1ccc(-c2nc(-c3ccccc3)nc(-c3cccc4oc5ccc(-c6ccc7c(c6)c6ccccc6n7-c6ccc7c(c6)oc6ccccc67)cc5c34)n2)cc1 ; CC1(C)c2ccccc2-c2ccc(-c3ccc4oc5cccc(-c6nc(-c7ccccc7)nc(-c7ccccc7)n6)c5c4c3)cc21 ; c1ccc(-c2nc(-c3ccccc3)nc(-c3cccc4oc5ccc(-c6ccc7c(c6)oc6ccccc67)cc5c34)n2)cc1 ; c1ccc(-c2nc(-c3ccccc3)nc(-c3cc(-c4ccc5c(c4)c4ccccc4n5-c4ccccc4)cc4oc5ccccc5c34)n2)cc1]

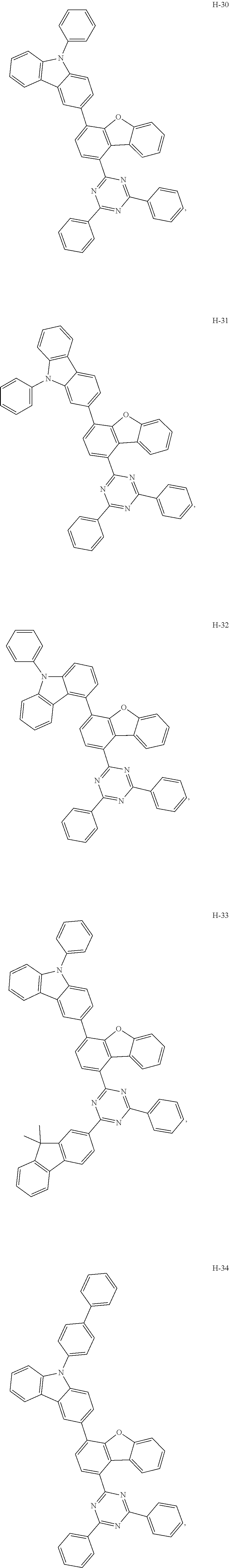 [SMILES: c1ccc(-c2nc(-c3ccccc3)nc(-c3ccc(-c4ccc5c(c4)c4ccccc4n5-c4ccccc4)c4oc5ccccc5c34)n2)cc1 ; c1ccc(-c2nc(-c3ccccc3)nc(-c3ccc(-c4ccc5c6ccccc6n(-c6ccccc6)c5c4)c4oc5ccccc5c34)n2)cc1 ; c1ccc(-c2nc(-c3ccccc3)nc(-c3ccc(-c4cccc5c4c4ccccc4n5-c4ccccc4)c4oc5ccccc5c34)n2)cc1 ; CC1(C)c2ccccc2-c2ccc(-c3nc(-c4ccccc4)nc(-c4ccc(-c5ccc6c(c5)c5ccccc5n6-c5ccccc5)c5oc6ccccc6c45)n3)cc21 ; c1ccc(-c2ccc(-n3c4ccccc4c4cc(-c5ccc(-c6nc(-c7ccccc7)nc(-c7ccccc7)n6)c6c5oc5ccccc56)ccc43)cc2)cc1]

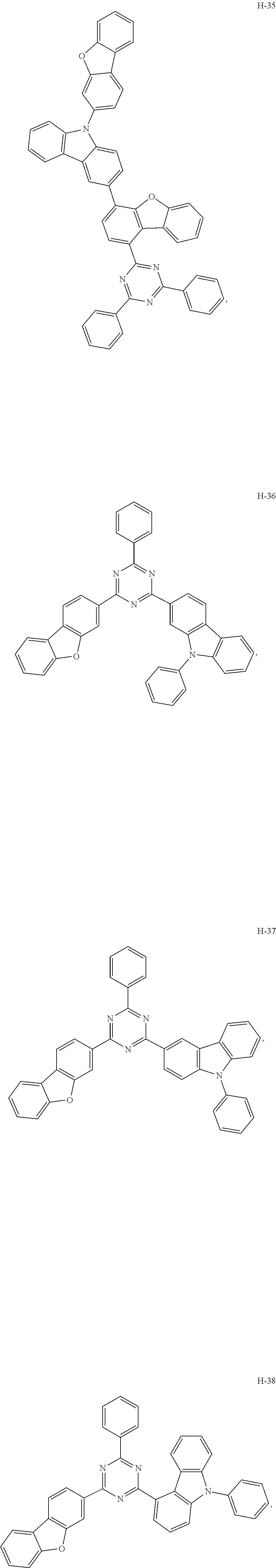 [SMILES: c1ccc(-c2nc(-c3ccccc3)nc(-c3ccc(-c4ccc5c(c4)c4ccccc4n5-c4ccc5c(c4)oc4ccccc45)c4oc5ccccc5c34)n2)cc1 ; c1ccc(-c2nc(-c3ccc4c(c3)oc3ccccc34)nc(-c3ccc4c5ccccc5n(-c5ccccc5)c4c3)n2)cc1 ; c1ccc(-c2nc(-c3ccc4c(c3)oc3ccccc34)nc(-c3ccc4c(c3)c3ccccc3n4-c3ccccc3)n2)cc1 ; c1ccc(-c2nc(-c3ccc4c(c3)oc3ccccc34)nc(-c3cccc4c3c3ccccc3n4-c3ccccc3)n2)cc1]

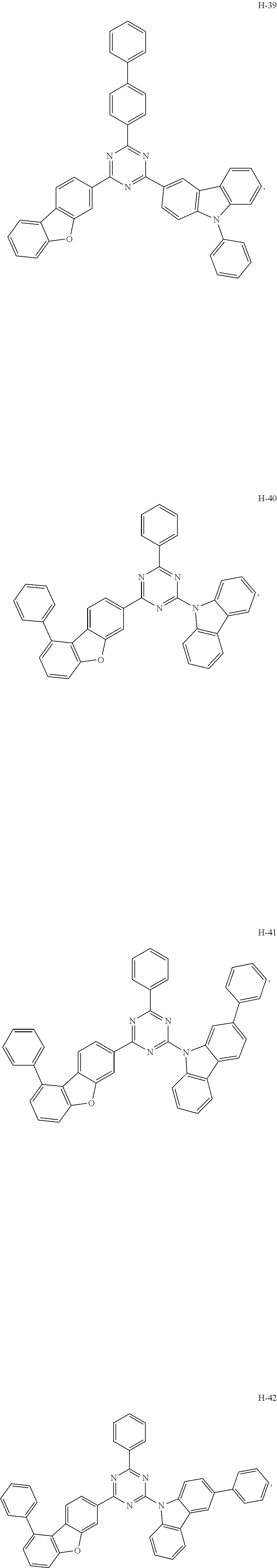 [SMILES: c1ccc(-c2ccc(-c3nc(-c4ccc5c(c4)oc4ccccc45)nc(-c4ccc5c(c4)c4ccccc4n5-c4ccccc4)n3)cc2)cc1 ; c1ccc(-c2nc(-c3ccc4c(c3)oc3cccc(-c5ccccc5)c34)nc(-n3c4ccccc4c4ccccc43)n2)cc1 ; c1ccc(-c2ccc3c4ccccc4n(-c4nc(-c5ccccc5)nc(-c5ccc6c(c5)oc5cccc(-c7ccccc7)c56)n4)c3c2)cc1 ; c1ccc(-c2ccc3c(c2)c2ccccc2n3-c2nc(-c3ccccc3)nc(-c3ccc4c(c3)oc3cccc(-c5ccccc5)c34)n2)cc1]

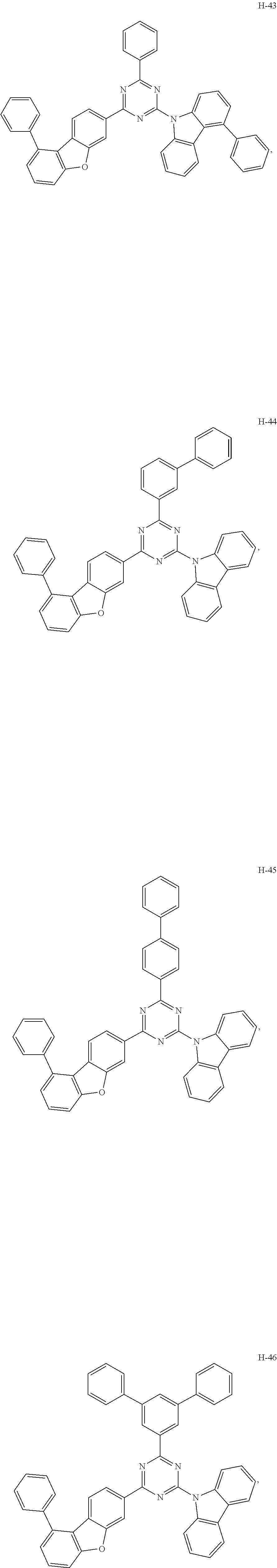 [SMILES: c1ccc(-c2nc(-c3ccc4c(c3)oc3cccc(-c5ccccc5)c34)nc(-n3c4ccccc4c4c(-c5ccccc5)cccc43)n2)cc1 ; c1ccc(-c2cccc(-c3nc(-c4ccc5c(c4)oc4cccc(-c6ccccc6)c45)nc(-n4c5ccccc5c5ccccc54)n3)c2)cc1 ; c1ccc(-c2ccc(-c3nc(-c4ccc5c(c4)oc4cccc(-c6ccccc6)c45)nc(-n4c5ccccc5c5ccccc54)n3)cc2)cc1 ; c1ccc(-c2cc(-c3ccccc3)cc(-c3nc(-c4ccc5c(c4)oc4cccc(-c6ccccc6)c45)nc(-n4c5ccccc5c5ccccc54)n3)c2)cc1]

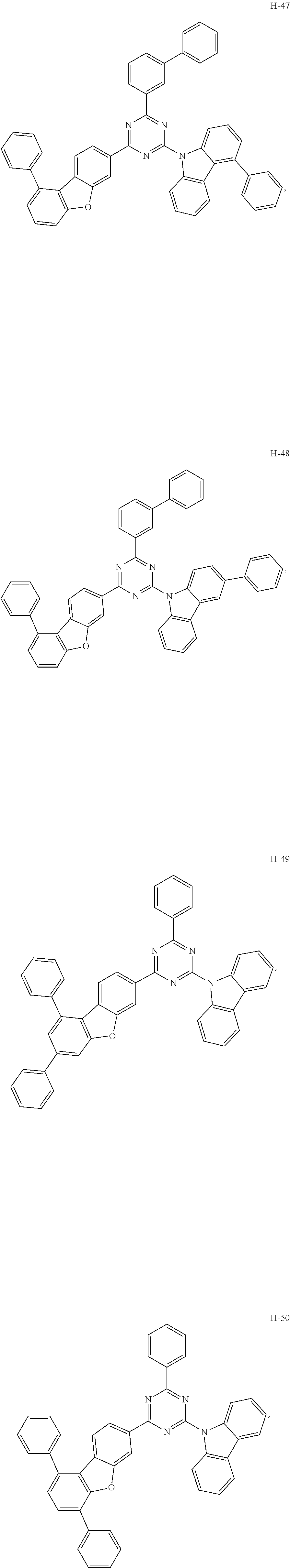 [SMILES: c1ccc(-c2cccc(-c3nc(-c4ccc5c(c4)oc4cccc(-c6ccccc6)c45)nc(-n4c5ccccc5c5c(-c6ccccc6)cccc54)n3)c2)cc1 ; c1ccc(-c2cccc(-c3nc(-c4ccc5c(c4)oc4cccc(-c6ccccc6)c45)nc(-n4c5ccccc5c5cc(-c6ccccc6)ccc54)n3)c2)cc1 ; c1ccc(-c2cc(-c3ccccc3)c3c(c2)oc2cc(-c4nc(-c5ccccc5)nc(-n5c6ccccc6c6ccccc65)n4)ccc23)cc1 ; c1ccc(-c2nc(-c3ccc4c(c3)oc3c(-c5ccccc5)ccc(-c5ccccc5)c34)nc(-n3c4ccccc4c4ccccc43)n2)cc1]

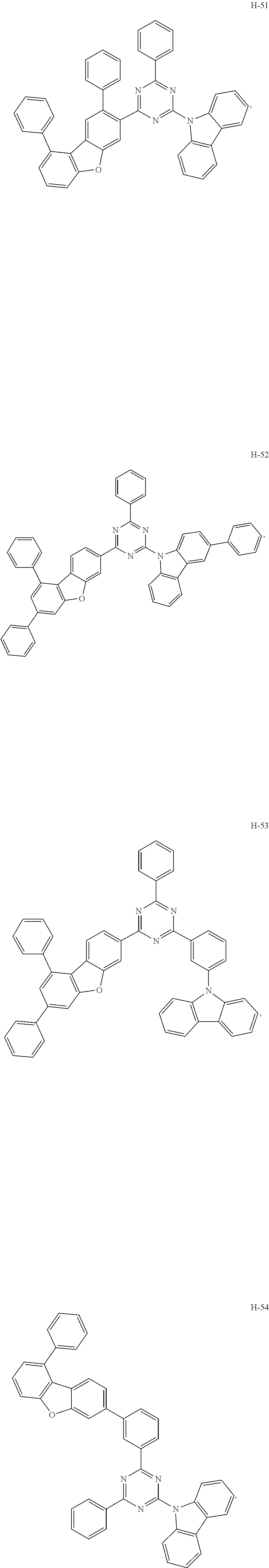 [SMILES: c1ccc(-c2nc(-c3cc4oc5cccc(-c6ccccc6)c5c4cc3-c3ccccc3)nc(-n3c4ccccc4c4ccccc43)n2)cc1 ; c1ccc(-c2cc(-c3ccccc3)c3c(c2)oc2cc(-c4nc(-c5ccccc5)nc(-n5c6ccccc6c6cc(-c7ccccc7)ccc65)n4)ccc23)cc1 ; c1ccc(-c2cc(-c3ccccc3)c3c(c2)oc2cc(-c4nc(-c5ccccc5)nc(-c5cccc(-n6c7ccccc7c7ccccc76)c5)n4)ccc23)cc1 ; c1ccc(-c2nc(-c3cccc(-c4ccc5c(c4)oc4cccc(-c6ccccc6)c45)c3)nc(-n3c4ccccc4c4ccccc43)n2)cc1]

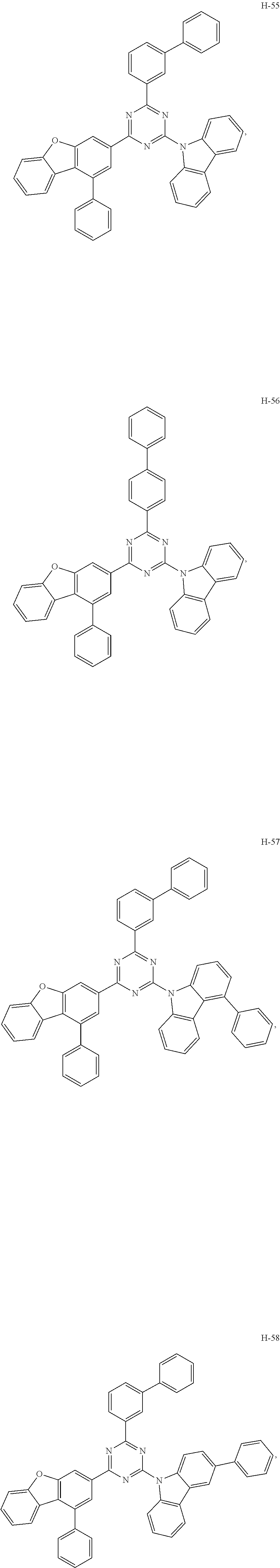 [SMILES: c1ccc(-c2cccc(-c3nc(-c4cc(-c5ccccc5)c5c(c4)oc4ccccc45)nc(-n4c5ccccc5c5ccccc54)n3)c2)cc1 ; c1ccc(-c2ccc(-c3nc(-c4cc(-c5ccccc5)c5c(c4)oc4ccccc45)nc(-n4c5ccccc5c5ccccc54)n3)cc2)cc1 ; c1ccc(-c2cccc(-c3nc(-c4cc(-c5ccccc5)c5c(c4)oc4ccccc45)nc(-n4c5ccccc5c5c(-c6ccccc6)cccc54)n3)c2)cc1 ; c1ccc(-c2cccc(-c3nc(-c4cc(-c5ccccc5)c5c(c4)oc4ccccc45)nc(-n4c5ccccc5c5cc(-c6ccccc6)ccc54)n3)c2)cc1]

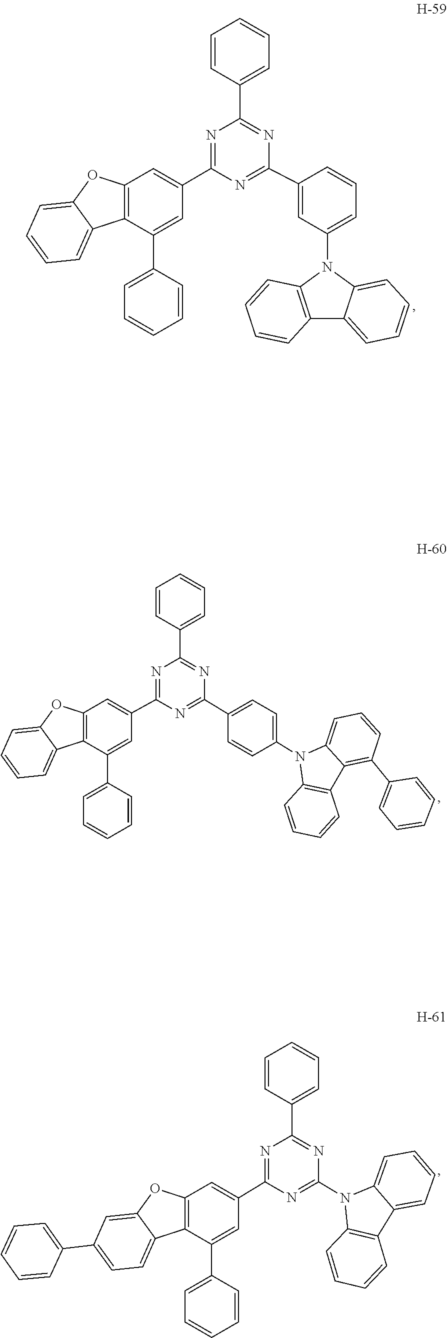 [SMILES: c1ccc(-c2nc(-c3cccc(-n4c5ccccc5c5ccccc54)c3)nc(-c3cc(-c4ccccc4)c4c(c3)oc3ccccc34)n2)cc1 ; c1ccc(-c2nc(-c3ccc(-n4c5ccccc5c5c(-c6ccccc6)cccc54)cc3)nc(-c3cc(-c4ccccc4)c4c(c3)oc3ccccc34)n2)cc1 ; c1ccc(-c2ccc3c(c2)oc2cc(-c4nc(-c5ccccc5)nc(-n5c6ccccc6c6ccccc65)n4)cc(-c4ccccc4)c23)cc1]

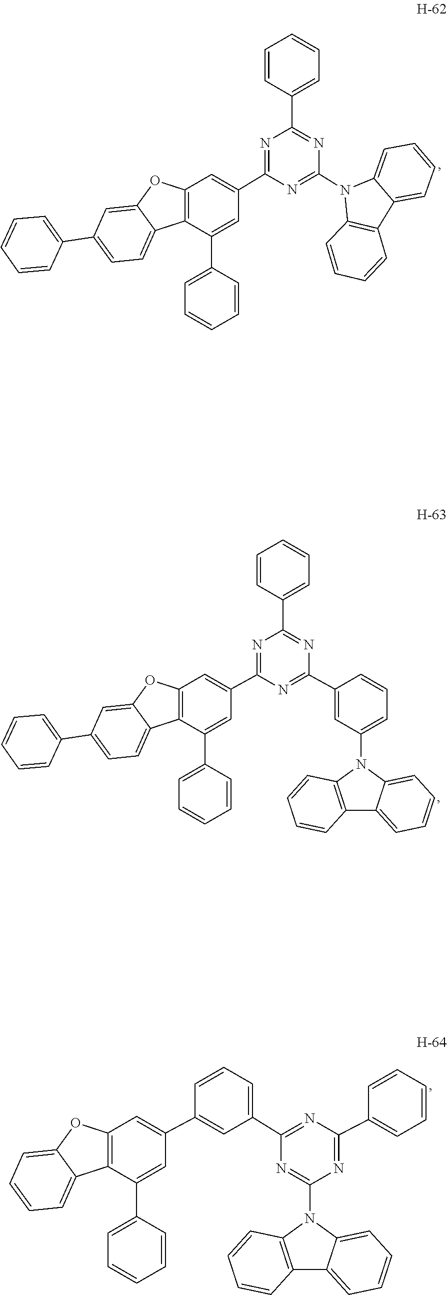 [SMILES: c1ccc(-c2ccc3c(c2)oc2cc(-c4nc(-c5ccccc5)nc(-n5c6ccccc6c6ccccc65)n4)cc(-c4ccccc4)c23)cc1 ; c1ccc(-c2ccc3c(c2)oc2cc(-c4nc(-c5ccccc5)nc(-c5cccc(-n6c7ccccc7c7ccccc76)c5)n4)cc(-c4ccccc4)c23)cc1 ; c1ccc(-c2nc(-c3cccc(-c4cc(-c5ccccc5)c5c(c4)oc4ccccc45)c3)nc(-n3c4ccccc4c4ccccc43)n2)cc1]

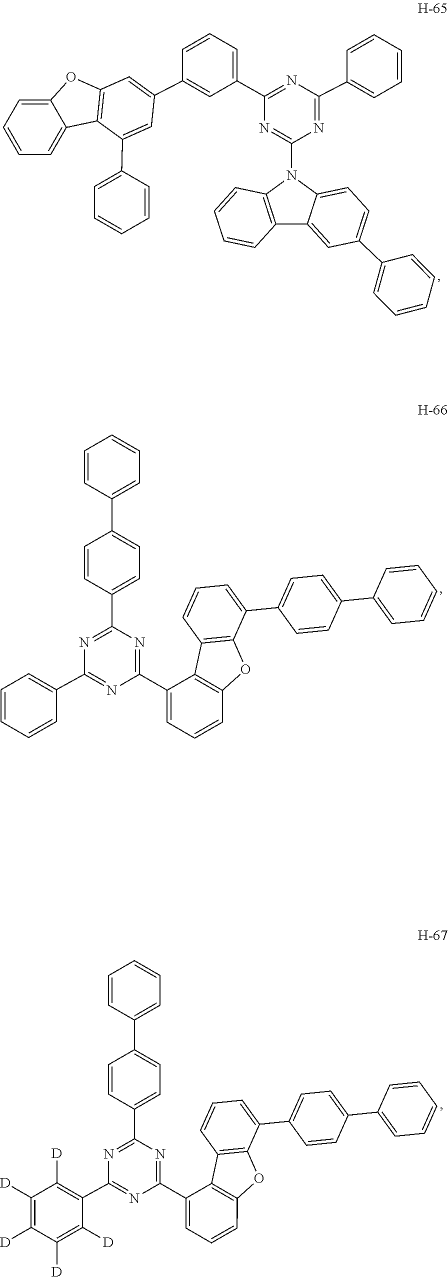 [SMILES: c1ccc(-c2ccc3c(c2)c2ccccc2n3-c2nc(-c3ccccc3)nc(-c3cccc(-c4cc(-c5ccccc5)c5c(c4)oc4ccccc45)c3)n2)cc1 ; c1ccc(-c2ccc(-c3nc(-c4ccccc4)nc(-c4cccc5oc6c(-c7ccc(-c8ccccc8)cc7)cccc6c45)n3)cc2)cc1 ; [2H]c1c([2H])c([2H])c(-c2nc(-c3ccc(-c4ccccc4)cc3)nc(-c3cccc4oc5c(-c6ccc(-c7ccccc7)cc6)cccc5c34)n2)c([2H])c1[2H]]

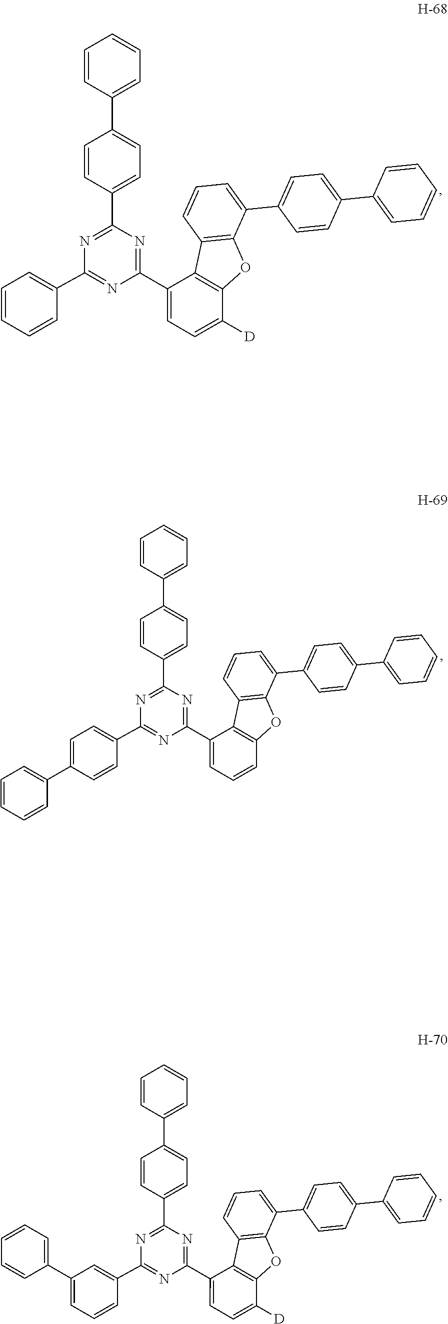 [SMILES: [2H]c1ccc(-c2nc(-c3ccccc3)nc(-c3ccc(-c4ccccc4)cc3)n2)c2c1oc1c(-c3ccc(-c4ccccc4)cc3)cccc12 ; c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; [2H]c1ccc(-c2nc(-c3ccc(-c4ccccc4)cc3)nc(-c3cccc(-c4ccccc4)c3)n2)c2c1oc1c(-c3ccc(-c4ccccc4)cc3)cccc12]

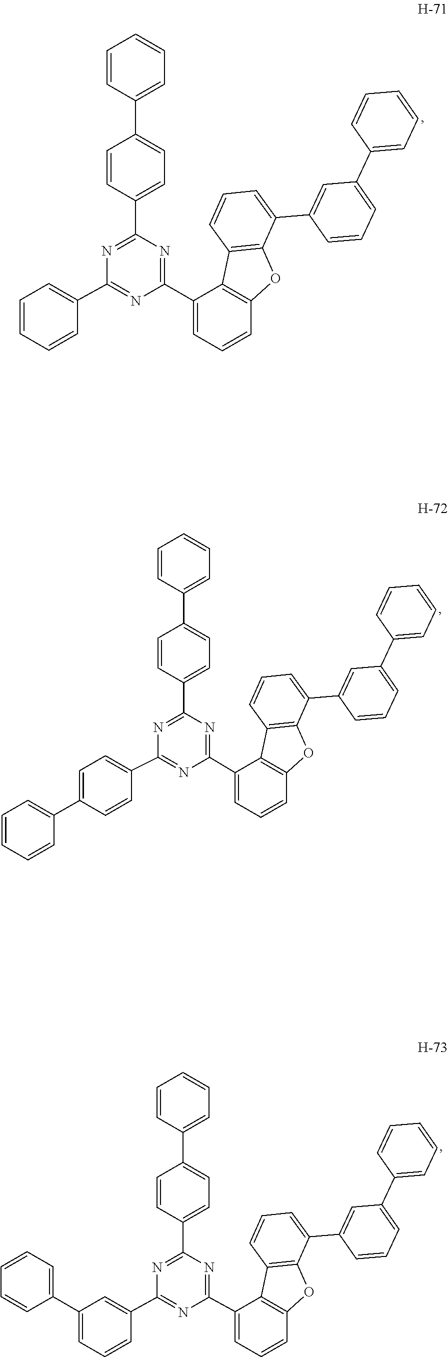 [SMILES: c1ccc(-c2ccc(-c3nc(-c4ccccc4)nc(-c4cccc5oc6c(-c7cccc(-c8ccccc8)c7)cccc6c45)n3)cc2)cc1 ; c1ccc(-c2ccc(-c3nc(-c4ccc(-c5ccccc5)cc4)nc(-c4cccc5oc6c(-c7cccc(-c8ccccc8)c7)cccc6c45)n3)cc2)cc1 ; c1ccc(-c2ccc(-c3nc(-c4cccc(-c5ccccc5)c4)nc(-c4cccc5oc6c(-c7cccc(-c8ccccc8)c7)cccc6c45)n3)cc2)cc1]

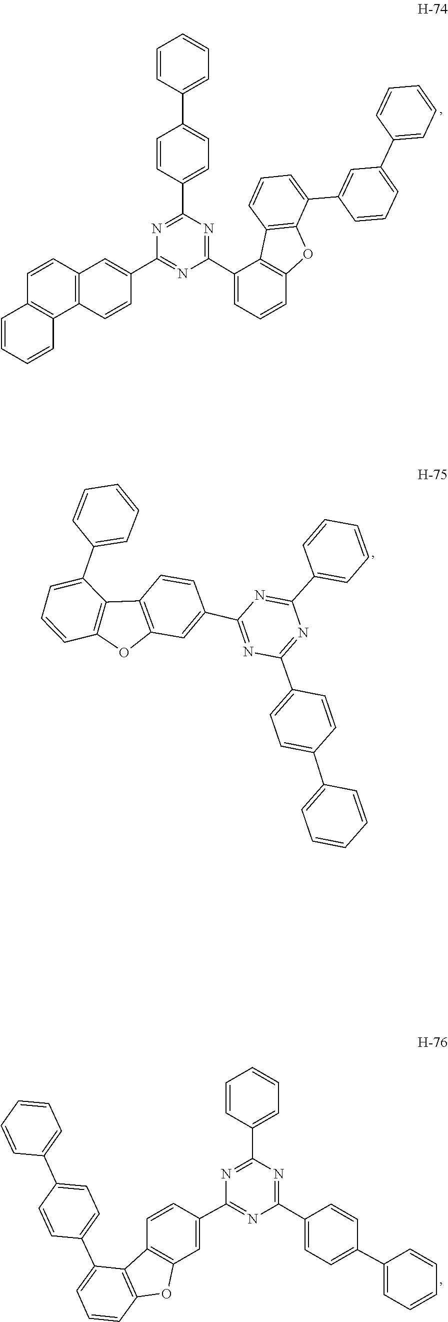 [SMILES: c1ccc(-c2ccc(-c3nc(-c4ccc5c(ccc6ccccc65)c4)nc(-c4cccc5oc6c(-c7cccc(-c8ccccc8)c7)cccc6c45)n3)cc2)cc1 ; c1ccc(-c2ccc(-c3nc(-c4ccccc4)nc(-c4ccc5c(c4)oc4cccc(-c6ccccc6)c45)n3)cc2)cc1 ; c1ccc(-c2ccc(-c3nc(-c4ccccc4)nc(-c4ccc5c(c4)oc4cccc(-c6ccc(-c7ccccc7)cc6)c45)n3)cc2)cc1]

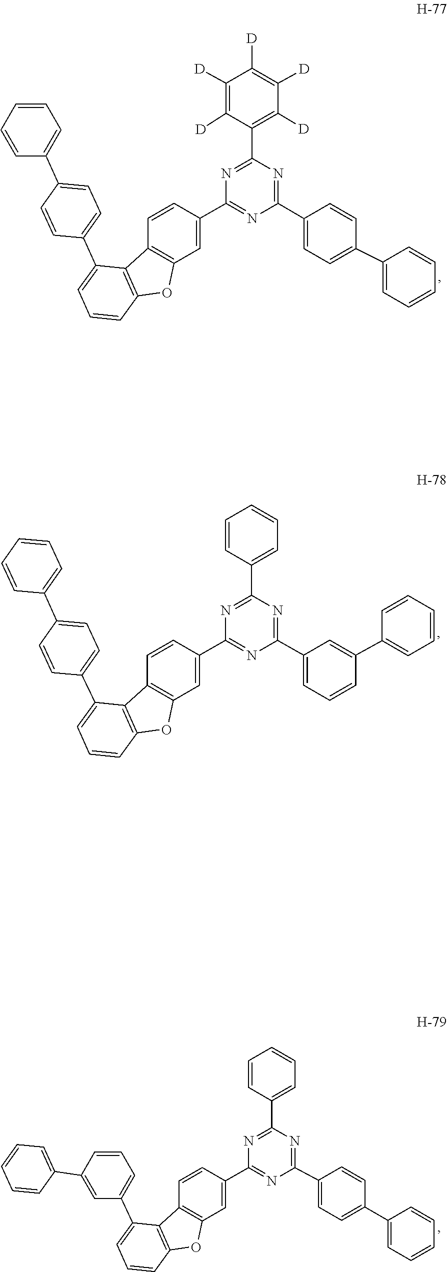 [SMILES: [2H]c1c([2H])c([2H])c(-c2nc(-c3ccc(-c4ccccc4)cc3)nc(-c3ccc4c(c3)oc3cccc(-c5ccc(-c6ccccc6)cc5)c34)n2)c([2H])c1[2H] ; c1ccc(-c2ccc(-c3cccc4oc5cc(-c6nc(-c7ccccc7)nc(-c7cccc(-c8ccccc8)c7)n6)ccc5c34)cc2)cc1 ; c1ccc(-c2ccc(-c3nc(-c4ccccc4)nc(-c4ccc5c(c4)oc4cccc(-c6cccc(-c7ccccc7)c6)c45)n3)cc2)cc1]

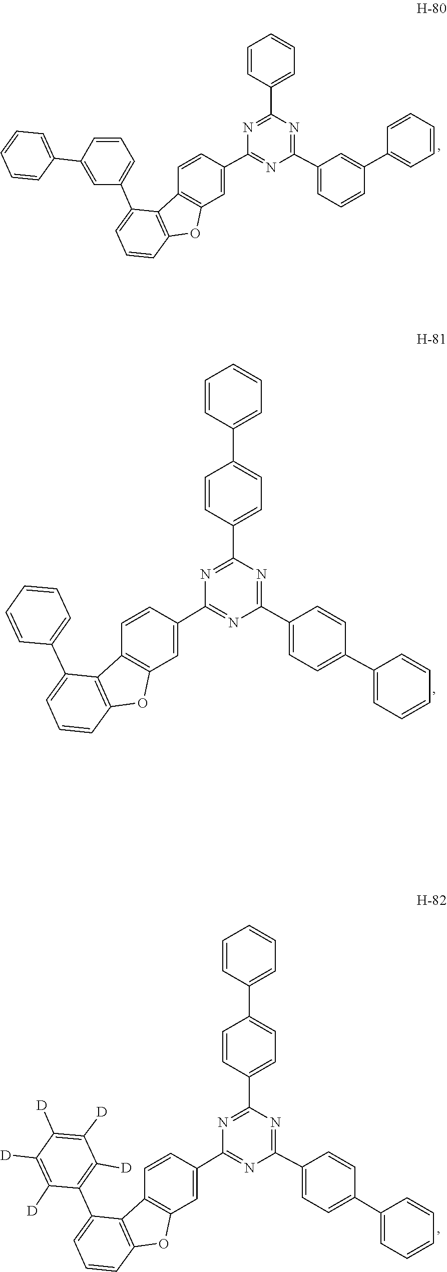 [SMILES: c1ccc(-c2cccc(-c3nc(-c4ccccc4)nc(-c4ccc5c(c4)oc4cccc(-c6cccc(-c7ccccc7)c6)c45)n3)c2)cc1 ; c1ccc(-c2ccc(-c3nc(-c4ccc(-c5ccccc5)cc4)nc(-c4ccc5c(c4)oc4cccc(-c6ccccc6)c45)n3)cc2)cc1 ; [2H]c1c([2H])c([2H])c(-c2cccc3oc4cc(-c5nc(-c6ccc(-c7ccccc7)cc6)nc(-c6ccc(-c7ccccc7)cc6)n5)ccc4c23)c([2H])c1[2H]]

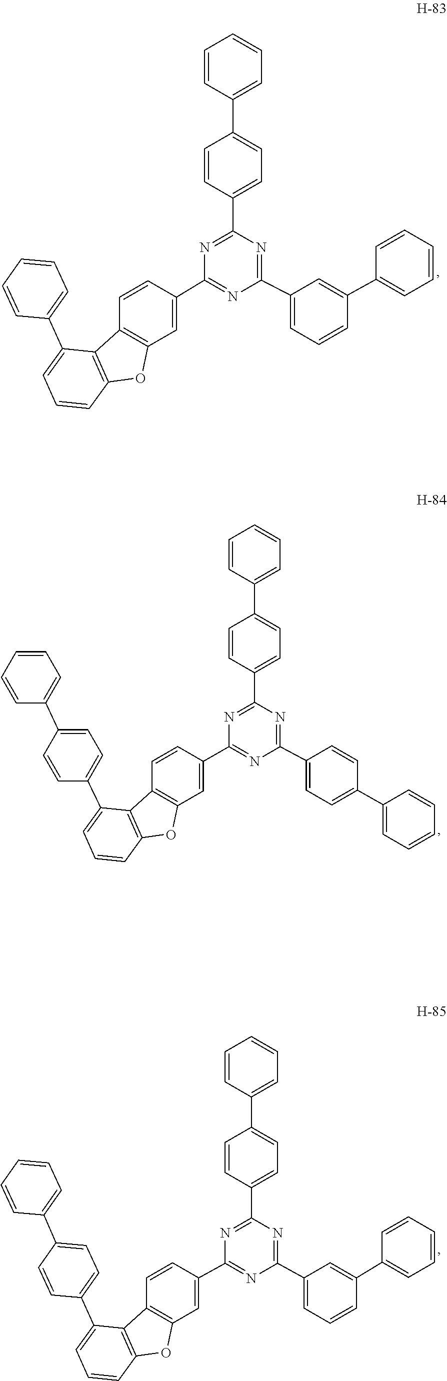 [SMILES: c1ccc(-c2ccc(-c3nc(-c4cccc(-c5ccccc5)c4)nc(-c4ccc5c(c4)oc4cccc(-c6ccccc6)c45)n3)cc2)cc1 ; c1ccc(-c2ccc(-c3nc(-c4ccc(-c5ccccc5)cc4)nc(-c4ccc5c(c4)oc4cccc(-c6ccc(-c7ccccc7)cc6)c45)n3)cc2)cc1 ; c1ccc(-c2ccc(-c3nc(-c4cccc(-c5ccccc5)c4)nc(-c4ccc5c(c4)oc4cccc(-c6ccc(-c7ccccc7)cc6)c45)n3)cc2)cc1]

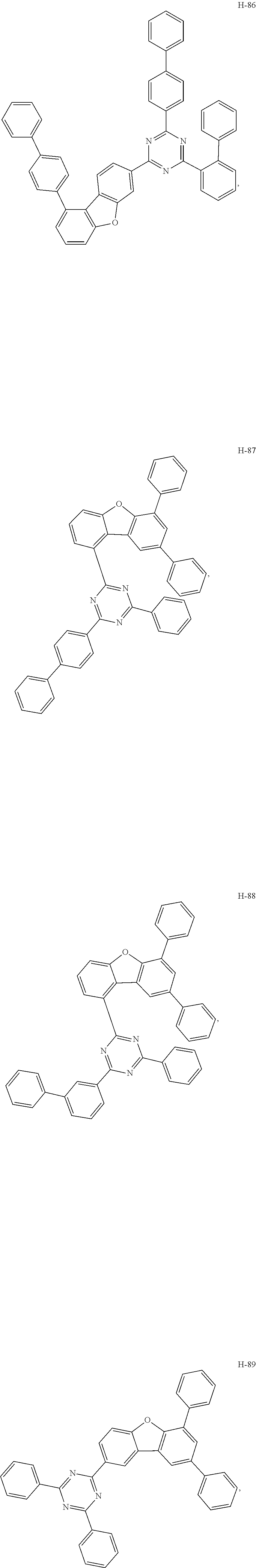 [SMILES: c1ccc(-c2ccc(-c3nc(-c4ccc5c(c4)oc4cccc(-c6ccc(-c7ccccc7)cc6)c45)nc(-c4ccccc4-c4ccccc4)n3)cc2)cc1 ; c1ccc(-c2ccc(-c3nc(-c4ccccc4)nc(-c4cccc5oc6c(-c7ccccc7)cc(-c7ccccc7)cc6c45)n3)cc2)cc1 ; c1ccc(-c2cccc(-c3nc(-c4ccccc4)nc(-c4cccc5oc6c(-c7ccccc7)cc(-c7ccccc7)cc6c45)n3)c2)cc1 ; c1ccc(-c2cc(-c3ccccc3)c3oc4ccc(-c5nc(-c6ccccc6)nc(-c6ccccc6)n5)cc4c3c2)cc1]

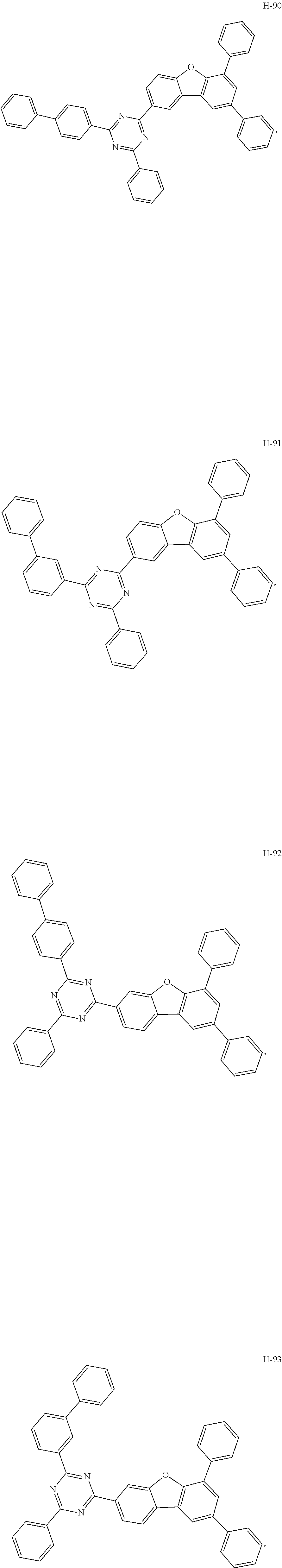 [SMILES: c1ccc(-c2ccc(-c3nc(-c4ccccc4)nc(-c4ccc5oc6c(-c7ccccc7)cc(-c7ccccc7)cc6c5c4)n3)cc2)cc1 ; c1ccc(-c2cccc(-c3nc(-c4ccccc4)nc(-c4ccc5oc6c(-c7ccccc7)cc(-c7ccccc7)cc6c5c4)n3)c2)cc1 ; c1ccc(-c2ccc(-c3nc(-c4ccccc4)nc(-c4ccc5c(c4)oc4c(-c6ccccc6)cc(-c6ccccc6)cc45)n3)cc2)cc1 ; c1ccc(-c2cccc(-c3nc(-c4ccccc4)nc(-c4ccc5c(c4)oc4c(-c6ccccc6)cc(-c6ccccc6)cc45)n3)c2)cc1]

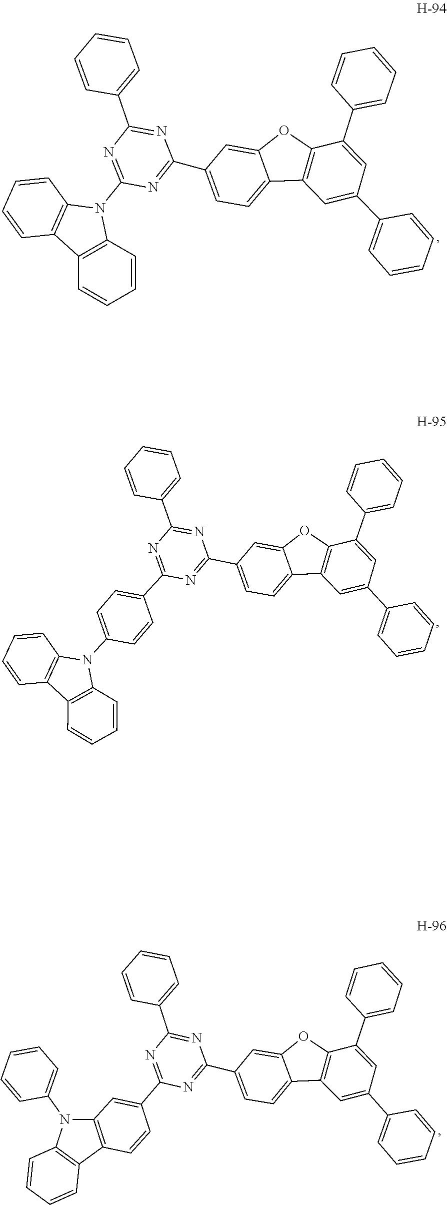 [SMILES: c1ccc(-c2cc(-c3ccccc3)c3oc4cc(-c5nc(-c6ccccc6)nc(-n6c7ccccc7c7ccccc76)n5)ccc4c3c2)cc1 ; c1ccc(-c2cc(-c3ccccc3)c3oc4cc(-c5nc(-c6ccccc6)nc(-c6ccc(-n7c8ccccc8c8ccccc87)cc6)n5)ccc4c3c2)cc1 ; c1ccc(-c2cc(-c3ccccc3)c3oc4cc(-c5nc(-c6ccccc6)nc(-c6ccc7c8ccccc8n(-c8ccccc8)c7c6)n5)ccc4c3c2)cc1]

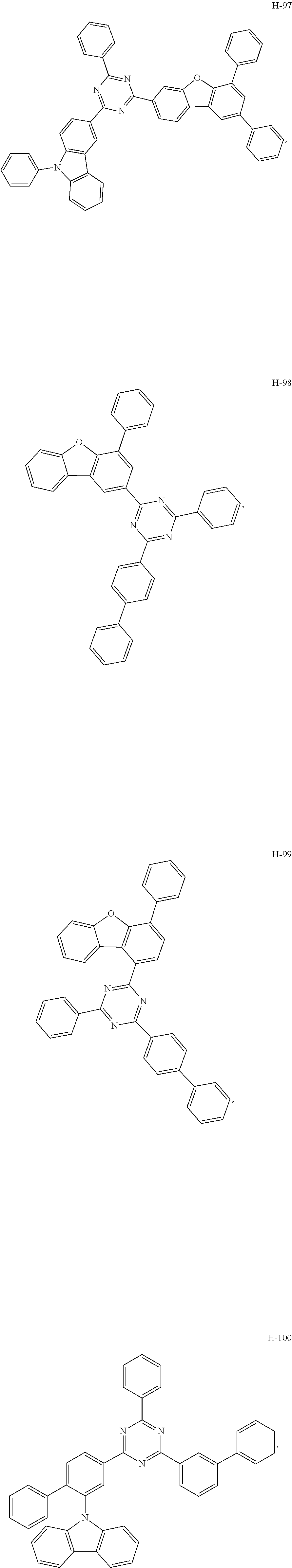 [SMILES: c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1 ; c1ccc(-c2ccc(-c3nc(-c4ccccc4)nc(-c4cc(-c5ccccc5)c5oc6ccccc6c5c4)n3)cc2)cc1 ; c1ccc(-c2ccc(-c3nc(-c4ccccc4)nc(-c4ccc(-c5ccccc5)c5oc6ccccc6c45)n3)cc2)cc1 ; c1ccc(-c2cccc(-c3nc(-c4ccccc4)nc(-c4ccc(-c5ccccc5)c(-n5c6ccccc6c6ccccc65)c4)n3)c2)cc1]

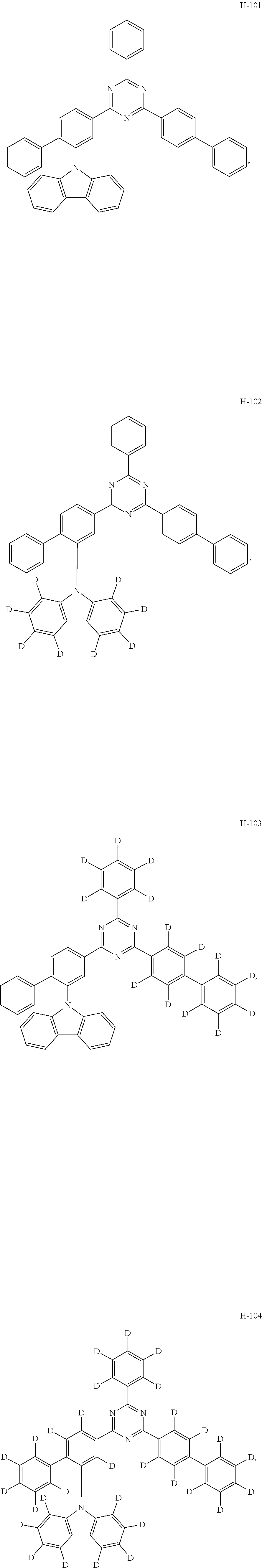

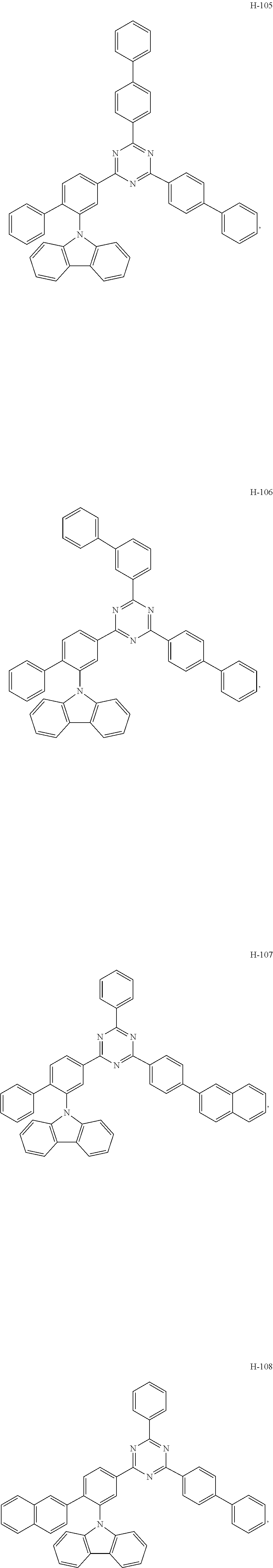 [SMILES: c1ccc(-c2ccc(-c3nc(-c4ccc(-c5ccccc5)cc4)nc(-c4ccc(-c5ccccc5)c(-n5c6ccccc6c6ccccc65)c4)n3)cc2)cc1 ; c1ccc(-c2ccc(-c3nc(-c4cccc(-c5ccccc5)c4)nc(-c4ccc(-c5ccccc5)c(-n5c6ccccc6c6ccccc65)c4)n3)cc2)cc1 ; c1ccc(-c2nc(-c3ccc(-c4ccc5ccccc5c4)cc3)nc(-c3ccc(-c4ccccc4)c(-n4c5ccccc5c5ccccc54)c3)n2)cc1 ; c1ccc(-c2ccc(-c3nc(-c4ccccc4)nc(-c4ccc(-c5ccc6ccccc6c5)c(-n5c6ccccc6c6ccccc65)c4)n3)cc2)cc1]

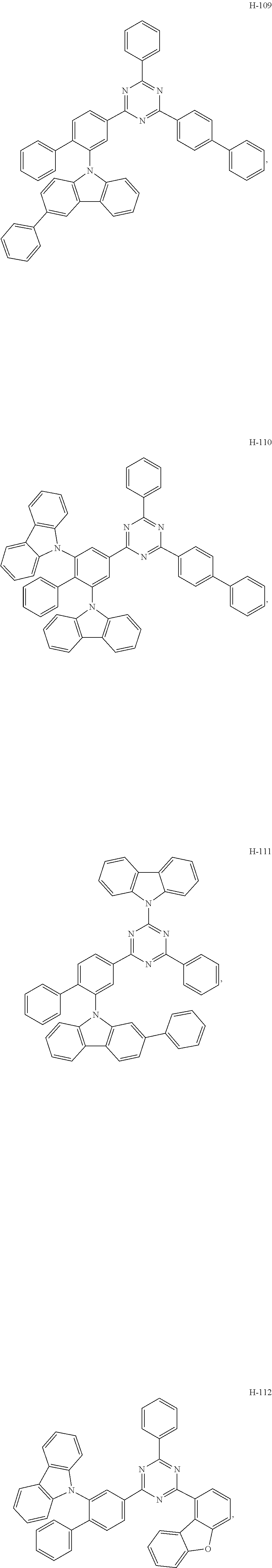 [SMILES: c1ccc(-c2ccc(-c3nc(-c4ccccc4)nc(-c4ccc(-c5ccccc5)c(-n5c6ccccc6c6cc(-c7ccccc7)ccc65)c4)n3)cc2)cc1 ; c1ccc(-c2ccc(-c3nc(-c4ccccc4)nc(-c4cc(-n5c6ccccc6c6ccccc65)c(-c5ccccc5)c(-n5c6ccccc6c6ccccc65)c4)n3)cc2)cc1 ; c1ccc(-c2ccc3c4ccccc4n(-c4cc(-c5nc(-c6ccccc6)nc(-n6c7ccccc7c7ccccc76)n5)ccc4-c4ccccc4)c3c2)cc1 ; c1ccc(-c2nc(-c3ccc(-c4ccccc4)c(-n4c5ccccc5c5ccccc54)c3)nc(-c3cccc4oc5ccccc5c34)n2)cc1]

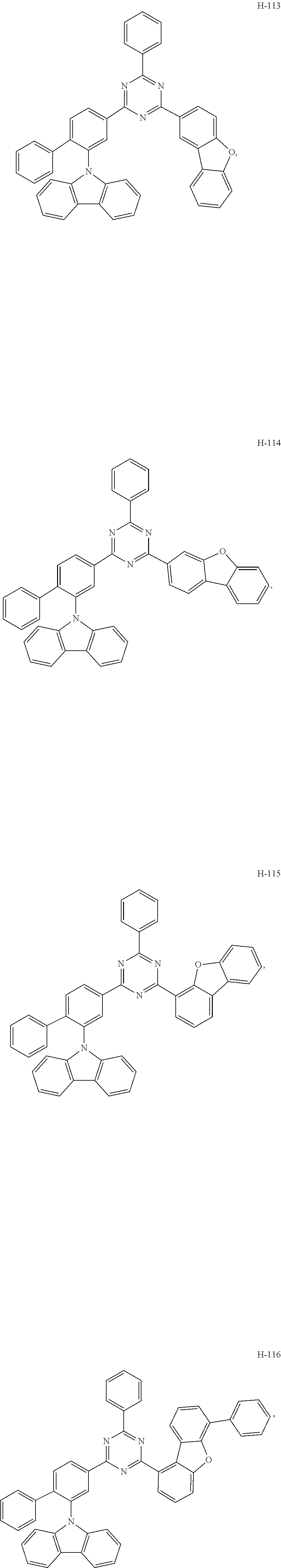 [SMILES: c1ccc(-c2nc(-c3ccc(-c4ccccc4)c(-n4c5ccccc5c5ccccc54)c3)nc(-c3ccc4oc5ccccc5c4c3)n2)cc1 ; c1ccc(-c2nc(-c3ccc(-c4ccccc4)c(-n4c5ccccc5c5ccccc54)c3)nc(-c3ccc4c(c3)oc3ccccc34)n2)cc1 ; c1ccc(-c2nc(-c3ccc(-c4ccccc4)c(-n4c5ccccc5c5ccccc54)c3)nc(-c3cccc4c3oc3ccccc34)n2)cc1 ; c1ccc(-c2nc(-c3ccc(-c4ccccc4)c(-n4c5ccccc5c5ccccc54)c3)nc(-c3cccc4oc5c(-c6ccccc6)cccc5c34)n2)cc1]

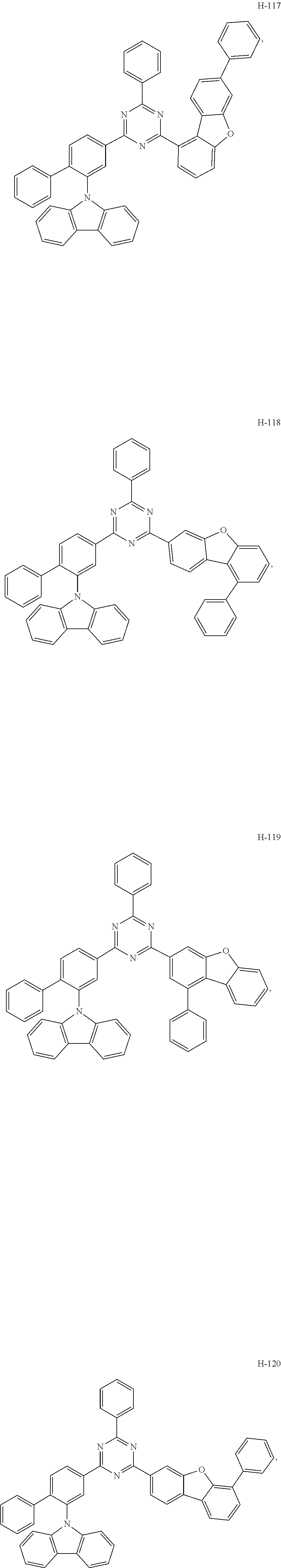 [SMILES: c1ccc(-c2ccc3c(c2)oc2cccc(-c4nc(-c5ccccc5)nc(-c5ccc(-c6ccccc6)c(-n6c7ccccc7c7ccccc76)c5)n4)c23)cc1 ; c1ccc(-c2nc(-c3ccc(-c4ccccc4)c(-n4c5ccccc5c5ccccc54)c3)nc(-c3ccc4c(c3)oc3cccc(-c5ccccc5)c34)n2)cc1 ; c1ccc(-c2nc(-c3ccc(-c4ccccc4)c(-n4c5ccccc5c5ccccc54)c3)nc(-c3cc(-c4ccccc4)c4c(c3)oc3ccccc34)n2)cc1 ; c1ccc(-c2nc(-c3ccc(-c4ccccc4)c(-n4c5ccccc5c5ccccc54)c3)nc(-c3ccc4c(c3)oc3c(-c5ccccc5)cccc34)n2)cc1]

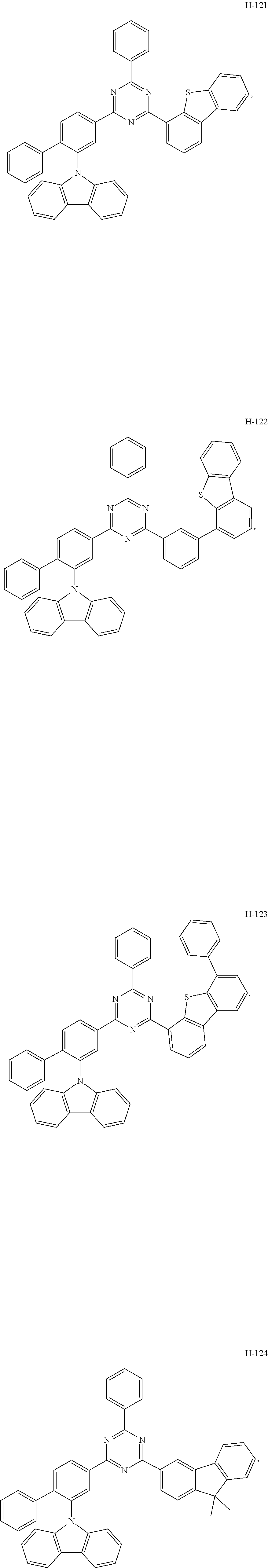 [SMILES: c1ccc(-c2nc(-c3ccc(-c4ccccc4)c(-n4c5ccccc5c5ccccc54)c3)nc(-c3cccc4c3sc3ccccc34)n2)cc1 ; c1ccc(-c2nc(-c3cccc(-c4cccc5c4sc4ccccc45)c3)nc(-c3ccc(-c4ccccc4)c(-n4c5ccccc5c5ccccc54)c3)n2)cc1 ; c1ccc(-c2nc(-c3ccc(-c4ccccc4)c(-n4c5ccccc5c5ccccc54)c3)nc(-c3cccc4c3sc3c(-c5ccccc5)cccc34)n2)cc1 ; CC1(C)c2ccccc2-c2cc(-c3nc(-c4ccccc4)nc(-c4ccc(-c5ccccc5)c(-n5c6ccccc6c6ccccc65)c4)n3)ccc21]

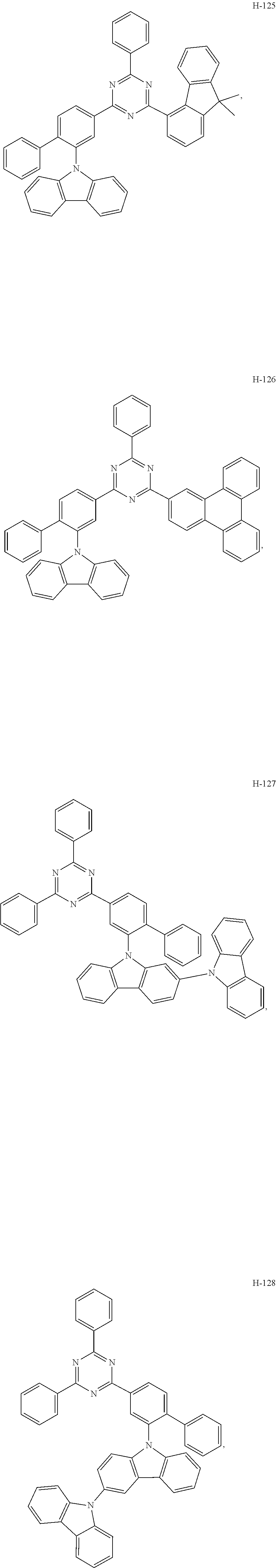 [SMILES: CC1(C)c2ccccc2-c2c(-c3nc(-c4ccccc4)nc(-c4ccc(-c5ccccc5)c(-n5c6ccccc6c6ccccc65)c4)n3)cccc21 ; c1ccc(-c2nc(-c3ccc(-c4ccccc4)c(-n4c5ccccc5c5ccccc54)c3)nc(-c3ccc4c5ccccc5c5ccccc5c4c3)n2)cc1 ; c1ccc(-c2nc(-c3ccccc3)nc(-c3ccc(-c4ccccc4)c(-n4c5ccccc5c5ccc(-n6c7ccccc7c7ccccc76)cc54)c3)n2)cc1 ; c1ccc(-c2nc(-c3ccccc3)nc(-c3ccc(-c4ccccc4)c(-n4c5ccccc5c5cc(-n6c7ccccc7c7ccccc76)ccc54)c3)n2)cc1]

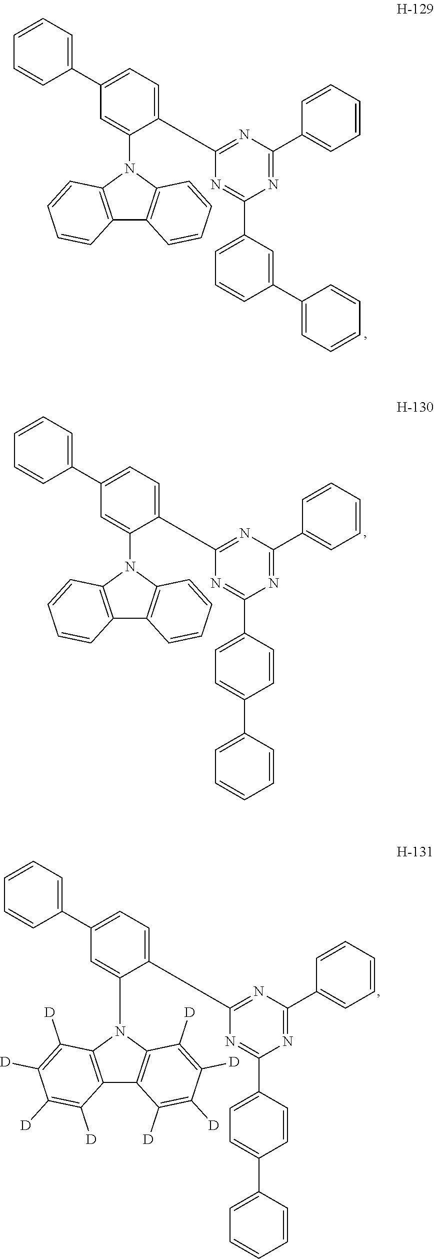 [SMILES: c1ccc(-c2cccc(-c3nc(-c4ccccc4)nc(-c4ccc(-c5ccccc5)cc4-n4c5ccccc5c5ccccc54)n3)c2)cc1 ; c1ccc(-c2ccc(-c3nc(-c4ccccc4)nc(-c4ccc(-c5ccccc5)cc4-n4c5ccccc5c5ccccc54)n3)cc2)cc1 ; [2H]c1c([2H])c([2H])c2c(c1[2H])c1c([2H])c([2H])c([2H])c([2H])c1n2-c1cc(-c2ccccc2)ccc1-c1nc(-c2ccccc2)nc(-c2ccc(-c3ccccc3)cc2)n1]

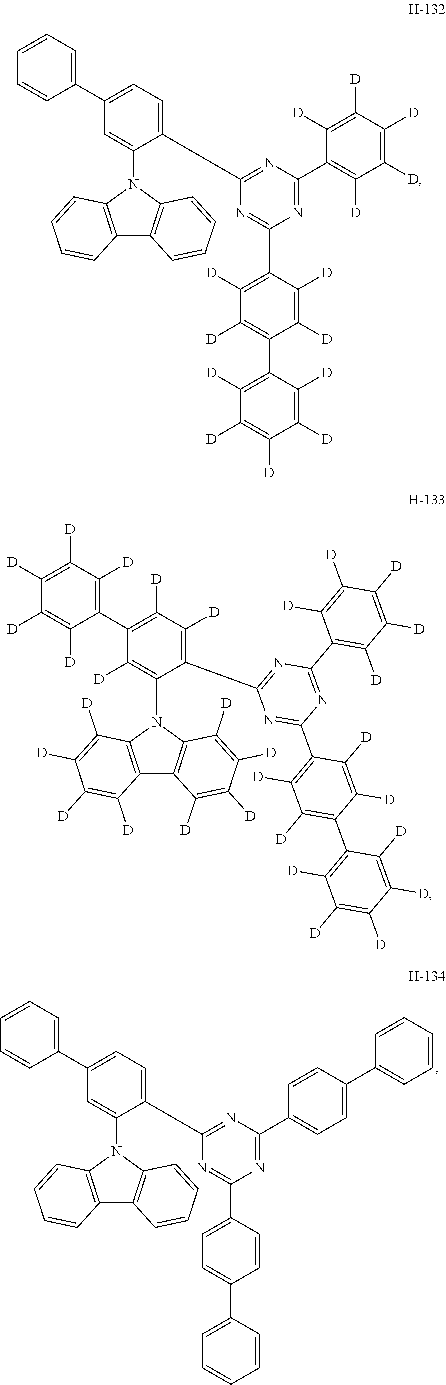

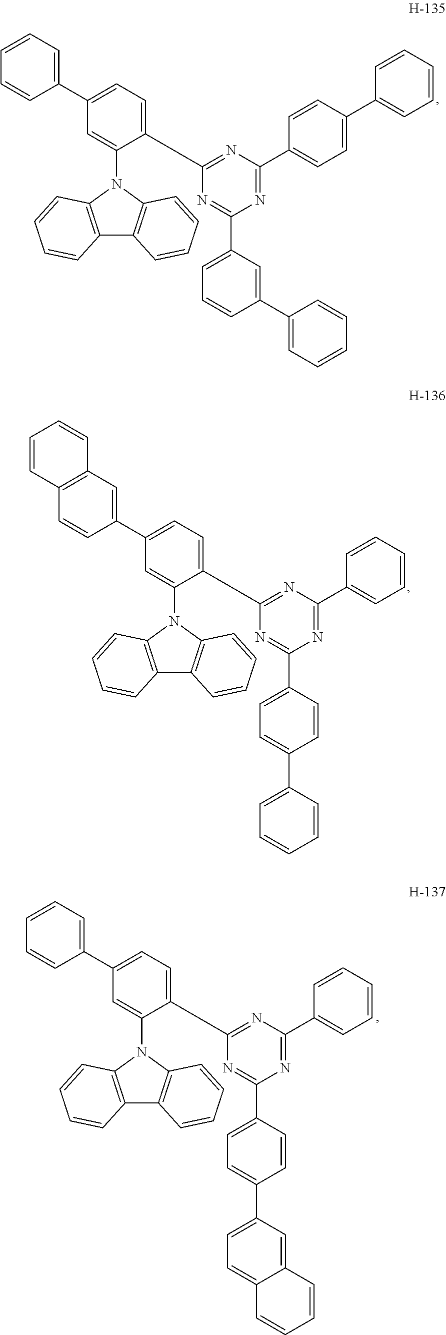 [SMILES: c1ccc(-c2ccc(-c3nc(-c4cccc(-c5ccccc5)c4)nc(-c4ccc(-c5ccccc5)cc4-n4c5ccccc5c5ccccc54)n3)cc2)cc1 ; c1ccc(-c2ccc(-c3nc(-c4ccccc4)nc(-c4ccc(-c5ccc6ccccc6c5)cc4-n4c5ccccc5c5ccccc54)n3)cc2)cc1 ; c1ccc(-c2ccc(-c3nc(-c4ccccc4)nc(-c4ccc(-c5ccc6ccccc6c5)cc4)n3)c(-n3c4ccccc4c4ccccc43)c2)cc1]

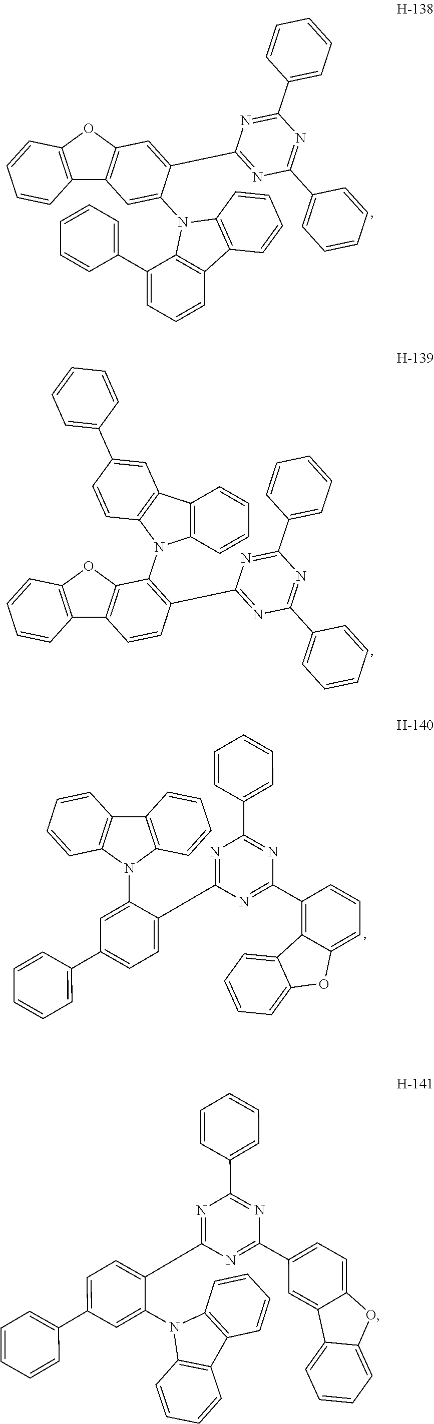 [SMILES: c1ccc(-c2nc(-c3ccccc3)nc(-c3cc4oc5ccccc5c4cc3-n3c4ccccc4c4cccc(-c5ccccc5)c43)n2)cc1 ; c1ccc(-c2ccc3c(c2)c2ccccc2n3-c2c(-c3nc(-c4ccccc4)nc(-c4ccccc4)n3)ccc3c2oc2ccccc23)cc1 ; c1ccc(-c2ccc(-c3nc(-c4ccccc4)nc(-c4cccc5oc6ccccc6c45)n3)c(-n3c4ccccc4c4ccccc43)c2)cc1 ; c1ccc(-c2ccc(-c3nc(-c4ccccc4)nc(-c4ccc5oc6ccccc6c5c4)n3)c(-n3c4ccccc4c4ccccc43)c2)cc1]

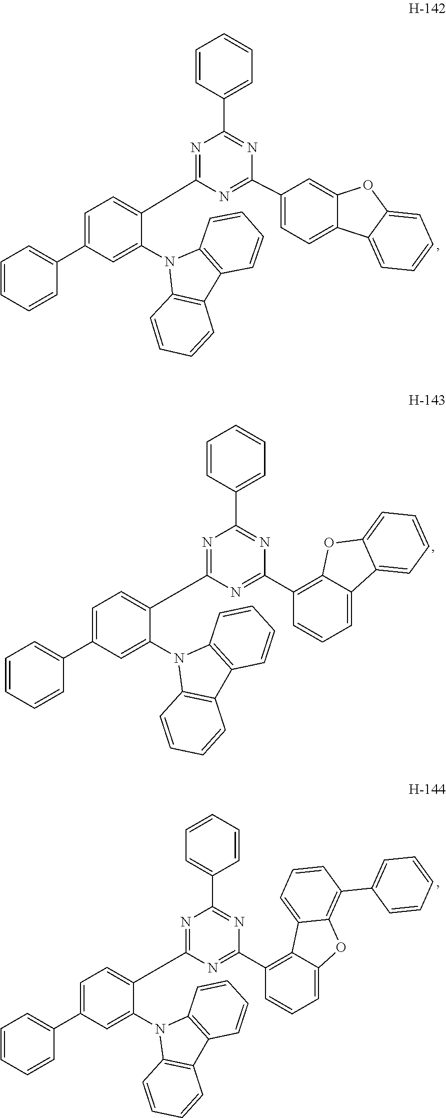 [SMILES: c1ccc(-c2ccc(-c3nc(-c4ccccc4)nc(-c4ccc5c(c4)oc4ccccc45)n3)c(-n3c4ccccc4c4ccccc43)c2)cc1 ; c1ccc(-c2ccc(-c3nc(-c4ccccc4)nc(-c4cccc5c4oc4ccccc45)n3)c(-n3c4ccccc4c4ccccc43)c2)cc1 ; c1ccc(-c2ccc(-c3nc(-c4ccccc4)nc(-c4cccc5oc6c(-c7ccccc7)cccc6c45)n3)c(-n3c4ccccc4c4ccccc43)c2)cc1]

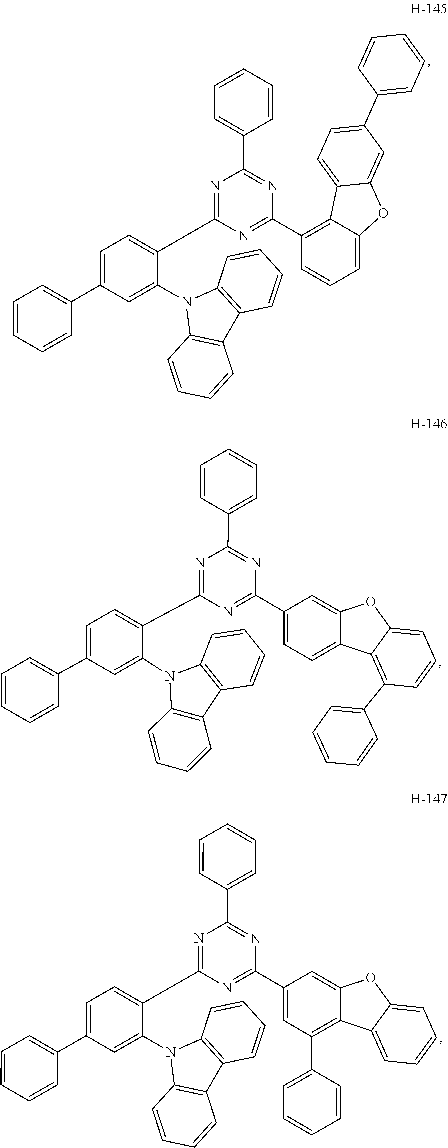 [SMILES: c1ccc(-c2ccc(-c3nc(-c4ccccc4)nc(-c4cccc5oc6cc(-c7ccccc7)ccc6c45)n3)c(-n3c4ccccc4c4ccccc43)c2)cc1 ; c1ccc(-c2ccc(-c3nc(-c4ccccc4)nc(-c4ccc5c(c4)oc4cccc(-c6ccccc6)c45)n3)c(-n3c4ccccc4c4ccccc43)c2)cc1 ; c1ccc(-c2ccc(-c3nc(-c4ccccc4)nc(-c4cc(-c5ccccc5)c5c(c4)oc4ccccc45)n3)c(-n3c4ccccc4c4ccccc43)c2)cc1]

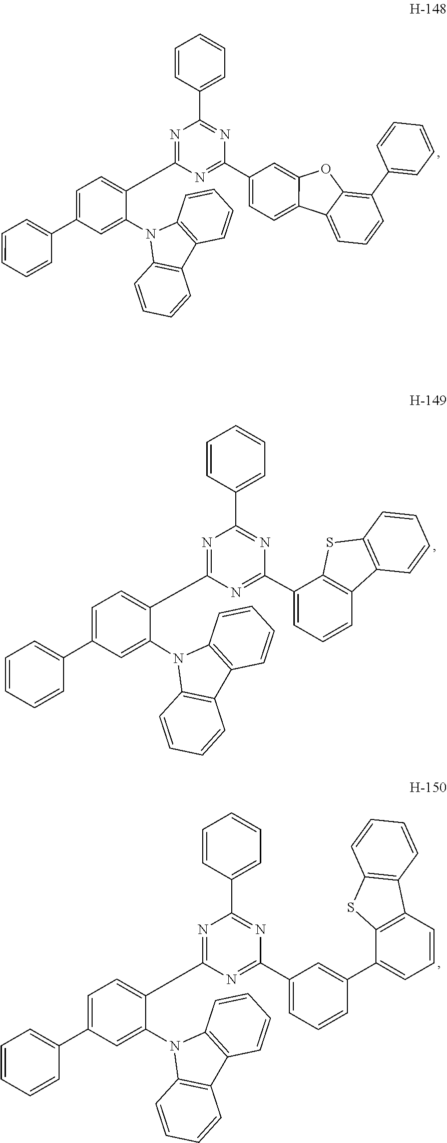 [SMILES: c1ccc(-c2ccc(-c3nc(-c4ccccc4)nc(-c4ccc5c(c4)oc4c(-c6ccccc6)cccc45)n3)c(-n3c4ccccc4c4ccccc43)c2)cc1 ; c1ccc(-c2ccc(-c3nc(-c4ccccc4)nc(-c4cccc5c4sc4ccccc45)n3)c(-n3c4ccccc4c4ccccc43)c2)cc1 ; c1ccc(-c2ccc(-c3nc(-c4ccccc4)nc(-c4cccc(-c5cccc6c5sc5ccccc56)c4)n3)c(-n3c4ccccc4c4ccccc43)c2)cc1]

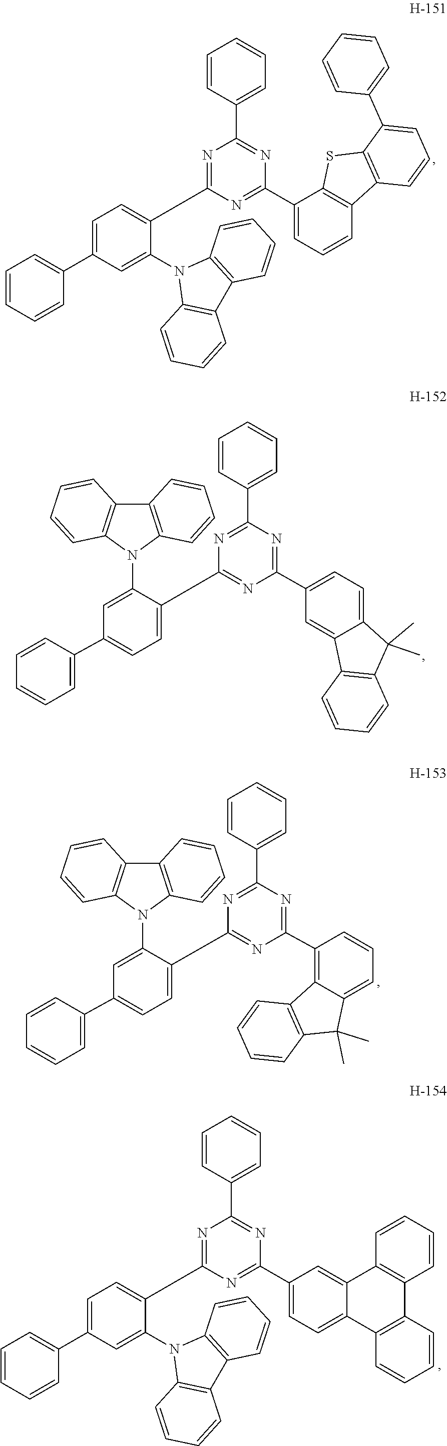 [SMILES: c1ccc(-c2ccc(-c3nc(-c4ccccc4)nc(-c4cccc5c4sc4c(-c6ccccc6)cccc45)n3)c(-n3c4ccccc4c4ccccc43)c2)cc1 ; CC1(C)c2ccccc2-c2cc(-c3nc(-c4ccccc4)nc(-c4ccc(-c5ccccc5)cc4-n4c5ccccc5c5ccccc54)n3)ccc21 ; CC1(C)c2ccccc2-c2c(-c3nc(-c4ccccc4)nc(-c4ccc(-c5ccccc5)cc4-n4c5ccccc5c5ccccc54)n3)cccc21 ; c1ccc(-c2ccc(-c3nc(-c4ccccc4)nc(-c4ccc5c6ccccc6c6ccccc6c5c4)n3)c(-n3c4ccccc4c4ccccc43)c2)cc1]

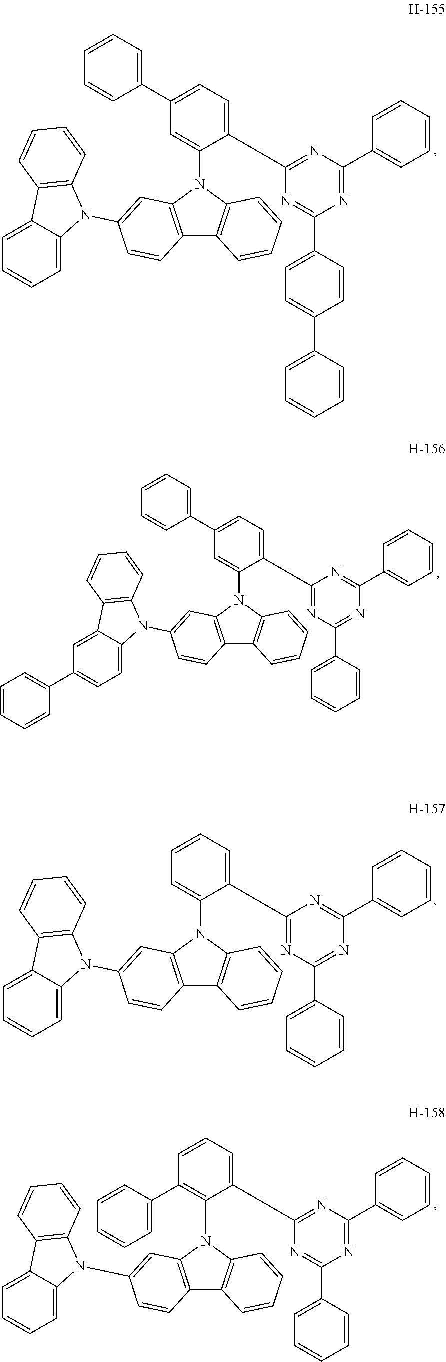 [SMILES: c1ccc(-c2ccc(-c3nc(-c4ccccc4)nc(-c4ccc(-c5ccccc5)cc4-n4c5ccccc5c5ccc(-n6c7ccccc7c7ccccc76)cc54)n3)cc2)cc1 ; c1ccc(-c2ccc(-c3nc(-c4ccccc4)nc(-c4ccccc4)n3)c(-n3c4ccccc4c4ccc(-n5c6ccccc6c6cc(-c7ccccc7)ccc65)cc43)c2)cc1 ; c1ccc(-c2nc(-c3ccccc3)nc(-c3ccccc3-n3c4ccccc4c4ccc(-n5c6ccccc6c6ccccc65)cc43)n2)cc1 ; c1ccc(-c2nc(-c3ccccc3)nc(-c3cccc(-c4ccccc4)c3-n3c4ccccc4c4ccc(-n5c6ccccc6c6ccccc65)cc43)n2)cc1]

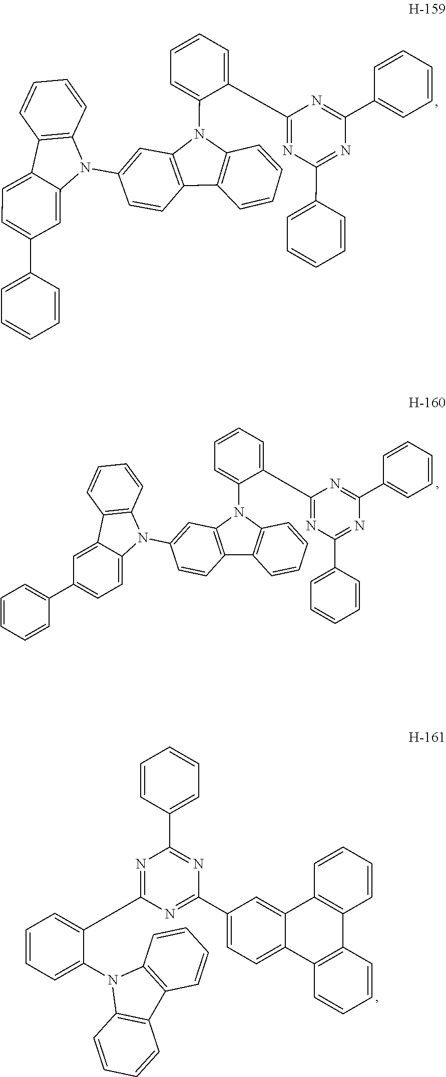 [SMILES: c1ccc(-c2ccc3c4ccccc4n(-c4ccc5c6ccccc6n(-c6ccccc6-c6nc(-c7ccccc7)nc(-c7ccccc7)n6)c5c4)c3c2)cc1 ; c1ccc(-c2ccc3c(c2)c2ccccc2n3-c2ccc3c4ccccc4n(-c4ccccc4-c4nc(-c5ccccc5)nc(-c5ccccc5)n4)c3c2)cc1 ; c1ccc(-c2nc(-c3ccc4c5ccccc5c5ccccc5c4c3)nc(-c3ccccc3-n3c4ccccc4c4ccccc43)n2)cc1]

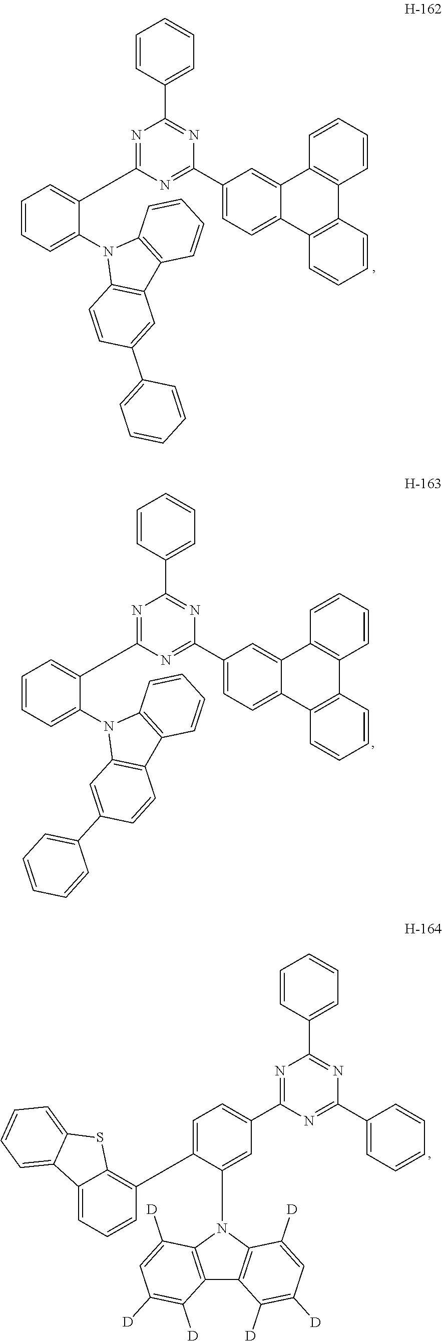 [SMILES: c1ccc(-c2ccc3c(c2)c2ccccc2n3-c2ccccc2-c2nc(-c3ccccc3)nc(-c3ccc4c5ccccc5c5ccccc5c4c3)n2)cc1 ; c1ccc(-c2ccc3c4ccccc4n(-c4ccccc4-c4nc(-c5ccccc5)nc(-c5ccc6c7ccccc7c7ccccc7c6c5)n4)c3c2)cc1 ; [2H]c1cc([2H])c2c(c1[2H])c1c([2H])c([2H])cc([2H])c1n2-c1cc(-c2nc(-c3ccccc3)nc(-c3ccccc3)n2)ccc1-c1cccc2c1sc1ccccc12]

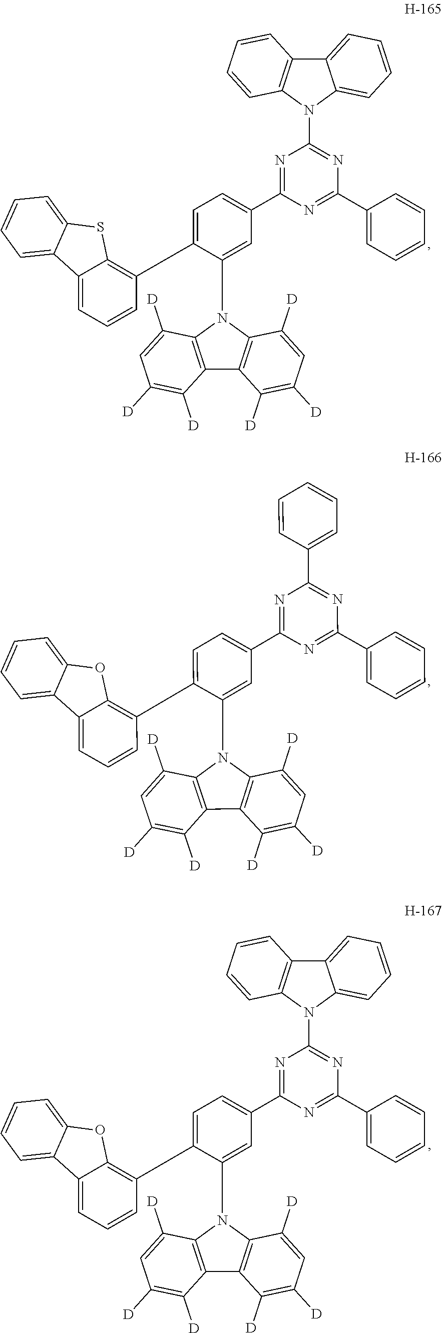 [SMILES: [2H]c1cc([2H])c2c(c1[2H])c1c([2H])c([2H])cc([2H])c1n2-c1cc(-c2nc(-c3ccccc3)nc(-n3c4ccccc4c4ccccc43)n2)ccc1-c1cccc2c1sc1ccccc12 ; [2H]c1cc([2H])c2c(c1[2H])c1c([2H])c([2H])cc([2H])c1n2-c1cc(-c2nc(-c3ccccc3)nc(-c3ccccc3)n2)ccc1-c1cccc2c1oc1ccccc12 ; [2H]c1cc([2H])c2c(c1[2H])c1c([2H])c([2H])cc([2H])c1n2-c1cc(-c2nc(-c3ccccc3)nc(-n3c4ccccc4c4ccccc43)n2)ccc1-c1cccc2c1oc1ccccc12]

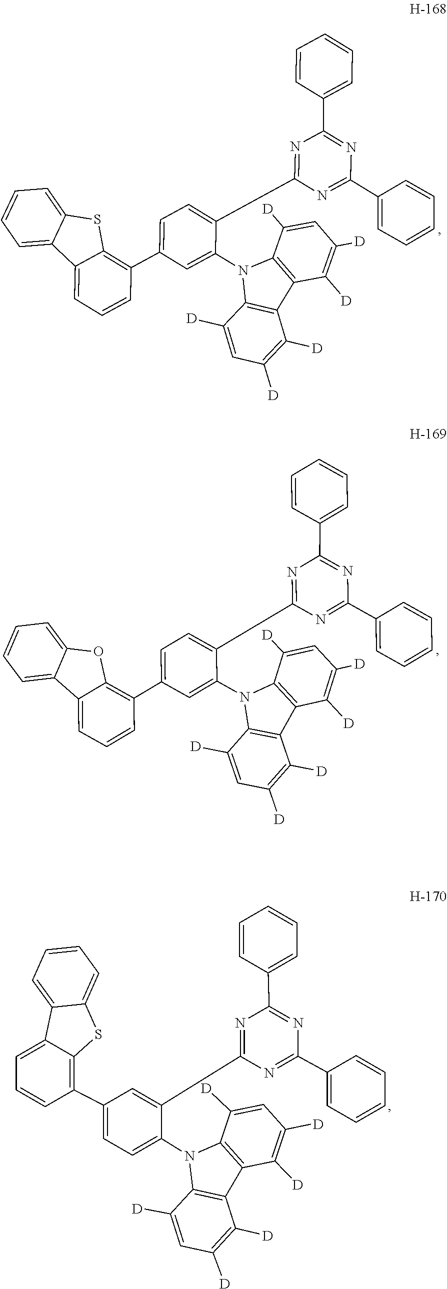 [SMILES: [2H]c1cc([2H])c2c(c1[2H])c1c([2H])c([2H])cc([2H])c1n2-c1cc(-c2cccc3c2sc2ccccc23)ccc1-c1nc(-c2ccccc2)nc(-c2ccccc2)n1 ; [2H]c1cc([2H])c2c(c1[2H])c1c([2H])c([2H])cc([2H])c1n2-c1cc(-c2cccc3c2oc2ccccc23)ccc1-c1nc(-c2ccccc2)nc(-c2ccccc2)n1 ; [2H]c1cc([2H])c2c(c1[2H])c1c([2H])c([2H])cc([2H])c1n2-c1ccc(-c2cccc3c2sc2ccccc23)cc1-c1nc(-c2ccccc2)nc(-c2ccccc2)n1]

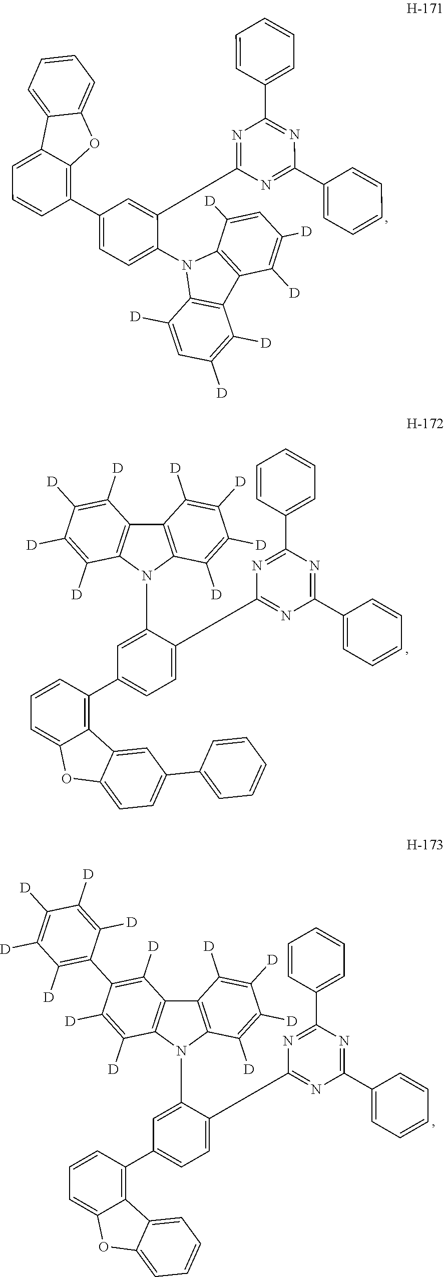 [SMILES: [2H]c1cc([2H])c2c(c1[2H])c1c([2H])c([2H])cc([2H])c1n2-c1ccc(-c2cccc3c2oc2ccccc23)cc1-c1nc(-c2ccccc2)nc(-c2ccccc2)n1 ; [2H]c1c([2H])c([2H])c2c(c1[2H])c1c([2H])c([2H])c([2H])c([2H])c1n2-c1cc(-c2cccc3oc4ccc(-c5ccccc5)cc4c23)ccc1-c1nc(-c2ccccc2)nc(-c2ccccc2)n1 ; [2H]c1c([2H])c([2H])c(-c2c([2H])c([2H])c3c(c2[2H])c2c([2H])c([2H])c([2H])c([2H])c2n3-c2cc(-c3cccc4oc5ccccc5c34)ccc2-c2nc(-c3ccccc3)nc(-c3ccccc3)n2)c([2H])c1[2H]]

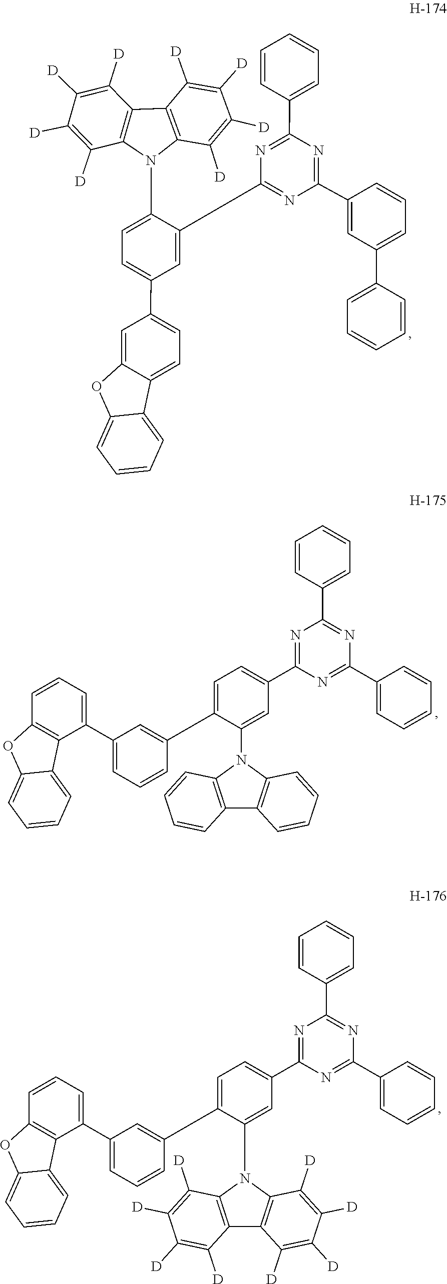 [SMILES: [2H]c1c([2H])c([2H])c2c(c1[2H])c1c([2H])c([2H])c([2H])c([2H])c1n2-c1ccc(-c2ccc3c(c2)oc2ccccc23)cc1-c1nc(-c2ccccc2)nc(-c2cccc(-c3ccccc3)c2)n1 ; c1ccc(-c2nc(-c3ccccc3)nc(-c3ccc(-c4cccc(-c5cccc6oc7ccccc7c56)c4)c(-n4c5ccccc5c5ccccc54)c3)n2)cc1 ; [2H]c1c([2H])c([2H])c2c(c1[2H])c1c([2H])c([2H])c([2H])c([2H])c1n2-c1cc(-c2nc(-c3ccccc3)nc(-c3ccccc3)n2)ccc1-c1cccc(-c2cccc3oc4ccccc4c23)c1]

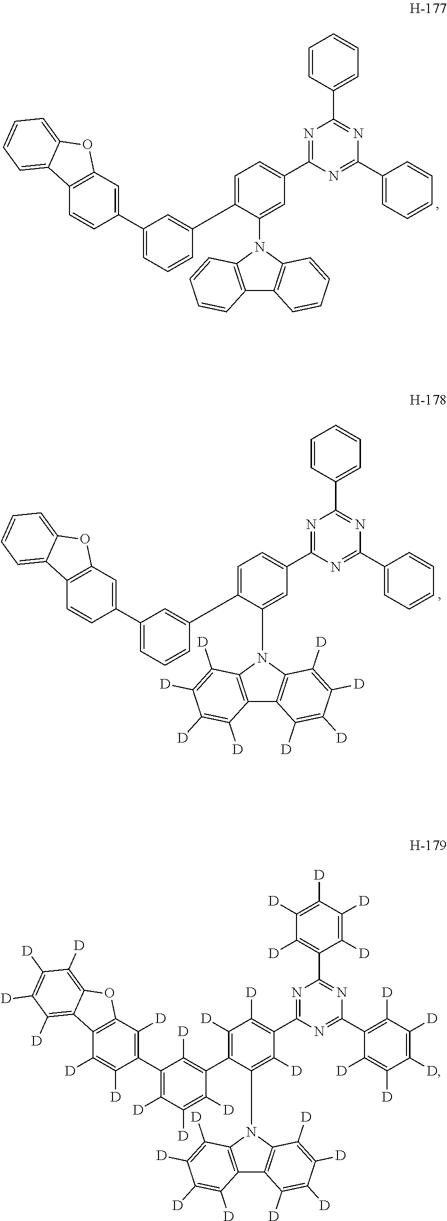

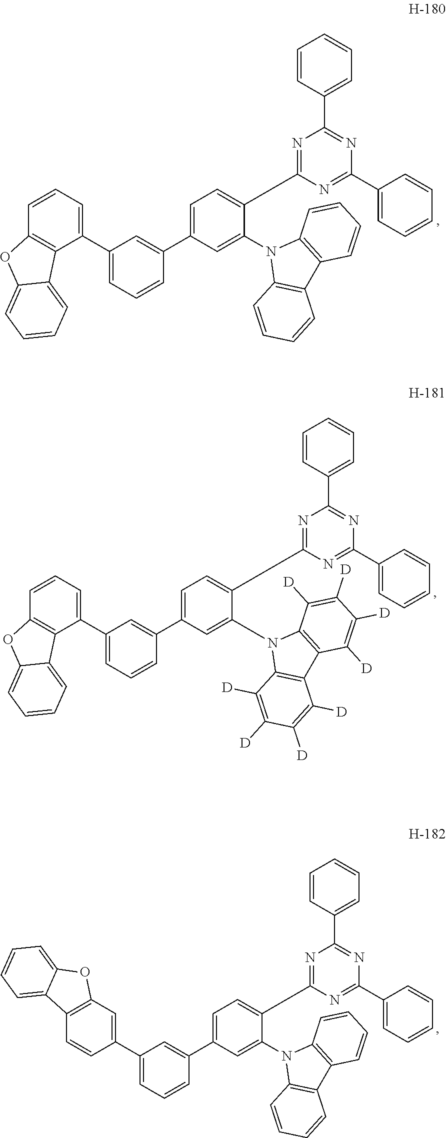 [SMILES: c1ccc(-c2nc(-c3ccccc3)nc(-c3ccc(-c4cccc(-c5cccc6oc7ccccc7c56)c4)cc3-n3c4ccccc4c4ccccc43)n2)cc1 ; [2H]c1c([2H])c([2H])c2c(c1[2H])c1c([2H])c([2H])c([2H])c([2H])c1n2-c1cc(-c2cccc(-c3cccc4oc5ccccc5c34)c2)ccc1-c1nc(-c2ccccc2)nc(-c2ccccc2)n1 ; c1ccc(-c2nc(-c3ccccc3)nc(-c3ccc(-c4cccc(-c5ccc6c(c5)oc5ccccc56)c4)cc3-n3c4ccccc4c4ccccc43)n2)cc1]

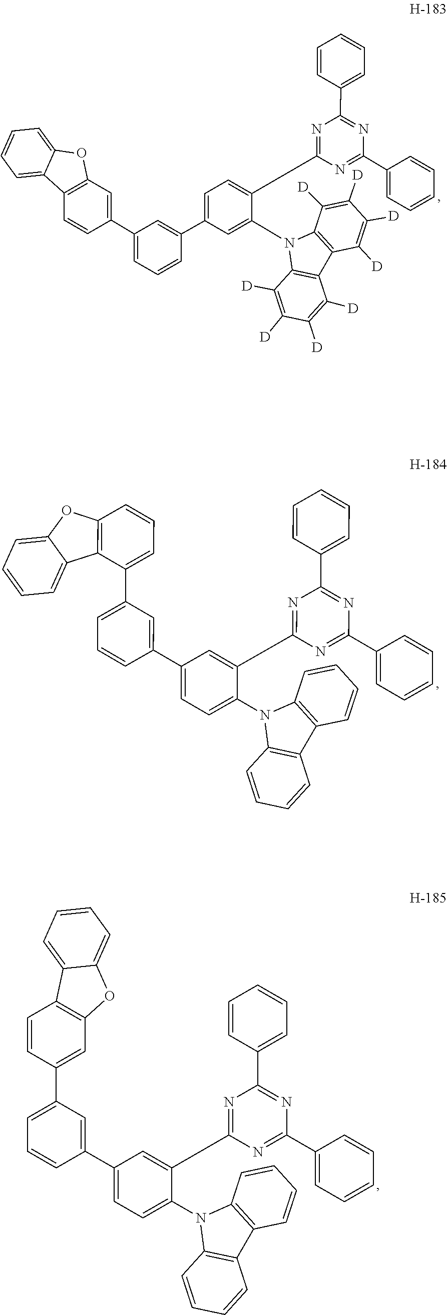 [SMILES: [2H]c1c([2H])c([2H])c2c(c1[2H])c1c([2H])c([2H])c([2H])c([2H])c1n2-c1cc(-c2cccc(-c3ccc4c(c3)oc3ccccc34)c2)ccc1-c1nc(-c2ccccc2)nc(-c2ccccc2)n1 ; c1ccc(-c2nc(-c3ccccc3)nc(-c3cc(-c4cccc(-c5cccc6oc7ccccc7c56)c4)ccc3-n3c4ccccc4c4ccccc43)n2)cc1 ; c1ccc(-c2nc(-c3ccccc3)nc(-c3cc(-c4cccc(-c5ccc6c(c5)oc5ccccc56)c4)ccc3-n3c4ccccc4c4ccccc43)n2)cc1]

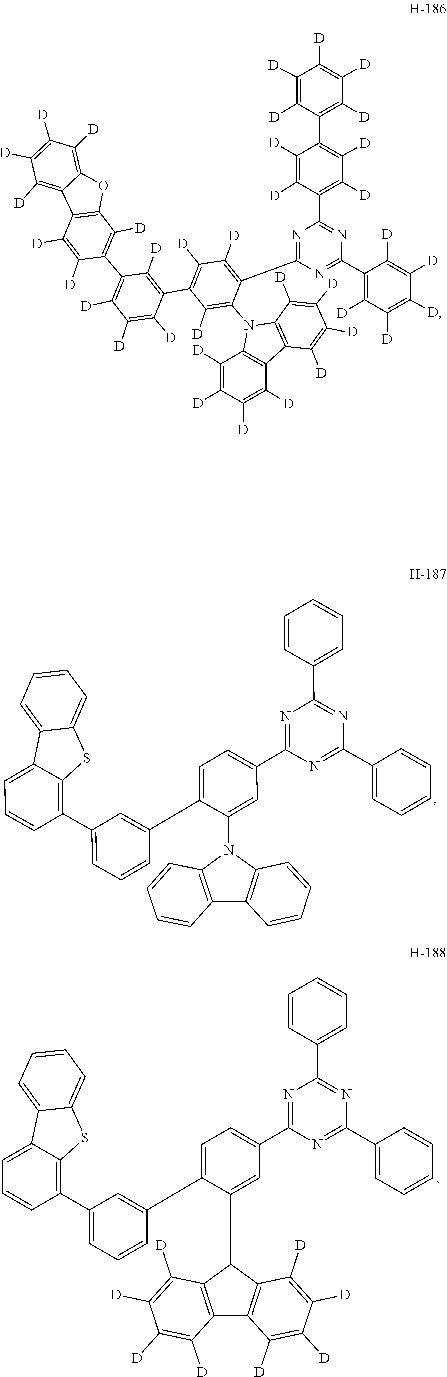

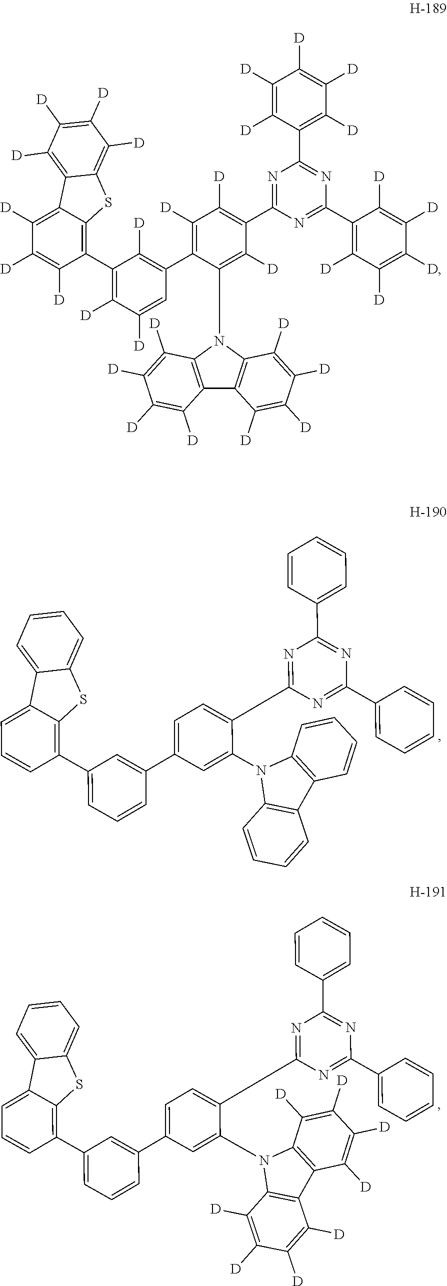

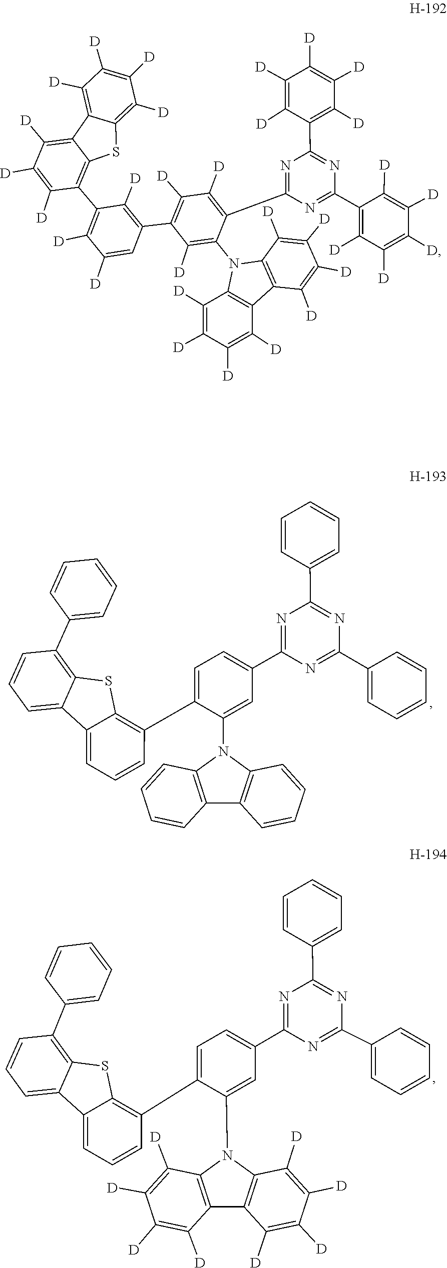

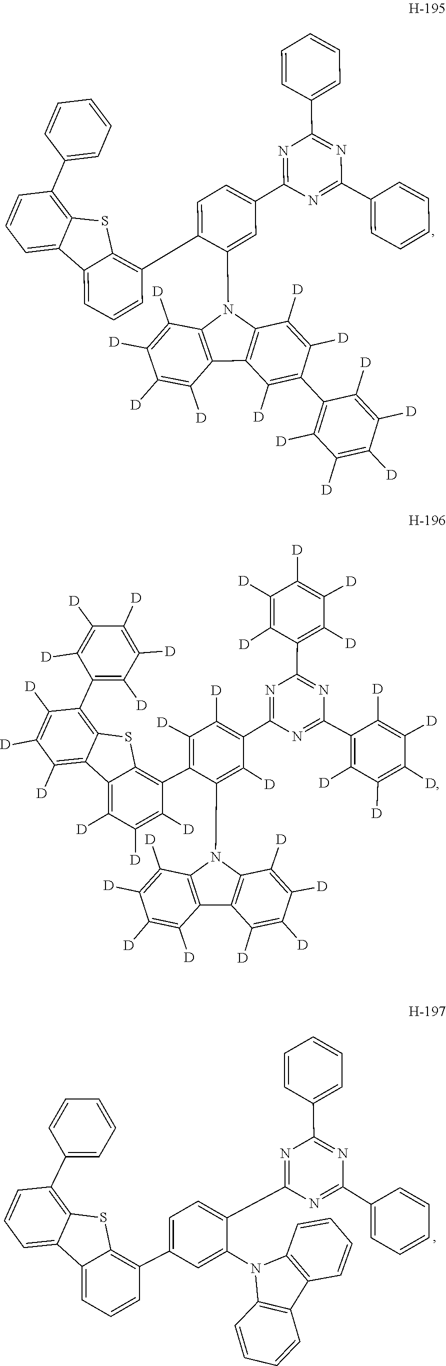

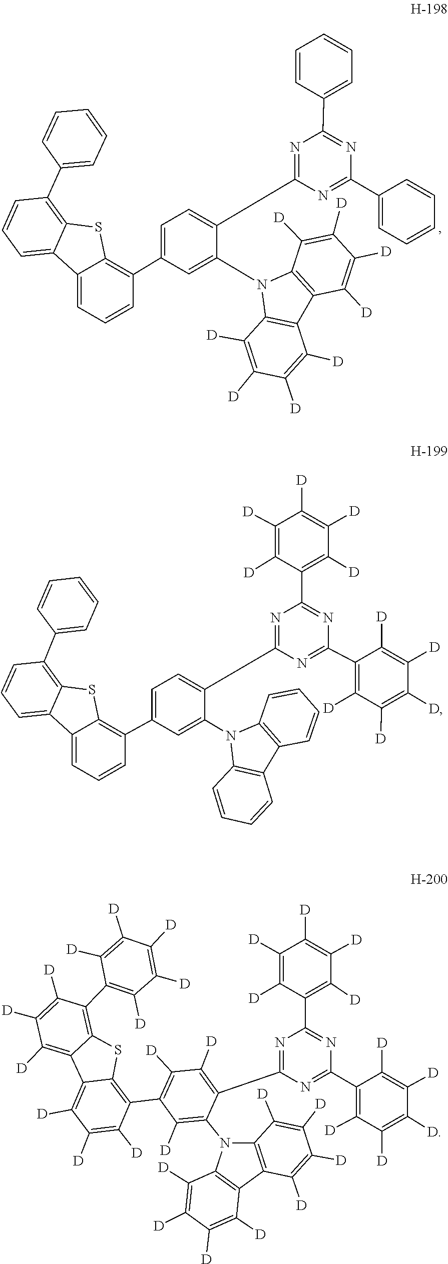

According to an embodiment of the present disclosure, at least one hydrogen in the structure of the first host compound and/or the structure of the second host compound is substituted with deuterium.

According to an embodiment of the present disclosure, hydrogens in the first host compound and/or the second host compound can be partially or fully substituted with deuterium.

According to an embodiment of the present disclosure, the deuteration rate of the first host compound and/or the deuteration rate of the second host compound are 5% to 100%.

According to an embodiment of the present disclosure, the deuteration rate of the first host compound and/or the deuteration rate of the second host compound are 30% to 100%.

According to an embodiment of the present disclosure, the deuteration rate of the first host compound and/or the deuteration rate of the second host compound are 50% to 100%.

In this embodiment, the “deuteration rate of the compound” refers to a percentage of the number of deuteriums in the compound structure relative to the total number of hydrogens and deuteriums in the compound structure.

According to an embodiment of the present disclosure, the compound is doped in the first host compound and the second host compound, and a weight of the compound accounts for 0.01% to 30% of a total weight of the emissive layer.

According to an embodiment of the present disclosure, the compound is doped in the first host compound and the second host compound, and a weight of the compound accounts for 0.1% to 30% of a total weight of the emissive layer.

According to an embodiment of the present disclosure, the compound is doped in the first host compound and the second host compound, and a weight of the compound accounts for 0.5% to 13% of a total weight of the emissive layer.

According to another embodiment of the present disclosure, further disclosed is a compound composition comprising the compound of any one of the preceding embodiments.

According to another embodiment of the present disclosure, further disclosed is a display device comprising the organic electroluminescent device of any one of the preceding embodiments.

According to another embodiment of the present disclosure, further disclosed is an application of the organic electroluminescent device of any one of the preceding embodiments in a display device.

### Combination with Other Materials

The materials described in the present disclosure for a particular layer in an organic light emitting device can be used in combination with various other materials present in the device. The combinations of these materials are described in more detail in U.S. Pat. Pub. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of hosts, dopants, transporting layers, blocking layers, injection layers, electrodes, and other layers that may be present. The combination of these materials is described in detail in paragraphs 0080-0101 of U.S. Pat. Pub. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art.

### Material Synthesis Example

A method for preparing the compound of the present disclosure is not limited. Typically, the following compounds are used as examples without limitation, and the synthesis routes and preparation methods thereof are described below.

### Synthesis Example 1

### Synthesis of Compound 3-2-8

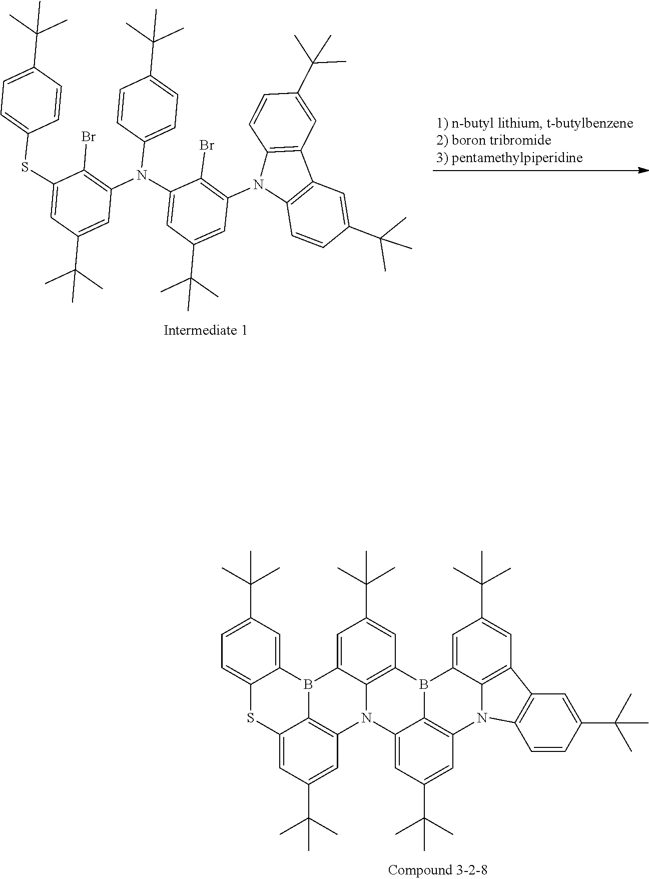

Under nitrogen protection at room temperature, Intermediate 1 (5.6 g, 5.5 mmol) was added to tert-butylbenzene (80.0 ml), and n-butyllithium (13.8 mmol) was added at −70° C. The mixture was allowed to react at room temperature for 1.5 h, heated to 60° C. and reacted for 1 h. The mixture was cooled to 0° C., and boron tribromide (16.1 mmol) was added. The mixture was heated to 80° C. and reacted for 12 h. The mixture was cooled to 0° C., and pentamethylpiperidine (19.2 mmol) was added. The mixture was heated to 180° C. and reacted for 48 h. After cooling, the mixture was filtered, and the filtrate was concentrated and subjected to column chromatography (toluene/n-hexane=1/5) to obtain an orange solid Compound 3-2-8 (360 mg, 0.4 mmol, with a yield of 7%). The product was confirmed as the target product with a molecular weight of 870.5.

### Synthesis Example 2

### Synthesis of Compound 4-1-94

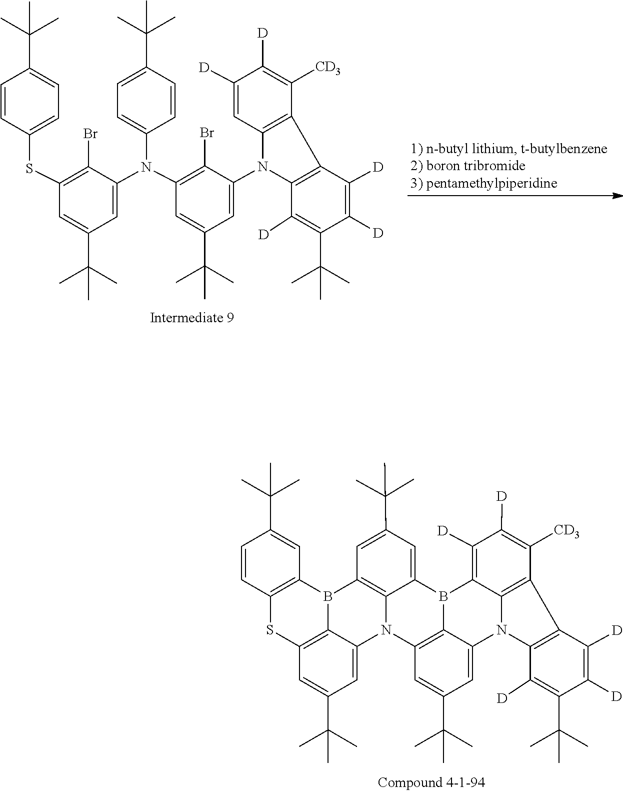 [SMILES: [2H]c1cc2c(c(C([2H])([2H])[2H])c1[2H])c1c([2H])c([2H])c(C(C)(C)C)c([2H])c1n2-c1cc(C(C)(C)C)cc(N(c2ccc(C(C)(C)C)cc2)c2cc(C(C)(C)C)cc(Sc3ccc(C(C)(C)C)cc3)c2Br)c1Br ; [2H]c1c(C(C)(C)C)c([2H])c2c(c1[2H])c1c(C([2H])([2H])[2H])c([2H])c([2H])c3c1n2-c1cc(C(C)(C)C)cc2c1B3c1cc(C(C)(C)C)cc3c1N2c1cc(C(C)(C)C)cc2c1B3c1cc(C(C)(C)C)ccc1S2]

Under nitrogen protection at room temperature, Intermediate 9 (6.8 g, 6.9 mmol) was added to tert-butylbenzene (100.0 ml), and n-butyllithium (16.0 mmol) was added at −70° C. The mixture was allowed to react at room temperature for 1.5 h, heated to 60° C. and reacted for 1 h. The mixture was cooled to 0° C., and boron tribromide (19.5 mmol) was added. The mixture was heated to 80° C. and reacted for 12 h. The mixture was cooled to 0° C., and pentamethylpiperidine (41.8 mmol) was added. The mixture was heated to 180° C. and reacted for 48 h. After cooling, the mixture was filtered, and the filtrate was concentrated and subjected to column chromatography (toluene/n-hexane=1/5) to obtain an orange solid Compound 4-1-94 (250 mg, 0.3 mmol, with a yield of 4%). The product was confirmed as the target product with a molecular weight of 836.48.

A method for preparing an electroluminescent device is not limited. The preparation methods of the following examples are merely illustrative and are not to be construed as limiting. Based on the related art, those skilled in the art can make reasonable improvements on the preparation methods of the following examples. For example, the proportions of various materials in an emissive layer are not particularly limited. Those skilled in the art can reasonably select the proportions within certain ranges based on the related art. For example, with the total weight of the materials in the emissive layer for reference, a host material may account for 75% to 98%, a metal complex may account for 1% to 20%, and a fluorescent material may account for 0.01% to 5%; or the host material may account for 88% to 98%, the metal complex may account for 0.05% to 3%, and the fluorescent material may account for 0.1% to 1%. Further, the host material comprises two materials, where the ratio of the two host materials may range from 99:1 to 1:99, the ratio may range from 80:20 to 20:80, or the ratio may range from 70:30 to 30:70. In device examples, the characteristics of a device were tested using the conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP) by methods well-known to the persons skilled in the art. As the persons skilled in the art are aware of the above-mentioned equipment use, test methods, and other related contents, the inherent data of the sample can be obtained with certainty and without influence, so the above related contents are not further described in this patent.

### Device Example

### Device Example 1

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. The organic layers specified below were sequentially deposited through vacuum thermal evaporation on the ITO anode at a rate of 0.2-2 Angstroms per second and a vacuum degree of about 10-8 Torr. Compound HT and Compound HT1 were co-deposited for use as a hole injection layer (HIL). Compound HT was used as a hole transport layer (HTL). Compound PH-1 was used as an electron blocking layer (EBL). Then, First Host Compound PH-87, Second Host Compound H-102, and Compound 3-2-8 of the present disclosure were co-deposited for use as an emissive layer. On the EML, Compound H-1 was used as a hole blocking layer (HBL). On the HBL, Compound ET and 8-hydroxyquinolinolato-lithium (Liq) were co-deposited for use as an electron transport layer (ETL). Finally, Liq was deposited for use as an electron injection layer with a thickness of 1 nm and Al was deposited for use as a cathode with a thickness of 120 nm. The device was transferred back to the glovebox and encapsulated with a glass lid and a moisture getter to complete the device.

### Device Example 2

The implementation mode in Device Example 2 was the same as that in Device Example 1, except that First Host Compound PH-87, Second Host Compound H-102, and Compound 4-1-94 of the present invention were co-deposited for use as an emissive layer (EML).

### Device Comparative Example 1

The implementation mode in Device Comparative Example 1 was the same as that in Device Example 2, except that First Host Compound PH-87, Second Host Compound H-102, and Compound A were co-deposited for use as an emissive layer (EML).

The detailed structures and thicknesses of layers of the devices are shown in Table 1. A layer using more than one material is obtained by doping different compounds at their weight ratio as recorded.

TABLE 1
Device structure in Example 1 to Example 2 and Comparative Example 1

| Device ID | HIL | HTL | EBL | EML | HBL | ETL |
|---|---|---|---|---|---|---|
| Example 1 | Compound | Compound | Compound | PH-87:H-102:Compound | Compound | Compound |
| | HT:Compound | HT | PH-1 | 3-2-8 | H-1 | ET:Liq |
| | HT1 (97:3) | (350 Å) | (50 Å) | (59:40:1) (400 Å) | (50 Å) | (40:60) |
| | (100 Å) | | | | | (350 Å) |
| Example 2 | Compound | Compound | Compound | PH-87:H-102:Compound | Compound | Compound |
| | HT:Compound | HT | PH-1 | 4-1-94 | H-1 | ET:Liq |
| | HT1 (97:3) | (350 Å) | (50 Å) | (59:40:1) (400 Å) | (50 Å) | (40:60) |
| | (100 Å) | | | | | (350 Å) |
| Comparative | Compound | Compound | Compound | PH-87:H-102:Compound | Compound | Compound |
| Example 1 | HT:Compound | HT | PH-1 | A | H-1 | ET:Liq |
| | HT1 (97:3) | (350 Å) | (50 Å) | (59:40:1) (400 Å) | (50 Å) | (40:60) |
| | (100 Å) | | | | | (350 Å) |

Some of the materials used in the devices are as follows:

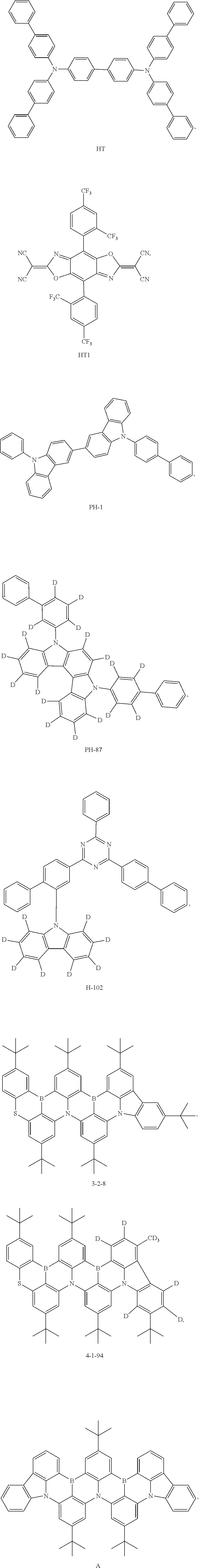

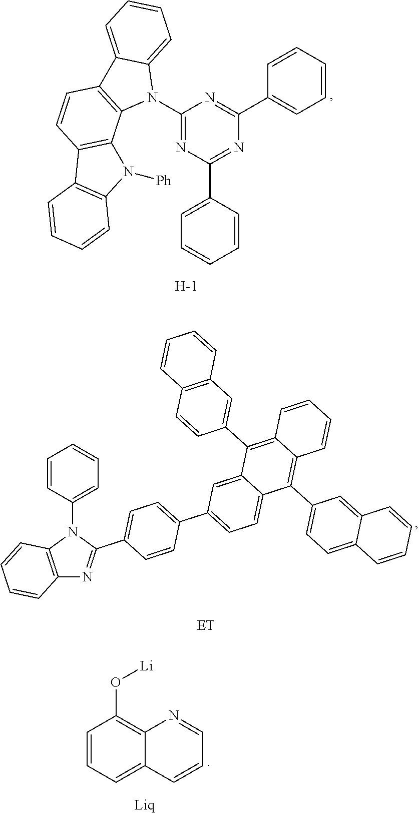

At a constant luminance of 1000 cd/m², the CIE data, maximum emission wavelength (λₘₐₓ), full width at half maximum (FWHM), drive voltage (V), current efficiency (CE), power efficiency (PE), and external quantum efficiency (EQE) of each device were measured. The data are recorded and shown in Table 2.

TABLE 2
Device data in Example 1 to Example 2 and Comparative Example 1

| | | λₘₐₓ | FWHM | Voltage | CE | PE | |
|---|---|---|---|---|---|---|---|
| Device ID | CIE (x, y) | (nm) | (nm) | (V) | (cd/A) | (lm/W) | EQE (%) |
| Example 1 | (0.296, 0.682) | 539 | 33.6 | 2.59 | 108 | 131 | 25.33 |
| Example 2 | (0.274, 0.698) | 535 | 33.4 | 2.59 | 110 | 134 | 26.10 |
| Comparative | (0.341, 0.646) | 546 | 33.8 | 2.63 | 105 | 125 | 24.11 |
| Example 1 | | | | | | | |

As can be seen from the data in Table 2, Device Example 1 where the compound having a structure of Formula 1 of the present disclosure is used as a fluorescent material has a CIE color coordinate of (0.296, 0.682) and a maximum emission wavelength of about 539 nm, Device Example 2 where the compound having a structure of Formula 1 of the present disclosure is used as a fluorescent material has a CIE color coordinate of (0.274, 0.698) and a maximum emission wavelength of about 535 nm, thus achieving particular green light emission. Moreover, in terms of device performance, Example 1 and Example 2 also have a relatively narrow full width at half maximum, a low level of driving voltage, and relatively high efficiency. This indicates that when the compound having the structure of Formula 1 of the present disclosure is used as the fluorescent material, a fluorescent device having particular green light emission and excellent overall performance can be obtained, thus having broad application prospects. Further, to perform a more in-depth research on the luminescence performance of the compound of the present disclosure, the inventors of the present disclosure also performed a series of simulation experiments: Compound 3-2-8 of the present disclosure, Comparative Compound a, and Comparative Compound b were subjected to DFT calculations by using a B3LYP hybrid functional and a 6-311G** basis set in a Gaussian software package in a tetrahydrofuran (THF) solvent environment simulated by a solvation model based on density (SMD). The singlet energy levels (S1) of the compounds were obtained, and the maximum emission wavelengths λₘₐₓ (nm) of the photoluminescence spectrums of the compounds were obtained through conversion according to the formula λₘₐₓ (nm)=1240/S1. The data are recorded and listed in Table 3.

TABLE 3
λₘₐₓ data of compounds

| Compound No. | λₘₐₓ (nm) |
|---|---|
| Compound 3-2-8 | 527.08 |
| Comparative Compound a | 518.07 |
| Comparative Compound b | 547.52 |

The compounds have the following structures:

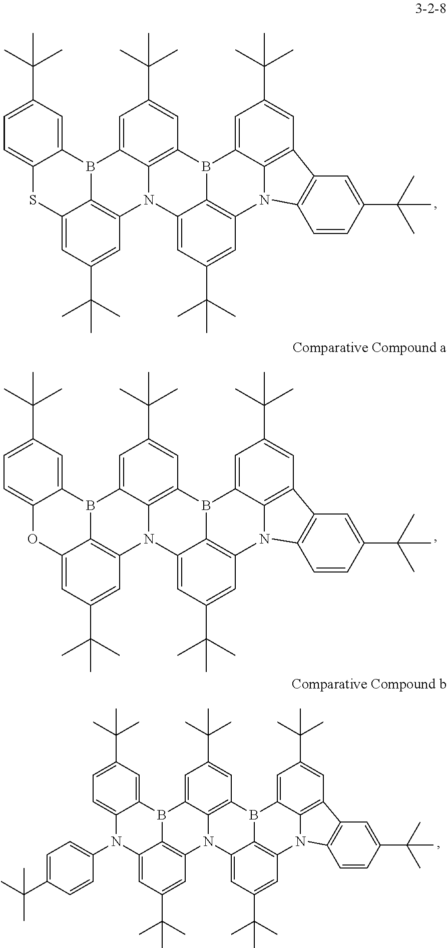

Compound 3-2-8 of the present disclosure differs from Comparative Compound a and Comparative Compound b only in that Z₃ atoms in the corresponding structure of General Formula 1 are different. As can be seen from the data in Table 3, the maximum emission wavelength of Comparative Compound a where Z₃ is selected from O is blueshifted by about 9 nm compared with that of Compound 3-2-8 of the present disclosure, while the maximum emission wavelength of Comparative Compound b where Z₃ is selected from N is redshifted by about 20 nm compared with that of Compound 3-2-8 of the present disclosure. Those skilled in the art know that there may be a certain deviation between the simulated data and the measured data within a reasonable range, but the variation trends should be the same. Therefore, the results of the relative blueshift and the relative redshift appearing in the calculated data should be consistent with the relative variation trends in the measured data, and the results of such relative variations are credible.

According to the measured maximum emission wavelength of the device example using Compound 3-2-8 of the present disclosure in Table 2 and the relative variation trend in Table 3, it can be inferred that the Comparative Compound would achieve a blue-green light emission, and the Comparative Compound b would achieve a yellow-green light emission, while the compound having the structure of Formula 1 of the present disclosure would achieve a particular green light emission with a wavelength between the wavelength of the blue-green light emission and the wavelength of the yellow-green light emission, thus having broad application prospects.

Further, the inventors of the present disclosure also performed a series of simulation experiments: Compound 4-1-106 of the present disclosure, Comparative Compound c, and Comparative Compound d were subjected to DFT calculations by using a B3LYP hybrid functional and a 6-311G** basis set in a Gaussian software package in a tetrahydrofuran (THF) solvent environment simulated by a solvation model based on density (SMD). The singlet energy levels (S1) of the compounds were obtained, and the maximum emission wavelengths λₘₐₓ (nm) of the photoluminescence spectrums of the compounds were obtained through conversion according to the formula λₘₐₓ (nm)=1240/S1. The data are recorded and listed in Table 4.

TABLE 4
λₘₐₓ data of compounds

| Compound No. | λₘₐₓ (nm) |
|---|---|
| Compound 4-1-106 | 521.64 |
| Comparative Compound c | 530.68 |
| Comparative Compound d | 539.84 |

The compounds have the following structures:

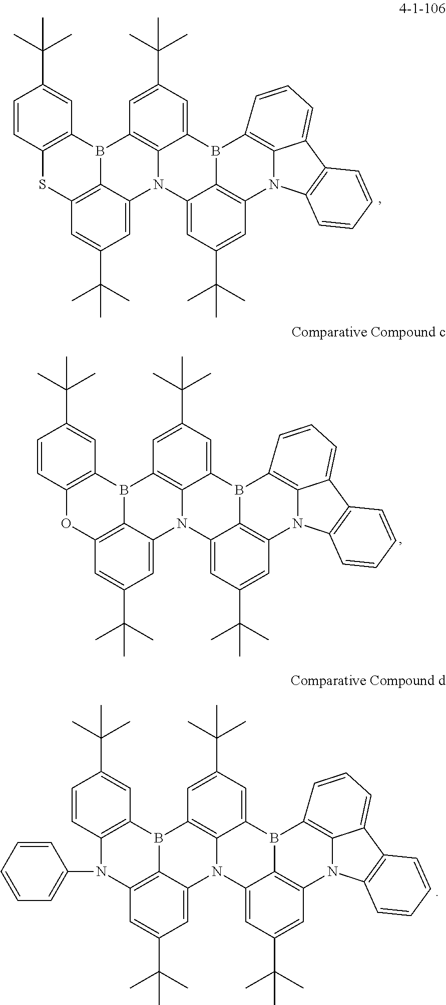 [SMILES: CC(C)(C)c1ccc2c(c1)B1c3cc(C(C)(C)C)cc4c3N(c3cc(C(C)(C)C)cc(c31)S2)c1cc(C(C)(C)C)cc2c1B4c1cccc3c4ccccc4n-2c13 ; CC(C)(C)c1ccc2c(c1)B1c3cc(C(C)(C)C)cc4c3N(c3cc(C(C)(C)C)cc(c31)O2)c1cc(C(C)(C)C)cc2c1B4c1cccc3c4ccccc4n-2c13 ; CC(C)(C)c1ccc2c(c1)B1c3cc(C(C)(C)C)cc4c3N(c3cc(C(C)(C)C)cc(c31)N2c1ccccc1)c1cc(C(C)(C)C)cc2c1B4c1cccc3c4ccccc4n-2c13]

Compound 4-1-106 of the present disclosure differs from Comparative Compound c and Comparative Compound d only in that Z₃ atoms in the corresponding structure of General Formula 1 are different. As can be seen from the data in Table 4, the maximum emission wavelength of Comparative Compound c where Z₃ is selected from O is blueshifted by about 9 nm compared with that of Compound 4-1-106 of the present disclosure, while the maximum emission wavelength of Comparative Compound d where Z₃ is selected from N is redshifted by about 9 nm compared with that of Compound 4-1-106 of the present disclosure. Those skilled in the art know that there may be a certain deviation between the simulated data and the measured data within a reasonable range, but the variation trends should be the same. Therefore, the results of the relative blueshift and the relative redshift appearing in the calculated data should be consistent with the relative variation trends in the measured data, and the results of such relative variations are credible. Meanwhile, the calculated data of Compound 4-1-106 of the present disclosure and Comparative Compounds c and d show the same trend as that of the aforementioned Compound 3-2-8 and Comparative Compounds a and b, further demonstrating the reliability of the calculated data.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. A compound having a structure represented by Formula 1: 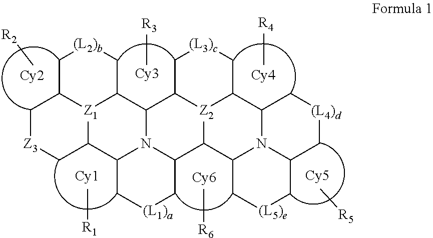
wherein,
the ring Cy1, the ring Cy2, the ring Cy3, the ring Cy4, the ring Cy5, and the ring Cy6 are, at each occurrence identically or differently, selected from an unsaturated carbocyclic ring having 5 to 30 carbon atoms, an unsaturated heterocyclic ring having 3 to 30 carbon atoms, or a combination thereof;
Z₁ and Z₂ are, at each occurrence identically or differently, selected from B, N, P, P═O, P═S, As, As═O, or As═S;
Z₃ is, at each occurrence identically or differently, selected from S, SiRR, GeRR, C═O, C═S, or C═CRR; when multiple R are present, the multiple R are identical or different;
L₁, L₂, L₃, L₄, and L₅ are, at each occurrence identically or differently, selected from a single bond, O, S, Se, BR′, NR′, PR′, P═OR′, P═SR′, AsR′, As═OR′, As═SR′, C═O, CR′R′, SiR′R′, or GeR′R′; when multiple R′ are present, the multiple R′ are identical or different;
a, b, c, d, and e are each independently selected from 0 or 1;
R₁, R₂, R₃, R₄, R₅, and R₆ represent, at each occurrence identically or differently, mono-substitution, multiple substitutions, or non-substitution;
R, R′, R₁, R₂, R₃, R₄, R₅, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, R′, R″, R₁, R₂, R₃, R₄, R₅, and R₆ can be optionally joined to form a ring.

2. The compound of claim 1, wherein the ring Cy1, the ring Cy2, the ring Cy3, the ring Cy4, the ring Cy5, and the ring Cy6 are, at each occurrence identically or differently, selected from a five-membered unsaturated carbocyclic ring, an aromatic ring having 6 to 18 carbon atoms, a heteroaromatic ring having 3 to 18 carbon atoms, or a combination thereof;
preferably, the ring Cy1, the ring Cy2, the ring Cy3, the ring Cy4, the ring Cy5, and the ring Cy6 are, at each occurrence identically or differently, selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring, or a combination thereof; and
more preferably, the ring Cy1, the ring Cy2, the ring Cy3, the ring Cy4, the ring Cy5, and the ring Cy6 are, at each occurrence identically or differently, selected from a benzene ring.

3. The compound of claim 1, wherein L₁, L₂, L₃, L₄, and L₅ are, at each occurrence identically or differently, selected from a single bond, O, S, Se, BR′, NR′, P═OR′, CR′R′, or SiR′R′; and the R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof;
preferably, L₁, L₂, L₃, L₄, and L₅ are, at each occurrence identically or differently, selected from a single bond, O, S, NR′, or CR′R′; and the R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof; and
more preferably, L₁, L₂, L₃, L₄, and L₅ are each a single bond.

4. The compound of claim 1, wherein a+b+c+d+e=0, 1, or 2; preferably, a+d+e=1 or 2; more preferably, d+e=1 or 2; still more preferably, a, b, c, and e are all 0, and d=1.

5. The compound of claim 1, wherein the compound has a structure represented by Formula 2-1 to Formula 2-20: 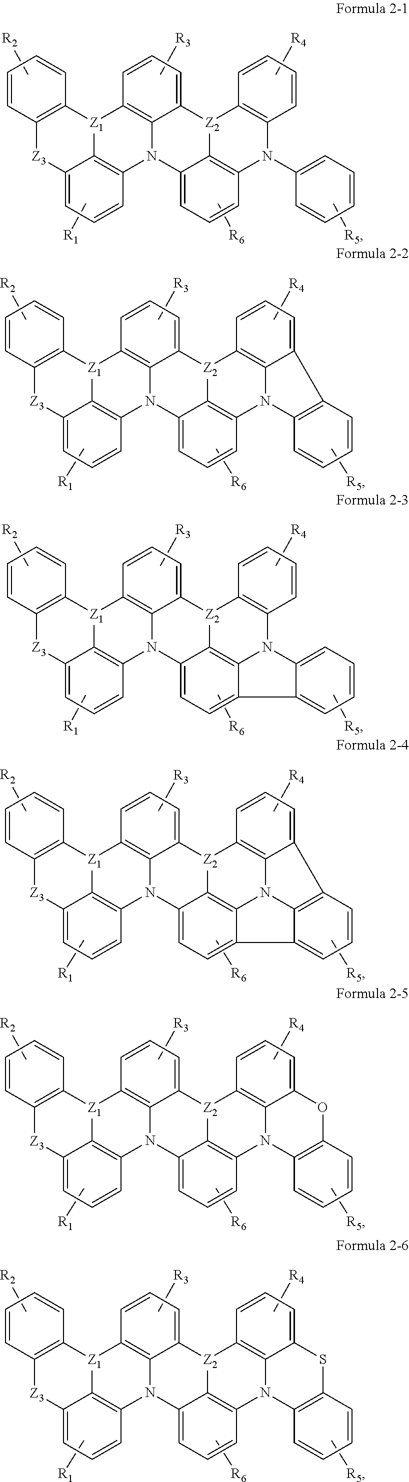 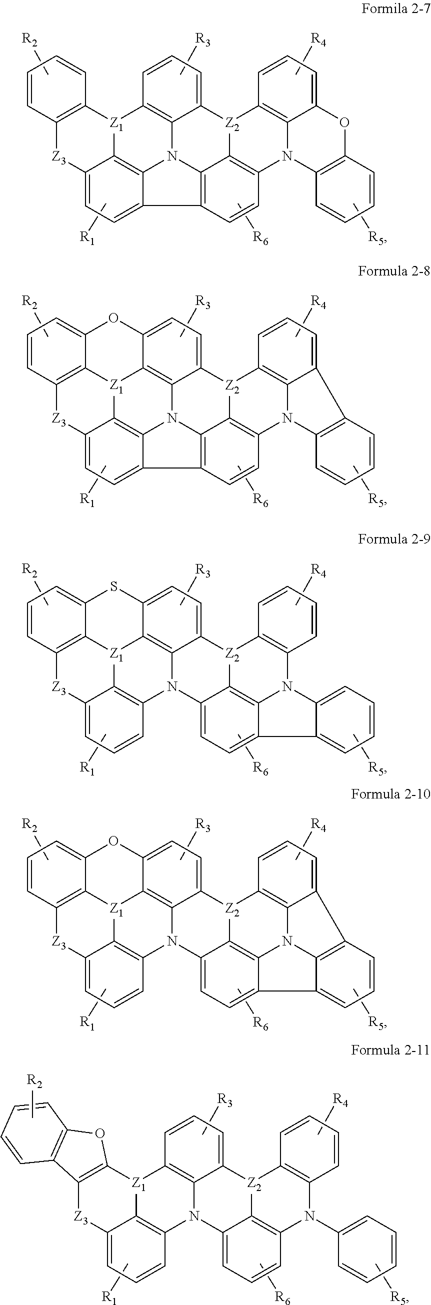 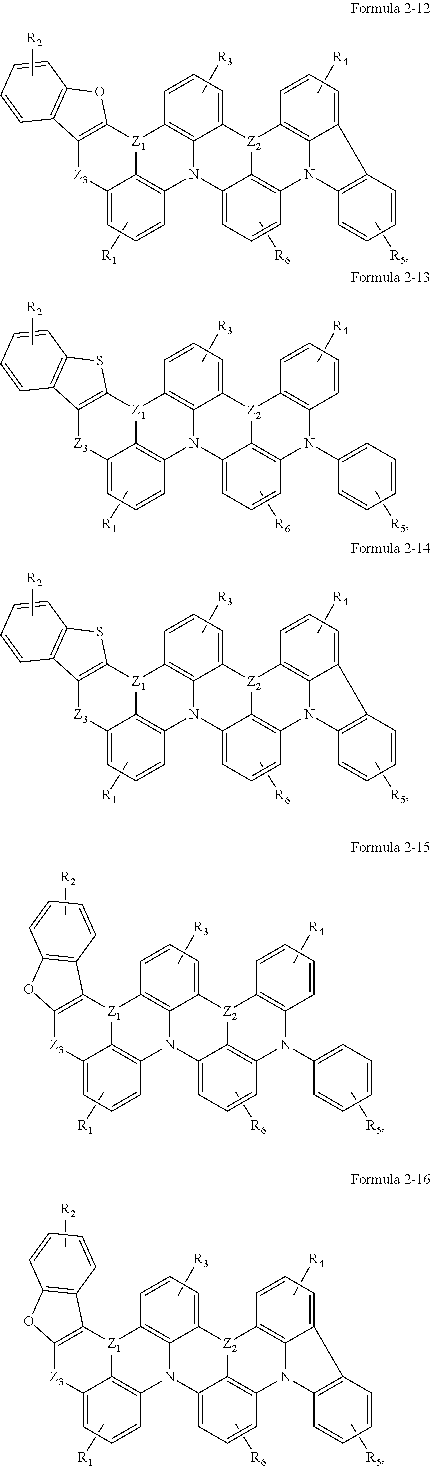 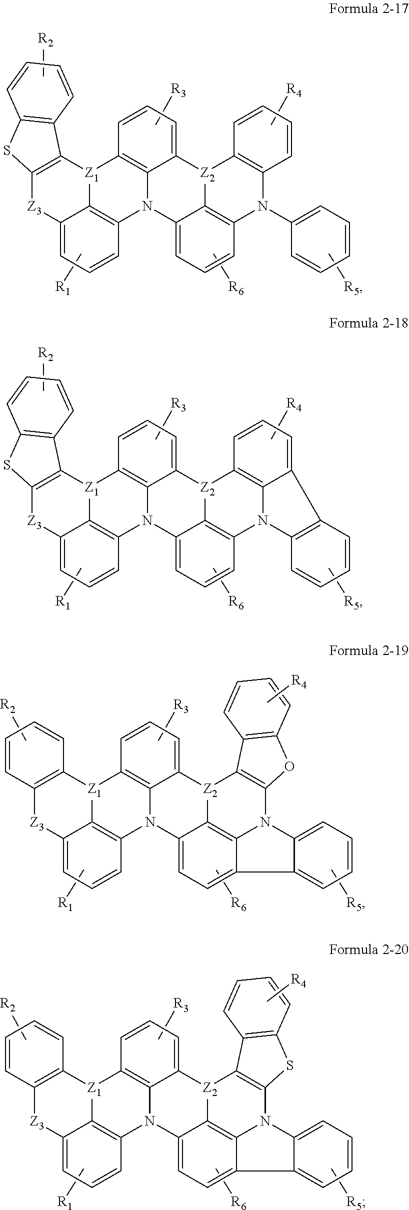
wherein,
Z₁ and Z₂ are, at each occurrence identically or differently, selected from B, N, P, P═O, P═S, As, As═O, or As═S;
Z₃ is, at each occurrence identically or differently, selected from S, SiRR, GeRR, C—O, C═S, or C═CRR; when multiple R are present, the multiple R are identical or different;
R₁, R₂, R₃, R₄, R₅, and R₆ represent, at each occurrence identically or differently, mono-substitution, multiple substitutions, or non-substitution;
R, R₁, R₂, R₃, R₄, R₅, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R, R″, R₁, R₂, R₃, R₄, R₅, and R₆ can be optionally joined to form a ring; and
preferably, the compound is selected from a structure represented by Formula 2-2.

6. The compound of claim 1, wherein Z₁ and Z₂ are, at each occurrence identically or differently, selected from B, P, P═O, or P═S;
preferably, Z₁ and Z₂ are, at each occurrence identically or differently, selected from B or P═O; and
more preferably, Z₁ and Z₂ are, at each occurrence, selected from B.

7. The compound of claim 5, wherein Z₃ is, at each occurrence identically or differently, selected from S, SiRR, C—O, or C—S; and the R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
preferably, Z₃ is, at each occurrence identically or differently, selected from S, SiRR, or C—O; and the R is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof; and
more preferably, Z₃ is, at each occurrence identically or differently, selected from S.

8. The compound of claim 5, wherein R₁, R₂, R₃, R₄, R₅, and R₆ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted amino having 0 to 20 carbon atoms, a cyano group, an isocyano group, a hydroxyl group, a sulfanyl group, and combinations thereof; and adjacent substituents R₁, R₂, R₃, R₄, R₅, and R₆ can be optionally joined to form a ring;
preferably, R₁, R₂, R₃, R₄, R₅, and R₆ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, cyano, hydroxyl, sulfanyl, and combinations thereof; and adjacent substituents R₁, R₂, R₃, R₄, R₅, and R₆ can be optionally joined to form a ring; and
more preferably, at least one R₁, at least one R₂, at least one R₃, at least one R₄, at least one R₅, and/or at least one R₆ are, at each occurrence identically or differently, selected from the group consisting of: deuterium, substituted or unsubstituted alkyl having 1 to 10 carbon atoms, substituted or unsubstituted cycloalkyl having 3 to 10 ring carbon atoms, substituted or unsubstituted alkenyl having 2 to 20 carbon atoms, substituted or unsubstituted aryl having 6 to 14 carbon atoms, substituted or unsubstituted heteroaryl having 3 to 14 carbon atoms, a hydroxyl group, a sulfanyl group, and combinations thereof; and adjacent substituents R₁, R₂, R₃, R₄, R₅, and R₆ can be optionally joined to form a ring.

9. The compound of claim 1, wherein the compound is selected from the group consisting of Compound 3-1-k, Compound 3-2-k, Compound 3-3-k, Compound 3-4-k, Compound 3-5-k, Compound 3-6-k, Compound 3-7-k, Compound 3-8-k, and Compound 4-1-k₁, wherein k is selected from an integer from 1 to 423, and k₁ is selected from an integer from 1 to 129;
Compound 3-1-k to Compound 3-8-k have the following structures: 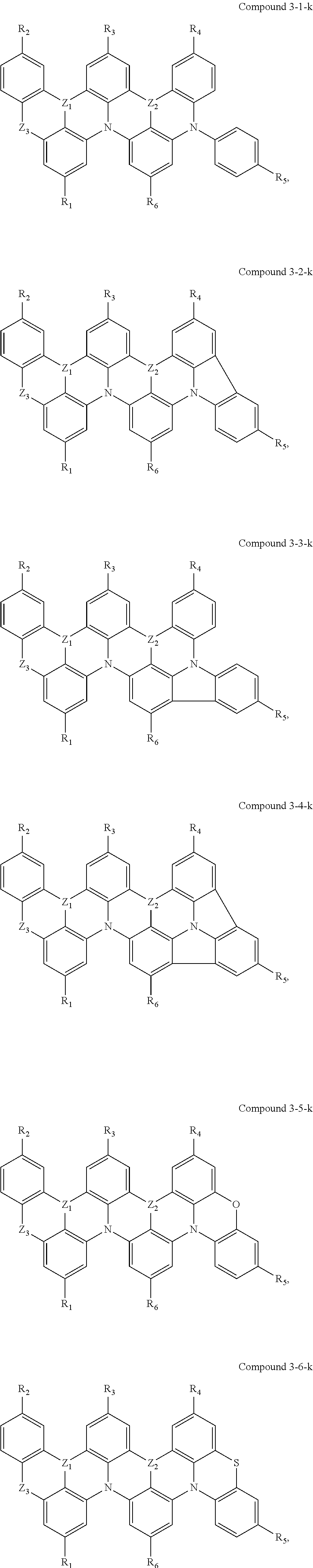 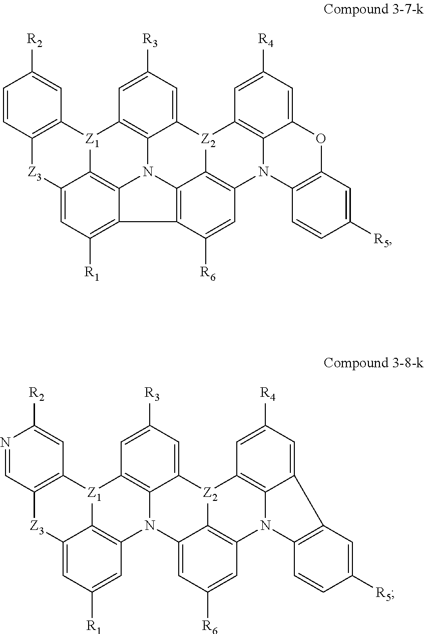
wherein when k is selected from an integer from 1 to 423, R₁, R₂, R₃, R₄, R₅, R₆, Z₁, Z₂, and Z₃ are selected from atoms or groups in the following table, respectively:

| k | R₁ | R₂ | R₃ | R₄ | R₅ | R₆ | Z₁ | Z₂ | Z₃ |
|---|---|---|---|---|---|---|---|---|---|
| 1 | H | H | H | H | H | H | B | B | S |
| 2 | D | D | D | D | D | D | B | B | S |
| 3 | P1 | P1 | P1 | P1 | P1 | P1 | B | B | S |
| 4 | P2 | P2 | P2 | P2 | P2 | P2 | B | B | S |
| 5 | P3 | P3 | P3 | P3 | P3 | P3 | B | B | S |
| 6 | P4 | P4 | P4 | P4 | P4 | P4 | B | B | S |
| 7 | P5 | P5 | P5 | P5 | P5 | P5 | B | B | S |
| 8 | P6 | P6 | P6 | P6 | P6 | P6 | B | B | S |
| 9 | P7 | P7 | P7 | P7 | P7 | P7 | B | B | S |
| 10 | P8 | P8 | P8 | P8 | P8 | P8 | B | B | S |
| 11 | P9 | P9 | P9 | P9 | P9 | P9 | B | B | S |
| 12 | P10 | P10 | P10 | P10 | P10 | P10 | B | B | S |
| 13 | P11 | P11 | P11 | P11 | P11 | P11 | B | B | S |
| 14 | P12 | P12 | P12 | P12 | P12 | P12 | B | B | S |
| 15 | P13 | P13 | P13 | P13 | P13 | P13 | B | B | S |
| 16 | P14 | P14 | P14 | P14 | P14 | P14 | B | B | S |
| 17 | P15 | P15 | P15 | P15 | P15 | P15 | B | B | S |
| 18 | P16 | P16 | P16 | P16 | P16 | P16 | B | B | S |
| 19 | P17 | P17 | P17 | P17 | P17 | P17 | B | B | S |
| 20 | P1 | P1 | H | P1 | P1 | P1 | B | B | S |
| 21 | P2 | P2 | H | P2 | P2 | P2 | B | B | S |
| 22 | P3 | P3 | H | P3 | P3 | P3 | B | B | S |
| 23 | P4 | P4 | H | P4 | P4 | P4 | B | B | S |
| 24 | P5 | P5 | H | P5 | P5 | P5 | B | B | S |
| 25 | P6 | P6 | H | P6 | P6 | P6 | B | B | S |
| 26 | P7 | P7 | H | P7 | P7 | P7 | B | B | S |
| 27 | P8 | P8 | H | P8 | P8 | P8 | B | B | S |
| 28 | P9 | P9 | H | P9 | P9 | P9 | B | B | S |
| 29 | P10 | P10 | H | P10 | P10 | P10 | B | B | S |
| 30 | P11 | P11 | H | P11 | P11 | P11 | B | B | S |
| 31 | P12 | P12 | H | P12 | P12 | P12 | B | B | S |
| 32 | P13 | P13 | H | P13 | P13 | P13 | B | B | S |
| 33 | P14 | P14 | H | P14 | P14 | P14 | B | B | S |
| 34 | P15 | P15 | H | P15 | P15 | P15 | B | B | S |
| 35 | P16 | P16 | H | P16 | P16 | P16 | B | B | S |
| 36 | P17 | P17 | H | P17 | P17 | P17 | B | B | S |
| 37 | H | P1 | H | P1 | P1 | H | B | B | S |
| 38 | H | P2 | H | P2 | P2 | H | B | B | S |
| 39 | H | P3 | H | P3 | P3 | H | B | B | S |
| 40 | H | P4 | H | P4 | P4 | H | B | B | S |
| 41 | H | P5 | H | P5 | P5 | H | B | B | S |
| 42 | H | P6 | H | P6 | P6 | H | B | B | S |
| 43 | H | P7 | H | P7 | P7 | H | B | B | S |
| 44 | H | P8 | H | P8 | P8 | H | B | B | S |
| 45 | H | P9 | H | P9 | P9 | H | B | B | S |
| 46 | H | P10 | H | P10 | P10 | H | B | B | S |
| 47 | H | P11 | H | P11 | P11 | H | B | B | S |
| 48 | H | P12 | H | P12 | P12 | H | B | B | S |
| 49 | H | P13 | H | P13 | P13 | H | B | B | S |
| 50 | H | P14 | H | P14 | P14 | H | B | B | S |
| 51 | H | P15 | H | P15 | P15 | H | B | B | S |
| 52 | H | P16 | H | P16 | P16 | H | B | B | S |
| 53 | H | P17 | H | P17 | P17 | H | B | B | S |
| 54 | P6 | P1 | P6 | P1 | P1 | P6 | B | B | S |
| 55 | P6 | P2 | P6 | P2 | P2 | P6 | B | B | S |
| 56 | P6 | P3 | P6 | P3 | P3 | P6 | B | B | S |
| 57 | P6 | P4 | P6 | P4 | P4 | P6 | B | B | S |
| 58 | P6 | P5 | P6 | P5 | P5 | P6 | B | B | S |
| 59 | P6 | P7 | P6 | P7 | P7 | P6 | B | B | S |
| 60 | P6 | P8 | P6 | P8 | P8 | P6 | B | B | S |
| 61 | P6 | P9 | P6 | P9 | P9 | P6 | B | B | S |
| 62 | P6 | P10 | P6 | P10 | P10 | P6 | B | B | S |
| 63 | P6 | P11 | P6 | P11 | P11 | P6 | B | B | S |
| 64 | P6 | P12 | P6 | P12 | P12 | P6 | B | B | S |
| 65 | P6 | P13 | P6 | P13 | P13 | P6 | B | B | S |
| 66 | P6 | P14 | P6 | P14 | P14 | P6 | B | B | S |
| 67 | P6 | P15 | P6 | P15 | P15 | P6 | B | B | S |
| 68 | P6 | P16 | P6 | P16 | P16 | P6 | B | B | S |
| 69 | P6 | P17 | P6 | P17 | P17 | P6 | B | B | S |
| 70 | P6 | P1 | H | P1 | P1 | P6 | B | B | S |
| 71 | P6 | P2 | H | P2 | P2 | P6 | B | B | S |
| 72 | P6 | P3 | H | P3 | P3 | P6 | B | B | S |
| 73 | P6 | P4 | H | P4 | P4 | P6 | B | B | S |
| 74 | P6 | P5 | H | P5 | P5 | P6 | B | B | S |
| 75 | P6 | P7 | H | P7 | P7 | P6 | B | B | S |
| 76 | P6 | P8 | H | P8 | P8 | P6 | B | B | S |
| 77 | P6 | P9 | H | P9 | P9 | P6 | B | B | S |
| 78 | P6 | P10 | H | P10 | P10 | P6 | B | B | S |
| 79 | P6 | P11 | H | P11 | P11 | P6 | B | B | S |
| 80 | P6 | P12 | H | P12 | P12 | P6 | B | B | S |
| 81 | P6 | P13 | H | P13 | P13 | P6 | B | B | S |
| 82 | P6 | P14 | H | P14 | P14 | P6 | B | B | S |
| 83 | P6 | P15 | H | P15 | P15 | P6 | B | B | S |
| 84 | P6 | P16 | H | P16 | P16 | P6 | B | B | S |
| 85 | P6 | P17 | H | P17 | P17 | P6 | B | B | S |
| 86 | H | H | H | H | H | H | B | B | C═O |
| 87 | D | D | D | D | D | D | B | B | C═O |
| 88 | P1 | P1 | P1 | P1 | P1 | P1 | B | B | C═O |
| 89 | P2 | P2 | P2 | P2 | P2 | P2 | B | B | C═O |
| 90 | P3 | P3 | P3 | P3 | P3 | P3 | B | B | C═O |
| 91 | P4 | P4 | P4 | P4 | P4 | P4 | B | B | C═O |
| 92 | P5 | P5 | P5 | P5 | P5 | P5 | B | B | C═O |
| 93 | P6 | P6 | P6 | P6 | P6 | P6 | B | B | C═O |
| 94 | P7 | P7 | P7 | P7 | P7 | P7 | B | B | C═O |
| 95 | P8 | P8 | P8 | P8 | P8 | P8 | B | B | C═O |
| 96 | P9 | P9 | P9 | P9 | P9 | P9 | B | B | C═O |
| 97 | P10 | P10 | P10 | P10 | P10 | P10 | B | B | C═O |
| 98 | P11 | P11 | P11 | P11 | P11 | P11 | B | B | C═O |
| 99 | P12 | P12 | P12 | P12 | P12 | P12 | B | B | C═O |
| 100 | P13 | P13 | P13 | P13 | P13 | P13 | B | B | C═O |
| 101 | P14 | P14 | P14 | P14 | P14 | P14 | B | B | C═O |
| 102 | P15 | P15 | P15 | P15 | P15 | P15 | B | B | C═O |
| 103 | P16 | P16 | P16 | P16 | P16 | P16 | B | B | C═O |
| 104 | P17 | P17 | P17 | P17 | P17 | P17 | B | B | C═O |
| 105 | P1 | P1 | H | P1 | P1 | P1 | B | B | C═O |
| 106 | P2 | P2 | H | P2 | P2 | P2 | B | B | C═O |
| 107 | P3 | P3 | H | P3 | P3 | P3 | B | B | C═O |
| 108 | P4 | P4 | H | P4 | P4 | P4 | B | B | C═O |
| 109 | P5 | P5 | H | P5 | P5 | P5 | B | B | C═O |
| 110 | P6 | P6 | H | P6 | P6 | P6 | B | B | C═O |
| 111 | P7 | P7 | H | P7 | P7 | P7 | B | B | C═O |
| 112 | P8 | P8 | H | P8 | P8 | P8 | B | B | C═O |
| 113 | P9 | P9 | H | P9 | P9 | P9 | B | B | C═O |
| 114 | P10 | P10 | H | P10 | P10 | P10 | B | B | C═O |
| 115 | P11 | P11 | H | P11 | P11 | P11 | B | B | C═O |
| 116 | P12 | P12 | H | P12 | P12 | P12 | B | B | C═O |
| 117 | P13 | P13 | H | P13 | P13 | P13 | B | B | C═O |
| 118 | P14 | P14 | H | P14 | P14 | P14 | B | B | C═O |
| 119 | P15 | P15 | H | P15 | P15 | P15 | B | B | C═O |
| 120 | P16 | P16 | H | P16 | P16 | P16 | B | B | C═O |
| 121 | P17 | P17 | H | P17 | P17 | P17 | B | B | C═O |
| 122 | H | P1 | H | P1 | P1 | H | B | B | C═O |
| 123 | H | P2 | H | P2 | P2 | H | B | B | C═O |
| 124 | H | P3 | H | P3 | P3 | H | B | B | C═O |
| 125 | H | P4 | H | P4 | P4 | H | B | B | C═O |
| 126 | H | P5 | H | P5 | P5 | H | B | B | C═O |
| 127 | H | P6 | H | P6 | P6 | H | B | B | C═O |
| 128 | H | P7 | H | P7 | P7 | H | B | B | C═O |
| 129 | H | P8 | H | P8 | P8 | H | B | B | C═O |
| 130 | H | P9 | H | P9 | P9 | H | B | B | C═O |
| 131 | H | P10 | H | P10 | P10 | H | B | B | C═O |
| 132 | H | P11 | H | P11 | P11 | H | B | B | C═O |
| 133 | H | P12 | H | P12 | P12 | H | B | B | C═O |
| 134 | H | P13 | H | P13 | P13 | H | B | B | C═O |
| 135 | H | P14 | H | P14 | P14 | H | B | B | C═O |
| 136 | H | P15 | H | P15 | P15 | H | B | B | C═O |
| 137 | H | P16 | H | P16 | P16 | H | B | B | C═O |
| 138 | H | P17 | H | P17 | P17 | H | B | B | C═O |
| 139 | P6 | P1 | P6 | P1 | P1 | P6 | B | B | C═O |
| 140 | P6 | P2 | P6 | P2 | P2 | P6 | B | B | C═O |
| 141 | P6 | P3 | P6 | P3 | P3 | P6 | B | B | C═O |
| 142 | P6 | P4 | P6 | P4 | P4 | P6 | B | B | C═O |
| 143 | P6 | P5 | P6 | P5 | P5 | P6 | B | B | C═O |
| 144 | P6 | P7 | P6 | P7 | P7 | P6 | B | B | C═O |
| 145 | P6 | P8 | P6 | P8 | P8 | P6 | B | B | C═O |
| 146 | P6 | P9 | P6 | P9 | P9 | P6 | B | B | C═O |
| 147 | P6 | P10 | P6 | P10 | P10 | P6 | B | B | C═O |
| 148 | P6 | P11 | P6 | P11 | P11 | P6 | B | B | C═O |
| 149 | P6 | P12 | P6 | P12 | P12 | P6 | B | B | C═O |
| 150 | P6 | P13 | P6 | P13 | P13 | P6 | B | B | C═O |
| 151 | P6 | P14 | P6 | P14 | P14 | P6 | B | B | C═O |
| 152 | P6 | P15 | P6 | P15 | P15 | P6 | B | B | C═O |
| 153 | P6 | P16 | P6 | P16 | P16 | P6 | B | B | C═O |
| 154 | P6 | P17 | P6 | P17 | P17 | P6 | B | B | C═O |
| 155 | P6 | P1 | H | P1 | P1 | P6 | B | B | C═O |
| 156 | P6 | P2 | H | P2 | P2 | P6 | B | B | C═O |
| 157 | P6 | P3 | H | P3 | P3 | P6 | B | B | C═O |
| 158 | P6 | P4 | H | P4 | P4 | P6 | B | B | C═O |
| 159 | P6 | P5 | H | P5 | P5 | P6 | B | B | C═O |
| 160 | P6 | P7 | H | P7 | P7 | P6 | B | B | C═O |
| 161 | P6 | P8 | H | P8 | P8 | P6 | B | B | C═O |
| 162 | P6 | P9 | H | P9 | P9 | P6 | B | B | C═O |
| 163 | P6 | P10 | H | P10 | P10 | P6 | B | B | C═O |
| 164 | P6 | P11 | H | P11 | P11 | P6 | B | B | C═O |
| 165 | P6 | P12 | H | P12 | P12 | P6 | B | B | C═O |
| 166 | P6 | P13 | H | P13 | P13 | P6 | B | B | C═O |
| 167 | P6 | P14 | H | P14 | P14 | P6 | B | B | C═O |
| 168 | P6 | P15 | H | P15 | P15 | P6 | B | B | C═O |
| 169 | P6 | P16 | H | P16 | P16 | P6 | B | B | C═O |
| 170 | P6 | P17 | H | P17 | P17 | P6 | B | B | C═O |
| 171 | H | H | H | H | H | H | B | B | SiPh₂ |
| 172 | D | D | D | D | D | D | B | B | SiPh₂ |
| 173 | P1 | P1 | P1 | P1 | P1 | P1 | B | B | SiPh₂ |
| 174 | P2 | P2 | P2 | P2 | P2 | P2 | B | B | SiPh₂ |
| 175 | P3 | P3 | P3 | P3 | P3 | P3 | B | B | SiPh₂ |
| 176 | P4 | P4 | P4 | P4 | P4 | P4 | B | B | SiPh₂ |
| 177 | P5 | P5 | P5 | P5 | P5 | P5 | B | B | SiPh₂ |
| 178 | P6 | P6 | P6 | P6 | P6 | P6 | B | B | SiPh₂ |
| 179 | P7 | P7 | P7 | P7 | P7 | P7 | B | B | SiPh₂ |
| 180 | P8 | P8 | P8 | P8 | P8 | P8 | B | B | SiPh₂ |
| 181 | P9 | P9 | P9 | P9 | P9 | P9 | B | B | SiPh₂ |
| 182 | P10 | P10 | P10 | P10 | P10 | P10 | B | B | SiPh₂ |
| 183 | P11 | P11 | P11 | P11 | P1 | P11 | B | B | SiPh₂ |
| 184 | P12 | P12 | P12 | P12 | P12 | P12 | B | B | SiPh₂ |
| 185 | P13 | P13 | P13 | P13 | P13 | P13 | B | B | SiPh₂ |
| 186 | P14 | P14 | P14 | P14 | P14 | P14 | B | B | SiPh₂ |
| 187 | P15 | P15 | P15 | P15 | P15 | P15 | B | B | SiPh₂ |
| 188 | P16 | P16 | P16 | P16 | P16 | P16 | B | B | SiPh₂ |
| 189 | P17 | P17 | P17 | P17 | P17 | P17 | B | B | SiPh₂ |
| 190 | P1 | P1 | H | P1 | P1 | P1 | B | B | SiPh₂ |
| 191 | P2 | P2 | H | P2 | P2 | P2 | B | B | SiPh₂ |
| 192 | P3 | P3 | H | P3 | P3 | P3 | B | B | SiPh₂ |
| 193 | P4 | P4 | H | P4 | P4 | P4 | B | B | SiPh₂ |
| 194 | P5 | P5 | H | P5 | P5 | P5 | B | B | SiPh₂ |
| 195 | P6 | P6 | H | P6 | P6 | P6 | B | B | SiPh₂ |
| 196 | P7 | P7 | H | P7 | P7 | P7 | B | B | SiPh₂ |
| 197 | P8 | P8 | H | P8 | P8 | P8 | B | B | SiPh₂ |
| 198 | P9 | P9 | H | P9 | P9 | P9 | B | B | SiPh₂ |
| 199 | P10 | P10 | H | P10 | P10 | P10 | B | B | SiPh₂ |
| 200 | P11 | P11 | H | P11 | P11 | P11 | B | B | SiPh₂ |
| 201 | P12 | P12 | H | P12 | P12 | P12 | B | B | SiPh₂ |
| 202 | P13 | P13 | H | P13 | P13 | P13 | B | B | SiPh₂ |
| 203 | P14 | P14 | H | P14 | P14 | P14 | B | B | SiPh₂ |
| 204 | P15 | P15 | H | P15 | P15 | P15 | B | B | SiPh₂ |
| 205 | P16 | P16 | H | P16 | P16 | P16 | B | B | SiPh₂ |
| 206 | P17 | P17 | H | P17 | P17 | P17 | B | B | SiPh₂ |
| 207 | H | P1 | H | P1 | P1 | H | B | B | SiPh₂ |
| 208 | H | P2 | H | P2 | P2 | H | B | B | SiPh₂ |
| 209 | H | P3 | H | P3 | P3 | H | B | B | SiPh₂ |
| 210 | H | P4 | H | P4 | P4 | H | B | B | SiPh₂ |
| 211 | H | P5 | H | P5 | P5 | H | B | B | SiPh₂ |
| 212 | H | P6 | H | P6 | P6 | H | B | B | SiPh₂ |
| 213 | H | P7 | H | P7 | P7 | H | B | B | SiPh₂ |
| 214 | H | P8 | H | P8 | P8 | H | B | B | SiPh₂ |
| 215 | H | P9 | H | P9 | P9 | H | B | B | SiPh₂ |
| 216 | H | P10 | H | P10 | P10 | H | B | B | SiPh₂ |
| 217 | H | P11 | H | P11 | P11 | H | B | B | SiPh₂ |
| 218 | H | P12 | H | P12 | P12 | H | B | B | SiPh₂ |
| 219 | H | P13 | H | P13 | P13 | H | B | B | SiPh₂ |
| 220 | H | P14 | H | P14 | P14 | H | B | B | SiPh₂ |
| 221 | H | P15 | H | P15 | P15 | H | B | B | SiPh₂ |
| 222 | H | P16 | H | P16 | P16 | H | B | B | SiPh₂ |
| 223 | H | P17 | H | P17 | P17 | H | B | B | SiPh₂ |
| 224 | P6 | P1 | P6 | P1 | P1 | P6 | B | B | SiPh₂ |
| 225 | P6 | P2 | P6 | P2 | P2 | P6 | B | B | SiPh₂ |
| 226 | P6 | P3 | P6 | P3 | P3 | P6 | B | B | SiPh₂ |
| 227 | P6 | P4 | P6 | P4 | P4 | P6 | B | B | SiPh₂ |
| 228 | P6 | P5 | P6 | P5 | P5 | P6 | B | B | SiPh₂ |
| 229 | P6 | P7 | P6 | P7 | P7 | P6 | B | B | SiPh₂ |
| 230 | P6 | P8 | P6 | P8 | P8 | P6 | B | B | SiPh₂ |
| 231 | P6 | P9 | P6 | P9 | P9 | P6 | B | B | SiPh₂ |
| 232 | P6 | P10 | P6 | P10 | P10 | P6 | B | B | SiPh₂ |
| 233 | P6 | P11 | P6 | P11 | P11 | P6 | B | B | SiPh₂ |
| 234 | P6 | P12 | P6 | P12 | P12 | P6 | B | B | SiPh₂ |
| 235 | P6 | P13 | P6 | P13 | P13 | P6 | B | B | SiPh₂ |
| 236 | P6 | P14 | P6 | P14 | P14 | P6 | B | B | SiPh₂ |
| 237 | P6 | P15 | P6 | P15 | P15 | P6 | B | B | SiPh₂ |
| 238 | P6 | P16 | P6 | P16 | P16 | P6 | B | B | SiPh₂ |
| 239 | P6 | P17 | P6 | P17 | P17 | P6 | B | B | SiPh₂ |
| 240 | P6 | P1 | H | P1 | P1 | P6 | B | B | SiPh₂ |
| 241 | P6 | P2 | H | P2 | P2 | P6 | B | B | SiPh₂ |
| 242 | P6 | P3 | H | P3 | P3 | P6 | B | B | SiPh₂ |
| 243 | P6 | P4 | H | P4 | P4 | P6 | B | B | SiPh₂ |
| 244 | P6 | P5 | H | P5 | P5 | P6 | B | B | SiPh₂ |
| 245 | P6 | P7 | H | P7 | P7 | P6 | B | B | SiPh₂ |
| 246 | P6 | P8 | H | P8 | P8 | P6 | B | B | SiPh₂ |
| 247 | P6 | P9 | H | P9 | P9 | P6 | B | B | SiPh₂ |
| 248 | P6 | P10 | H | P10 | P10 | P6 | B | B | SiPh₂ |
| 249 | P6 | P11 | H | P11 | P11 | P6 | B | B | SiPh₂ |
| 250 | P6 | P12 | H | P12 | P12 | P6 | B | B | SiPh₂ |
| 251 | P6 | P13 | H | P13 | P13 | P6 | B | B | SiPh₂ |
| 252 | P6 | P14 | H | P14 | P14 | P6 | B | B | SiPh₂ |
| 253 | P6 | P15 | H | P15 | P15 | P6 | B | B | SiPh₂ |
| 254 | P6 | P16 | H | P16 | P16 | P6 | B | B | SiPh₂ |
| 255 | P6 | P17 | H | P17 | P17 | P6 | B | B | SiPh₂ |
| 256 | H | H | H | H | H | H | P | P | S |
| 257 | P1 | P1 | P1 | P1 | P1 | P1 | P | P | S |
| 258 | P2 | P2 | P2 | P2 | P2 | P2 | P | P | S |
| 259 | P6 | P6 | P6 | P6 | P6 | P6 | P | P | S |
| 260 | P6 | P1 | H | P1 | P1 | P6 | P | P | S |
| 261 | P6 | P2 | H | P2 | P2 | P6 | P | P | S |
| 262 | P6 | H | P6 | H | H | P6 | P | P | S |
| 263 | P6 | P1 | P6 | P1 | P1 | P6 | P | P | S |
| 264 | P6 | P2 | P6 | P2 | P2 | P6 | P | P | S |
| 265 | H | P14 | H | P14 | P14 | H | P | P | S |
| 266 | H | P15 | H | P15 | P15 | H | P | P | S |
| 267 | H | P16 | H | P16 | P16 | H | P | P | S |
| 268 | H | P17 | H | P17 | P17 | H | P | P | S |
| 269 | H | P6 | H | P6 | P6 | H | P | P | S |
| 270 | H | H | H | H | H | H | P | P | C═O |
| 271 | P1 | P1 | P1 | P1 | P1 | P1 | P | P | C═O |
| 272 | P2 | P2 | P2 | P2 | P2 | P2 | P | P | C═O |
| 273 | P6 | P6 | P6 | P6 | P6 | P6 | P | P | C═O |
| 274 | P6 | P1 | H | P1 | P1 | P6 | P | P | C═O |
| 275 | P6 | P2 | H | P2 | P2 | P6 | P | P | C═O |
| 276 | P6 | H | P6 | H | H | P6 | P | P | C═O |
| 277 | P6 | P1 | P6 | P1 | P1 | P6 | P | P | C═O |
| 278 | P6 | P2 | P6 | P2 | P2 | P6 | P | P | C═O |
| 279 | H | P14 | H | P14 | P14 | H | P | P | C═O |
| 280 | H | P15 | H | P15 | P15 | H | P | P | C═O |
| 281 | H | P16 | H | P16 | P16 | H | P | P | C═O |
| 282 | H | P17 | H | P17 | P17 | H | P | P | C═O |
| 283 | H | P6 | H | P6 | P6 | H | P | P | C═O |
| 284 | H | H | H | H | H | H | P | P | SiPh₂ |
| 285 | P1 | P1 | P1 | P1 | P1 | P1 | P | P | SiPh₂ |
| 286 | P2 | P2 | P2 | P2 | P2 | P2 | P | P | SiPh₂ |
| 287 | P6 | P6 | P6 | P6 | P6 | P6 | P | P | SiPh₂ |
| 288 | P6 | P1 | H | P1 | P1 | P6 | P | P | SiPh₂ |
| 289 | P6 | P2 | H | P2 | P2 | P6 | P | P | SiPh₂ |
| 290 | P6 | H | P6 | H | H | P6 | P | P | SiPh₂ |
| 291 | P6 | P1 | P6 | P1 | P1 | P6 | P | P | SiPh₂ |
| 292 | P6 | P2 | P6 | P2 | P2 | P6 | P | P | SiPh₂ |
| 293 | H | P14 | H | P14 | P14 | H | P | P | SiPh₂ |
| 294 | H | P15 | H | P15 | P15 | H | P | P | SiPh₂ |
| 295 | H | P16 | H | P16 | P16 | H | P | P | SiPh₂ |
| 296 | H | P17 | H | P17 | P17 | H | P | P | SiPh₂ |
| 297 | H | P6 | H | P6 | P6 | H | P | P | SiPh₂ |
| 298 | H | H | H | H | H | H | P═O | P═O | S |
| 299 | P1 | P1 | P1 | P1 | P1 | P1 | P═O | P═O | S |
| 300 | P2 | P2 | P2 | P2 | P2 | P2 | P═O | P═O | S |
| 301 | P6 | P6 | P6 | P6 | P6 | P6 | P═O | P═O | S |
| 302 | P6 | P1 | H | P1 | P1 | P6 | P═O | P═O | S |
| 303 | P6 | P2 | H | P2 | P2 | P6 | P═O | P═O | S |
| 304 | P6 | H | P6 | H | H | P6 | P═O | P═O | S |
| 305 | P6 | P1 | P6 | P1 | P1 | P6 | P═O | P═O | S |
| 306 | P6 | P2 | P6 | P2 | P2 | P6 | P═O | P═O | S |
| 307 | H | P14 | H | P14 | P14 | H | P═O | P═O | S |
| 308 | H | P15 | H | P15 | P15 | H | P═O | P═O | S |
| 309 | H | P16 | H | P16 | P16 | H | P═O | P═O | S |
| 310 | H | P17 | H | P17 | P17 | H | P═O | P═O | S |
| 311 | H | P6 | H | P6 | P6 | H | P═O | P═O | S |
| 312 | H | H | H | H | H | H | P═O | P═O | C═O |
| 313 | P1 | P1 | P1 | P1 | P1 | P1 | P═O | P═O | C═O |
| 314 | P2 | P2 | P2 | P2 | P2 | P2 | P═O | P═O | C═O |
| 315 | P6 | P6 | P6 | P6 | P6 | P6 | P═O | P═O | C═O |
| 316 | P6 | P1 | H | P1 | P1 | P6 | P═O | P═O | C═O |
| 317 | P6 | P2 | H | P2 | P2 | P6 | P═O | P═O | C═O |
| 318 | P6 | H | P6 | H | H | P6 | P═O | P═O | C═O |
| 319 | P6 | P1 | P6 | P1 | P1 | P6 | P═O | P═O | C═O |
| 320 | P6 | P2 | P6 | P2 | P2 | P6 | P═O | P═O | C═O |
| 321 | H | P14 | H | P14 | P14 | H | P═O | P═O | C═O |
| 322 | H | P15 | H | P15 | P15 | H | P═O | P═O | C═O |
| 323 | H | P16 | H | P16 | P16 | H | P═O | P═O | C═O |
| 324 | H | P17 | H | P17 | P17 | H | P═O | P═O | C═O |
| 325 | H | P6 | H | P6 | P6 | H | P═O | P═O | C═O |
| 326 | H | H | H | H | H | H | P═O | P═O | SiPh₂ |
| 327 | P1 | P1 | P1 | P1 | P1 | P1 | P═O | P═O | SiPh₂ |
| 328 | P2 | P2 | P2 | P2 | P2 | P2 | P═O | P═O | SiPh₂ |
| 329 | P6 | P6 | P6 | P6 | P6 | P6 | P═O | P═O | SiPh₂ |
| 330 | P6 | P1 | H | P1 | P1 | P6 | P═O | P═O | SiPh₂ |
| 331 | P6 | P2 | H | P2 | P2 | P6 | P═O | P═O | SiPh₂ |
| 332 | P6 | H | P6 | H | H | P6 | P═O | P═O | SiPh₂ |
| 333 | P6 | P1 | P6 | P1 | P1 | P6 | P═O | P═O | SiPh₂ |
| 334 | P6 | P2 | P6 | P2 | P2 | P6 | P═O | P═O | SiPh₂ |
| 335 | H | P14 | H | P14 | P14 | H | P═O | P═O | SiPh₂ |
| 336 | H | P15 | H | P15 | P15 | H | P═O | P═O | SiPh₂ |
| 337 | H | P16 | H | P16 | P16 | H | P═O | P═O | SiPh₂ |
| 338 | H | P17 | H | P17 | P17 | H | P═O | P═O | SiPh₂ |
| 339 | H | P6 | H | P6 | P6 | H | P═O | P═O | SiPh₂ |
| 340 | H | H | H | H | H | H | B | P═O | S |
| 341 | P1 | P1 | P1 | P1 | P1 | P1 | B | P═O | S |
| 342 | P2 | P2 | P2 | P2 | P2 | P2 | B | P═O | S |
| 343 | P6 | P6 | P6 | P6 | P6 | P6 | B | P═O | S |
| 344 | P6 | P1 | H | P1 | P1 | P6 | B | P═O | S |
| 345 | P6 | P2 | H | P2 | P2 | P6 | B | P═O | S |
| 346 | P6 | H | P6 | H | H | P6 | B | P═O | S |
| 347 | P6 | P1 | P6 | P1 | P1 | P6 | B | P═O | S |
| 348 | P6 | P2 | P6 | P2 | P2 | P6 | B | P═O | S |
| 349 | H | P14 | H | P14 | P14 | H | B | P═O | S |
| 350 | H | P15 | H | P15 | P15 | H | B | P═O | S |
| 351 | H | P16 | H | P16 | P16 | H | B | P═O | S |
| 352 | H | P17 | H | P17 | P17 | H | B | P═O | S |
| 353 | H | P6 | H | P6 | P6 | H | B | P═O | S |
| 354 | H | H | H | H | H | H | B | P═O | C═O |
| 355 | P1 | P1 | P1 | P1 | P1 | P1 | B | P═O | C═O |
| 356 | P2 | P2 | P2 | P2 | P2 | P2 | B | P═O | C═O |
| 357 | P6 | P6 | P6 | P6 | P6 | P6 | B | P═O | C═O |
| 358 | P6 | P1 | H | P1 | P1 | P6 | B | P═O | C═O |
| 359 | P6 | P2 | H | P2 | P2 | P6 | B | P═O | C═O |
| 360 | P6 | H | P6 | H | H | P6 | B | P═O | C═O |
| 361 | P6 | P1 | P6 | P1 | P1 | P6 | B | P═O | C═O |
| 362 | P6 | P2 | P6 | P2 | P2 | P6 | B | P═O | C═O |
| 363 | H | P14 | H | P14 | P14 | H | B | P═O | C═O |
| 364 | H | P15 | H | P15 | P15 | H | B | P═O | C═O |
| 365 | H | P16 | H | P16 | P16 | H | B | P═O | C═O |
| 366 | H | P17 | H | P17 | P17 | H | B | P═O | C═O |
| 367 | H | P6 | H | P6 | P6 | H | B | P═O | C═O |
| 368 | H | H | H | H | H | H | B | P═O | SiPh₂ |
| 369 | P1 | P1 | P1 | P1 | P1 | P1 | B | P═O | SiPh₂ |
| 370 | P2 | P2 | P2 | P2 | P2 | P2 | B | P═O | SiPh₂ |
| 371 | P6 | P6 | P6 | P6 | P6 | P6 | B | P═O | SiPh₂ |
| 372 | P6 | P1 | H | P1 | P1 | P6 | B | P═O | SiPh₂ |
| 373 | P6 | P2 | H | P2 | P2 | P6 | B | P═O | SiPh₂ |
| 374 | P6 | H | P6 | H | H | P6 | B | P═O | SiPh₂ |
| 375 | P6 | P1 | P6 | P1 | P1 | P6 | B | P═O | SiPh₂ |
| 376 | P6 | P2 | P6 | P2 | P2 | P6 | B | P═O | SiPh₂ |
| 377 | H | P14 | H | P14 | P14 | H | B | P═O | SiPh₂ |
| 378 | H | P15 | H | P15 | P15 | H | B | P═O | SiPh₂ |
| 379 | H | P16 | H | P16 | P16 | H | B | P═O | SiPh₂ |
| 380 | H | P17 | H | P17 | P17 | H | B | P═O | SiPh₂ |
| 381 | H | P6 | H | P6 | P6 | H | B | P═O | SiPh₂ |
| 382 | H | H | H | H | H | H | P | B | S |
| 383 | P1 | P1 | P1 | P1 | P1 | P1 | P | B | S |
| 384 | P2 | P2 | P2 | P2 | P2 | P2 | P | B | S |
| 385 | P6 | P6 | P6 | P6 | P6 | P6 | P | B | S |
| 386 | P6 | P1 | H | P1 | P1 | P6 | P | B | S |
| 387 | P6 | P2 | H | P2 | P2 | P6 | P | B | S |
| 388 | P6 | H | P6 | H | H | P6 | P | B | S |
| 389 | P6 | P1 | P6 | P1 | P1 | P6 | P | B | S |
| 390 | P6 | P2 | P6 | P2 | P2 | P6 | P | B | S |
| 391 | H | P14 | H | P14 | P14 | H | P | B | S |
| 392 | H | P15 | H | P15 | P15 | H | P | B | S |
| 393 | H | P16 | H | P16 | P16 | H | P | B | S |
| 394 | H | P17 | H | P17 | P17 | H | P | B | S |
| 395 | H | P6 | H | P6 | P6 | H | P | B | S |
| 396 | H | H | H | H | H | H | P | B | C═O |
| 397 | P1 | P1 | P1 | P1 | P1 | P1 | P | B | C═O |
| 398 | P2 | P2 | P2 | P2 | P2 | P2 | P | B | C═O |
| 399 | P6 | P6 | P6 | P6 | P6 | P6 | P | B | C═O |
| 400 | P6 | P1 | H | P1 | P1 | P6 | P | B | C═O |
| 401 | P6 | P2 | H | P2 | P2 | P6 | P | B | C═O |
| 402 | P6 | H | P6 | H | H | P6 | P | B | C═O |
| 403 | P6 | P1 | P6 | P1 | P1 | P6 | P | B | C═O |
| 404 | P6 | P2 | P6 | P2 | P2 | P6 | P | B | C═O |
| 405 | H | P14 | H | P14 | P14 | H | P | B | C═O |
| 406 | H | P15 | H | P15 | P15 | H | P | B | C═O |
| 407 | H | P16 | H | P16 | P16 | H | P | B | C═O |
| 408 | H | P17 | H | P17 | P17 | H | P | B | C═O |
| 409 | H | P6 | H | P6 | P6 | H | P | B | C═O |
| 410 | H | H | H | H | H | H | P | B | SiPh₂ |
| 411 | P1 | P1 | P1 | P1 | P1 | P1 | P | B | SiPh₂ |
| 412 | P2 | P2 | P2 | P2 | P2 | P2 | P | B | SiPh₂ |
| 413 | P6 | P6 | P6 | P6 | P6 | P6 | P | B | SiPh₂ |
| 414 | P6 | P1 | H | P1 | P1 | P6 | P | B | SiPh₂ |
| 415 | P6 | P2 | H | P2 | P2 | P6 | P | B | SiPh₂ |
| 416 | P6 | H | P6 | H | H | P6 | P | B | SiPh₂ |
| 417 | P6 | P1 | P6 | P1 | P1 | P6 | P | B | SiPh₂ |
| 418 | P6 | P2 | P6 | P2 | P2 | P6 | P | B | SiPh₂ |
| 419 | H | P14 | H | P14 | P14 | H | P | B | SiPh₂ |
| 420 | H | P15 | H | P15 | P15 | H | P | B | SiPh₂ |
| 421 | H | P16 | H | P16 | P16 | H | P | B | SiPh₂ |
| 422 | H | P17 | H | P17 | P17 | H | P | B | SiPh₂ |
| 423 | H | P6 | H | P6 | P6 | H | P | B | SiPh₂ |

wherein Ph represents phenyl, and P1 to P17 have the following structures: 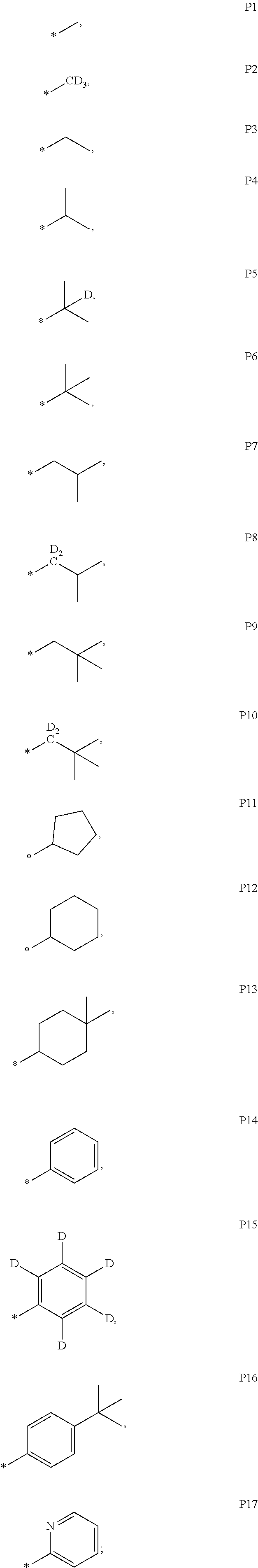
wherein “*” represents a position where P1 to P17 are joined to Compound 3-1-k to Compound 3-8-k;
Compound 4-1-1 to Compound 4-1-129 have the following structures: 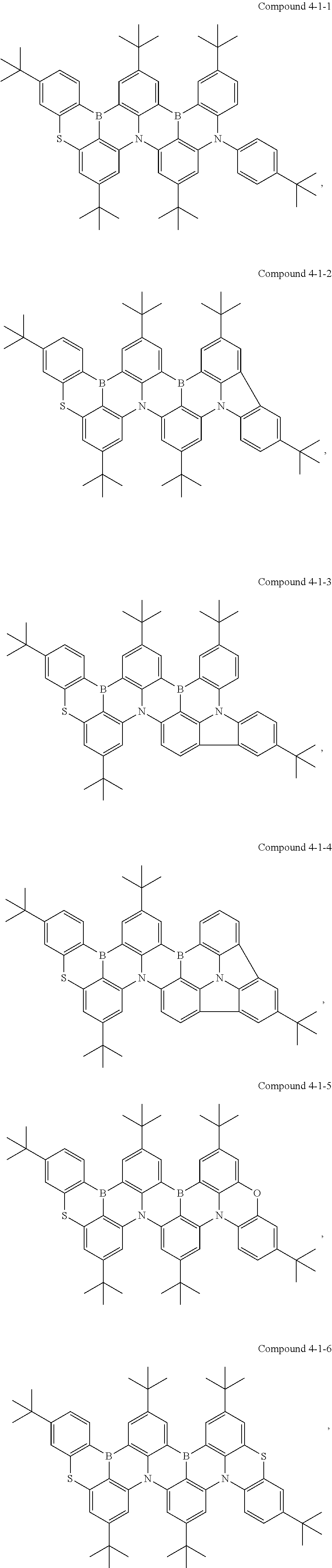 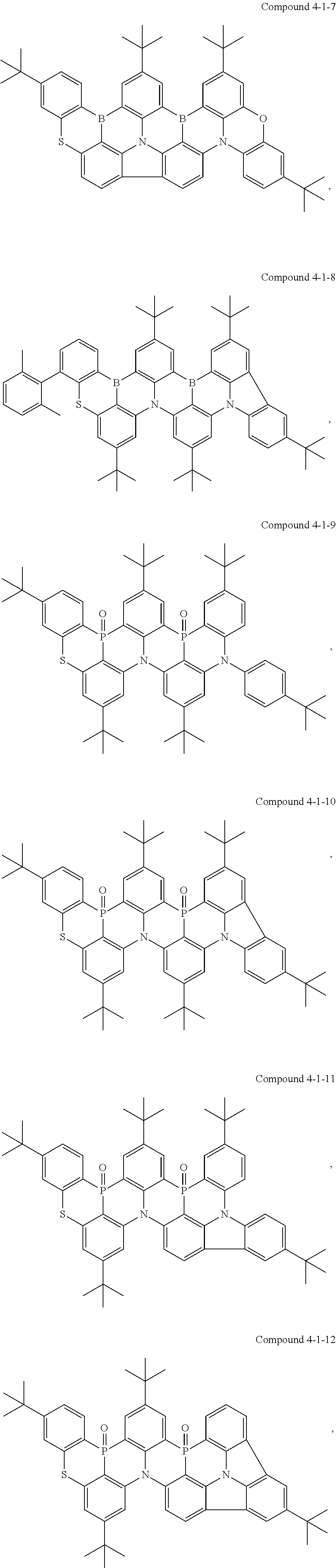 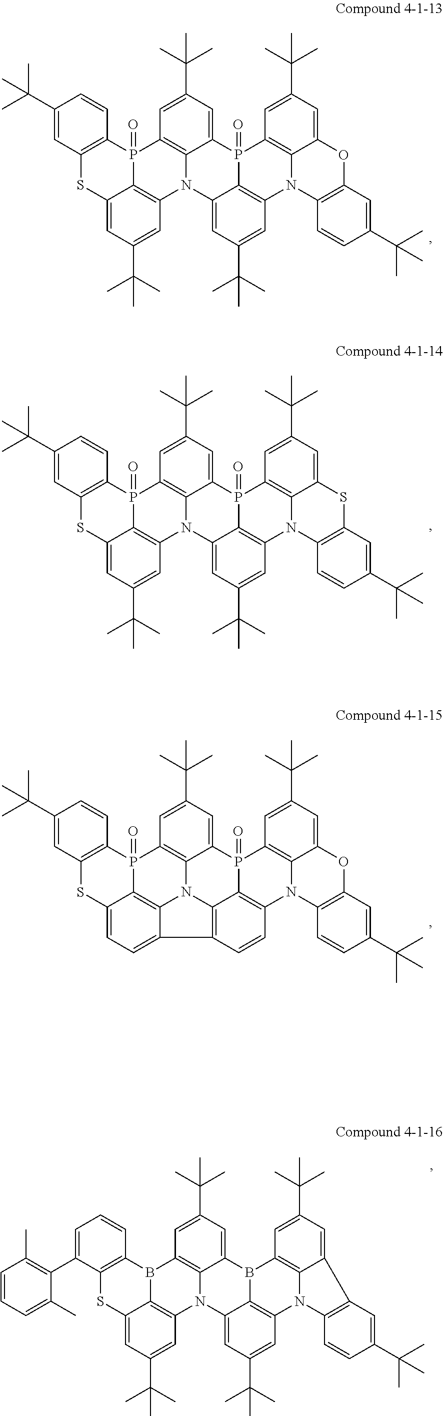 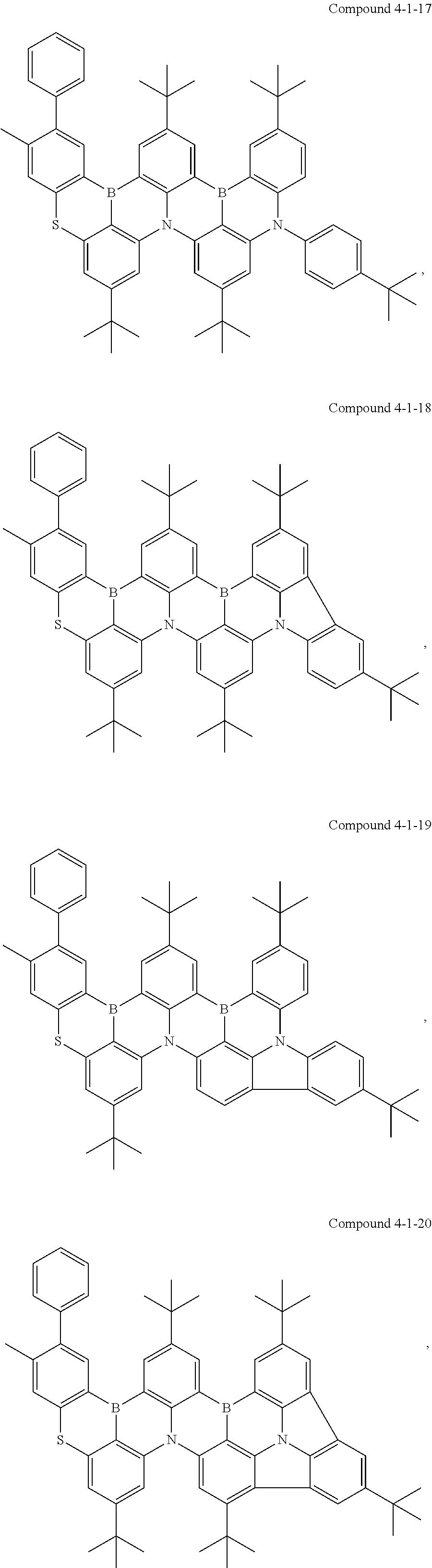 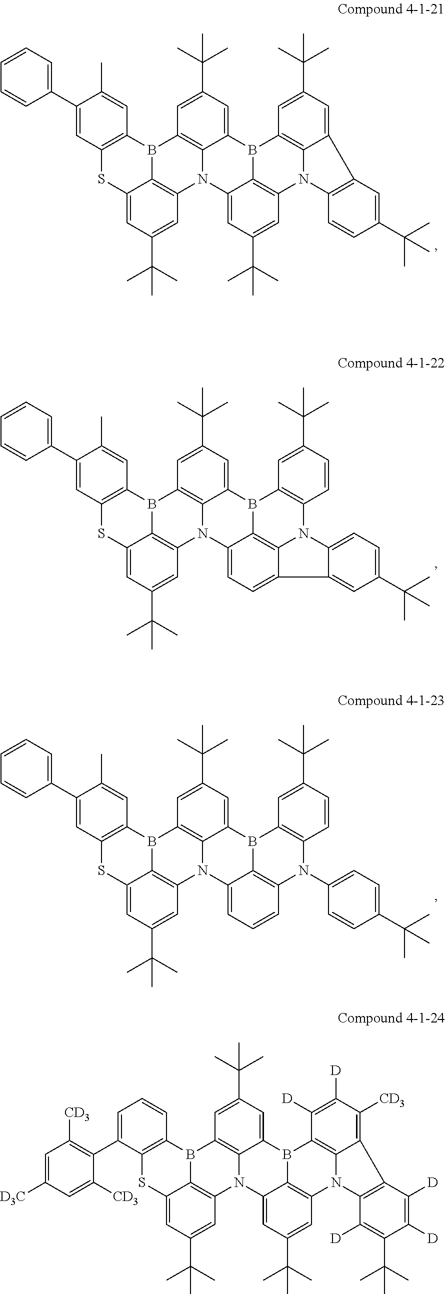 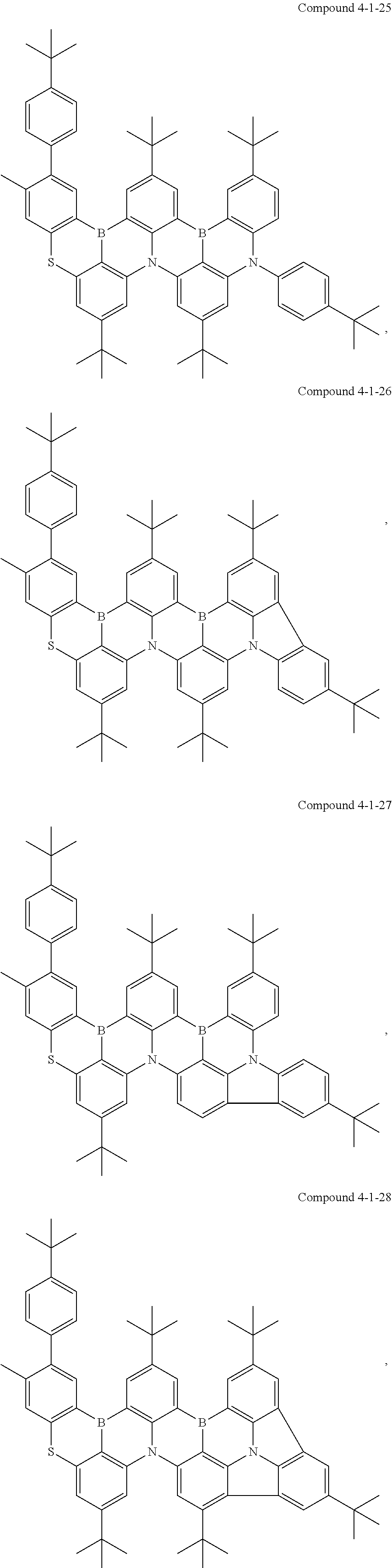 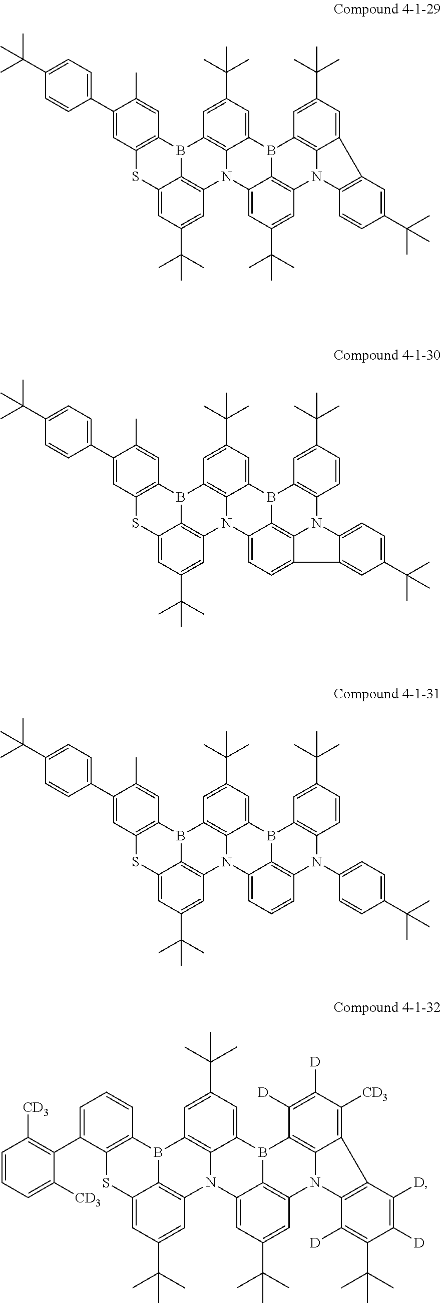 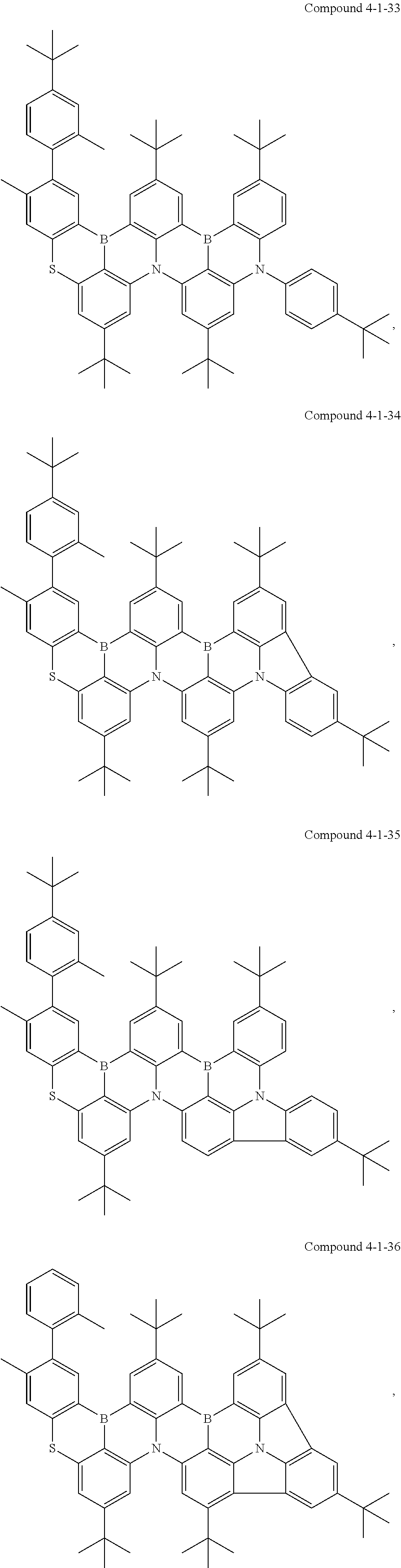 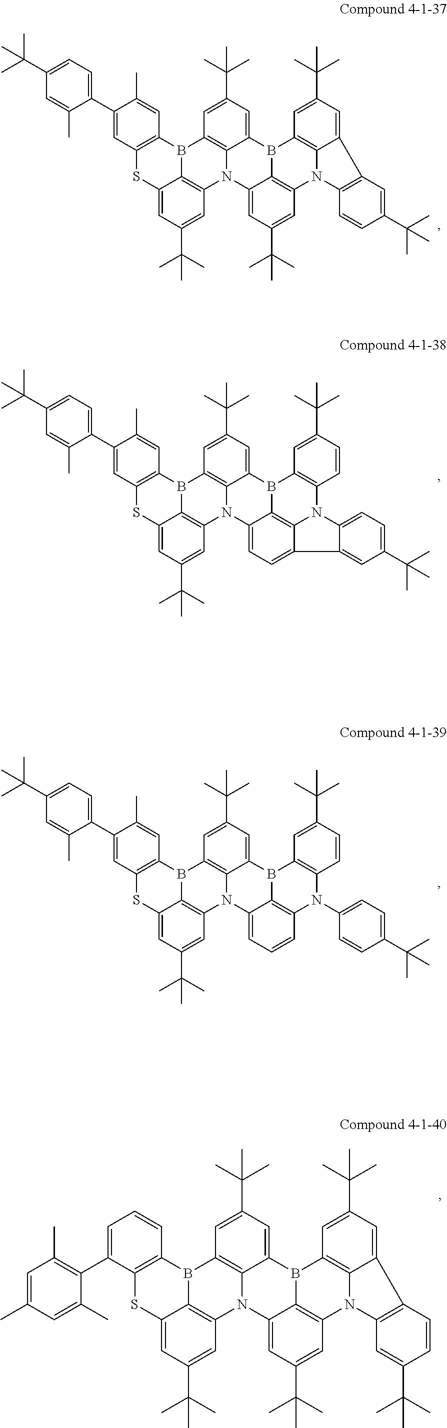 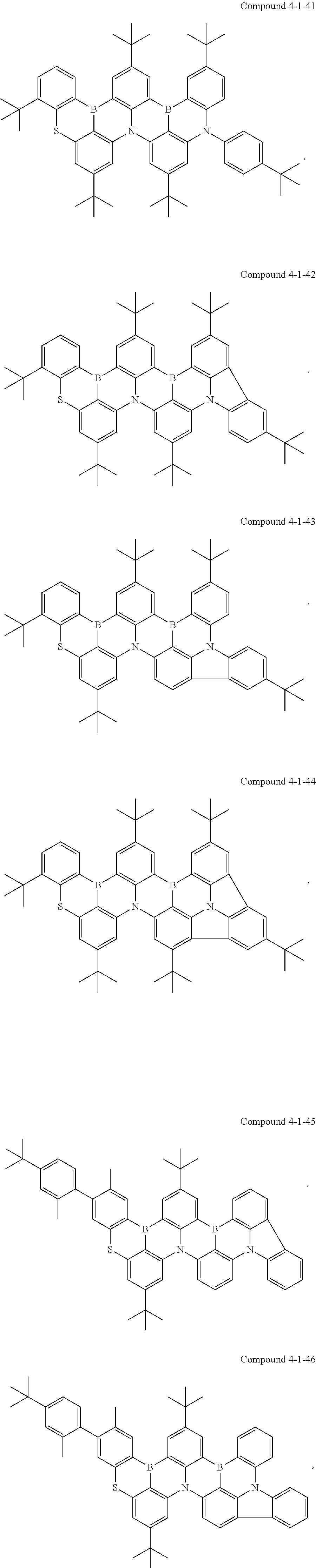 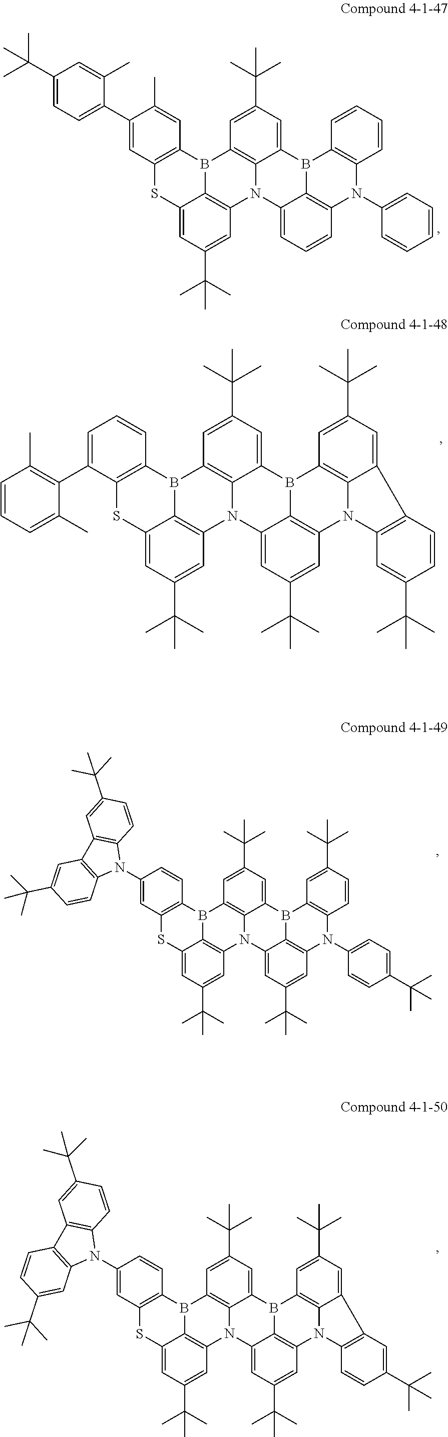 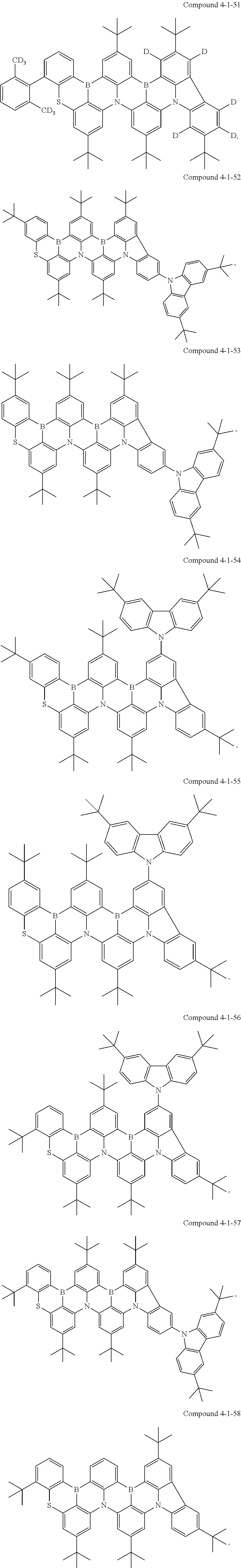 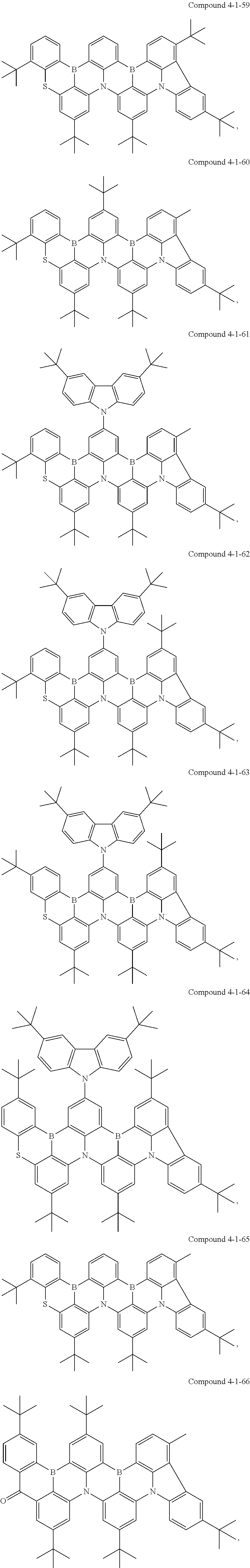 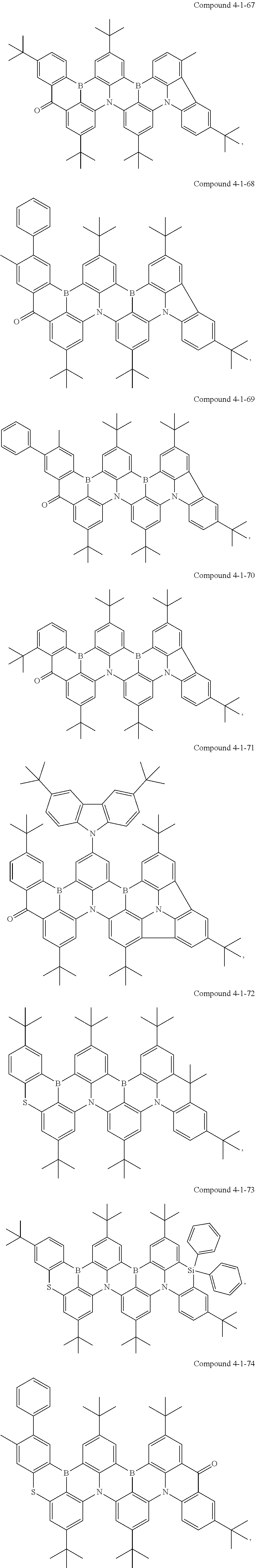 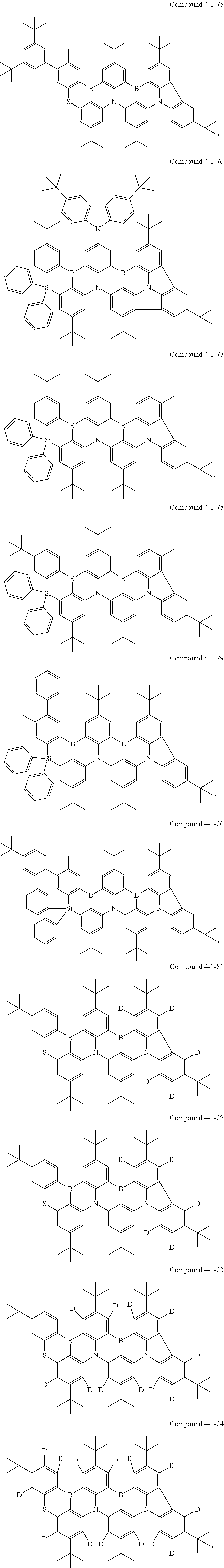 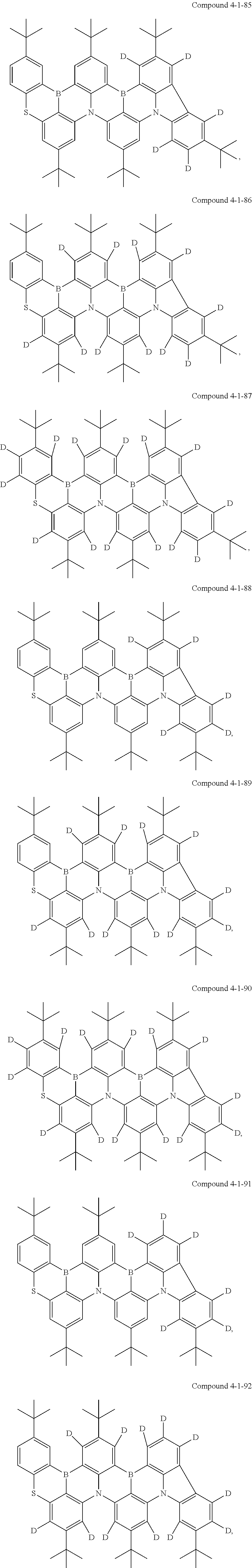 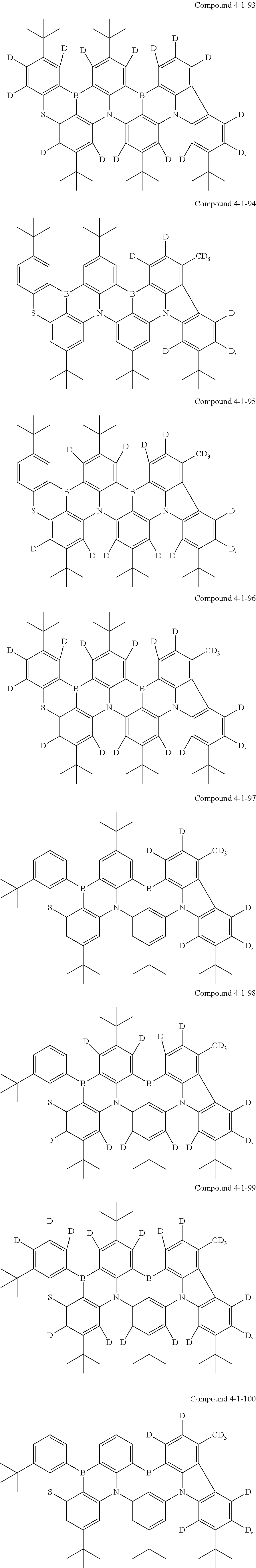 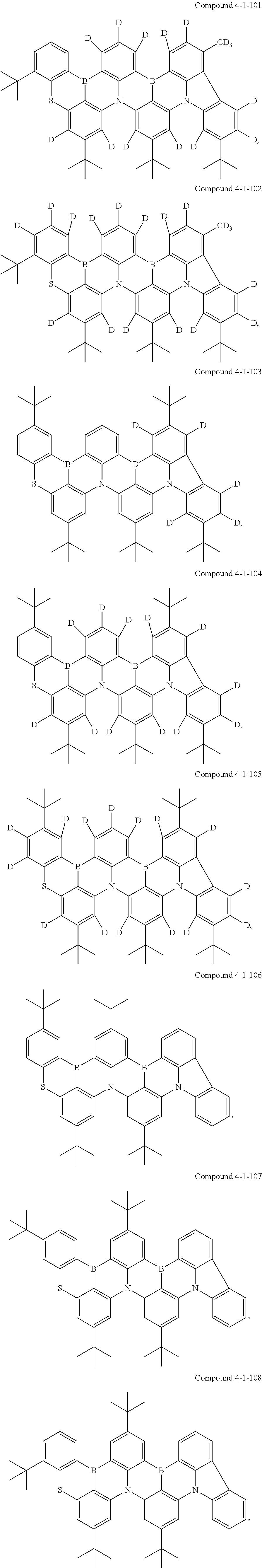 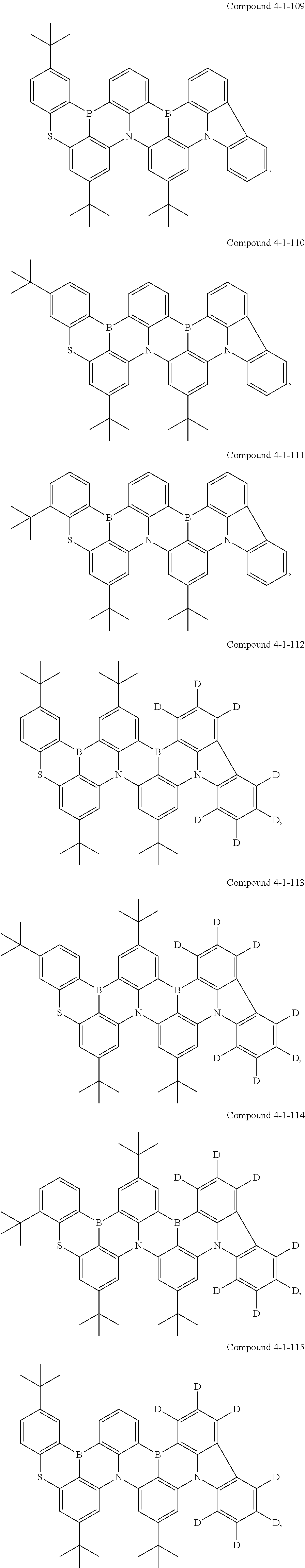 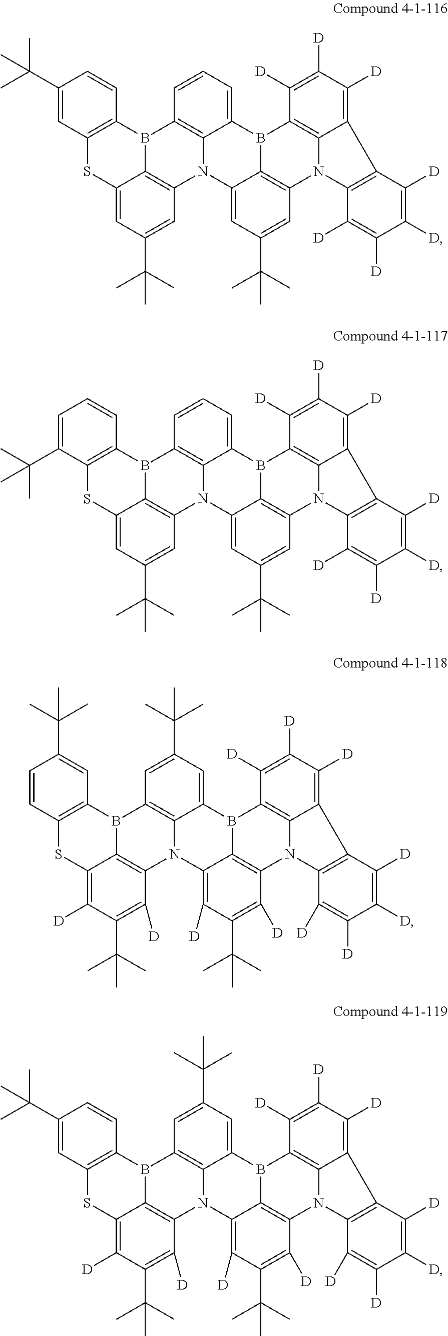 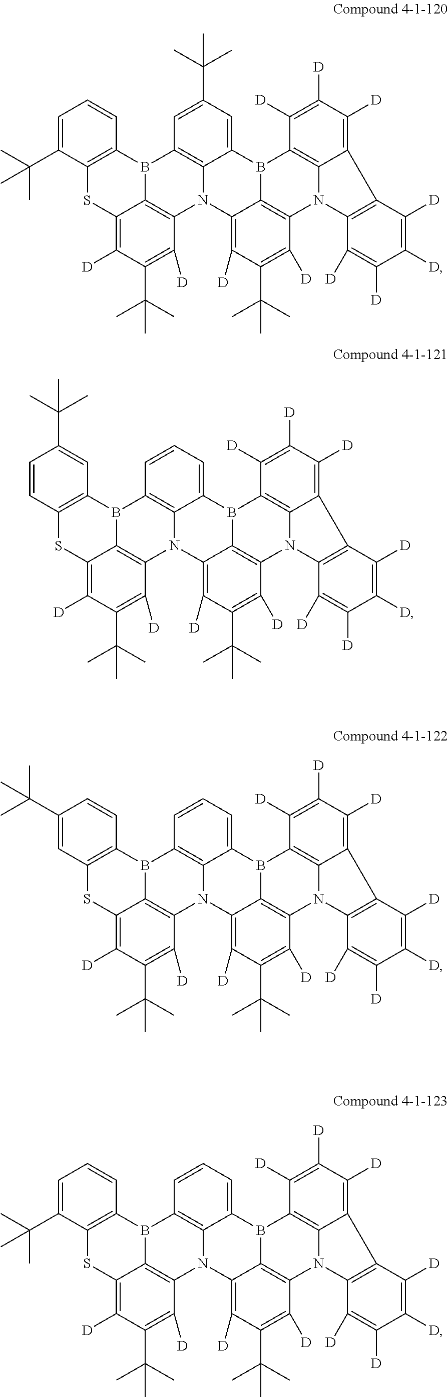 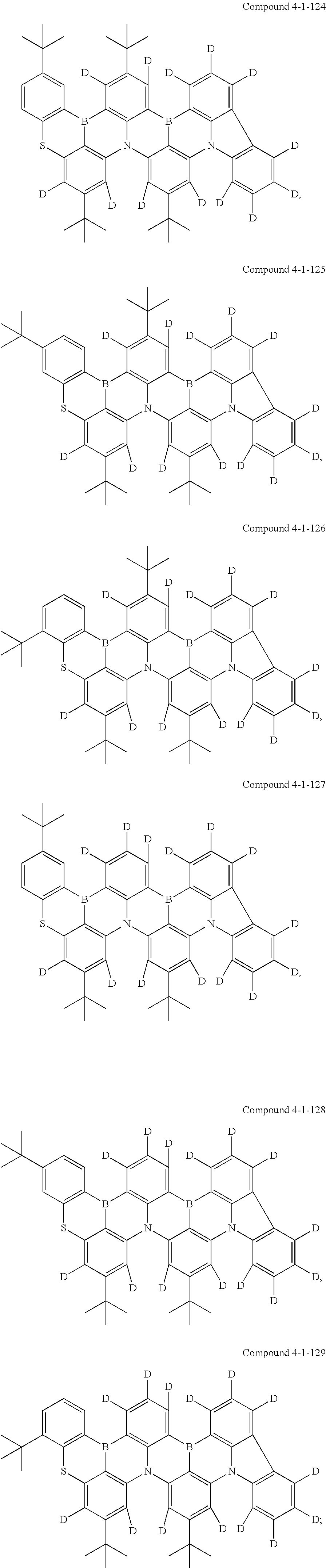
wherein optionally, hydrogens in the above compounds can be partially or fully substituted with deuterium.

10. An organic electroluminescent device, comprising an anode, a cathode, and an organic layer disposed between the anode and the cathode, wherein the organic layer comprises the compound of claim 1.

11. The organic electroluminescent device of claim 10, wherein the organic layer is an emissive layer, and the compound is a fluorescent material; preferably, the compound is a delayed fluorescent material; more preferably, the compound is a thermally activated delayed fluorescent material.

12. The organic electroluminescent device of claim 10, wherein the organic layer further comprises at least one metal complex; preferably, the at least one metal complex is used as a phosphorescent sensitizer.

13. The organic electroluminescent device of claim 11, wherein the emissive layer comprises at least one first host compound;
preferably, the emissive layer further comprises at least two host compounds; and
more preferably, at least one of the host compounds comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

14. The organic electroluminescent device of claim 13, wherein the first host compound has a structure represented by Formula X-1 or Formula X-2: 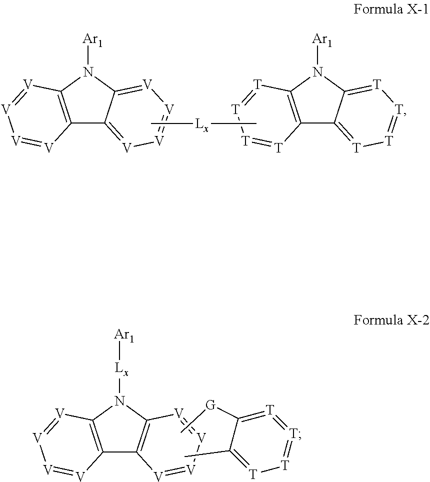
wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
G is, at each occurrence identically or differently, selected from C(R_{g})₂, NR_{g}, O, or S;
V is, at each occurrence identically or differently, selected from C, CRᵥ, or N;
in Formula X-1, T is, at each occurrence identically or differently, selected from C, CR_{T}, or N;
in Formula X-2, T is, at each occurrence identically or differently, selected from CR_{T} or N;
R_{g}, Rᵥ, and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms, or a combination thereof; and
adjacent substituents R_{g}, Rᵥ, and R_{T} can be optionally joined to form a ring.

15. The organic electroluminescent device of claim 14, wherein the emissive layer comprises the first host compound and a second host compound, and the second host compound has a structure represented by Formula Y: 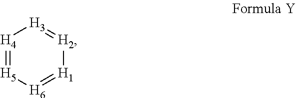
wherein,
H₁ to H₆ are, at each occurrence identically or differently, selected from C, CRₕ, or N, at least two of H₁ to H₆ are N, and at least one of H₁ to H₆ is C and joined to Formula A: 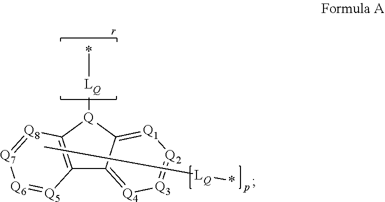
wherein,
Q is, at each occurrence identically or differently, selected from the group consisting of O, S, Se, N, NR_{Q}, CR_{Q}R_{Q}, SiR_{Q}R_{Q}, GeR_{Q}R_{Q}, and R_{Q}C═CR_{Q}; when two R_{Q} are present at the same time, the two R_{Q} may be identical or different;
p is 0 or 1; r is 0 or 1;
when Q is selected from N, p is 0, and r is 1;
when Q is selected from the group consisting of O, S, Se, NR_{Q}, CR_{Q}R_{Q}, SiR_{Q}R_{Q}, GER_{Q}R_{Q}, and R_{Q}C═CR_{Q}, p is 1, and r is 0;
L_{Q} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
Q₁ to Q₈ are, at each occurrence identically or differently, selected from C, CR_{q}, or N;
Rₕ, R_{Q}, and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
“*” represents a position where Formula A is joined to Formula Y; and
adjacent substituents Rₕ, R_{Q}, and R_{q} can be optionally joined to form a ring.

16. The organic electroluminescent device of claim 15, wherein the compound is doped in the first host compound and the second host compound, and a weight of the compound accounts for 0.1% to 30% of a total weight of the emissive layer; and
preferably, the weight of the compound accounts for 0.5% to 13% of the total weight of the emissive layer.

17. A compound composition, comprising the compound of claim 1.

18. A display device, comprising the organic electroluminescent device of claim 10.
